(19) United States
(12) Patent Application Publication
(10) Pub. No.: US 2026/0255764 A1
(43) Pub. Date: Aug. 27, 2026

(54) DISPLAY DEVICE AND METHOD OF MANUFACTURING DISPLAY DEVICE

(71) Applicant: DAI NIPPON PRINTING CO., LTD., Tokyo (JP)

(72) Inventors: Kotaro ADACHI, Tokyo (JP); Hironori HASHIGUCHI, Tokyo (JP); Kazuki KAWAMOTO, Tokyo (JP); Tetsuro YANO, Tokyo (JP)

(21) Appl. No.: 18/877,857

(22) PCT Filed: Jun. 21, 2023
(86) PCT No.: PCT/JP2023/022972

§ 371 Date: Jan. 28, 2025

(30) Foreign Application Priority Data
Jun. 21, 2022 (JP) 2022-099945
Feb. 22, 2023 (JP) 2023-026633

(51) Int. Cl. H10H 29/855; H10H 29/01; H10H 29/24

(52) U.S. Cl. CPC H10H 29/855; H10H 29/0363; H10H 29/24

(57) ABSTRACT

[Object] To increase luminance in a direction in which a display device is visually recognized.

[Solution] A display device 1 includes a light-emitting substrate 10 that includes a semiconductor layer 11 that is divided into unit regions 10a and light-emitting portions 13 that are disposed in the multiple unit regions 10a, and an optical sheet 20. The optical sheet 20 includes multiple unit lenses 21. The multiple unit regions 10a are arranged in a first direction and a second direction. w/p is less than 0.025, and at least r/p is 0.2 or more and less than 0.525 and an expression (1) is satisfied, r/p is 0.525 or more and less than 1.5 and an expression (2) is satisfied, r/p is 0.2 or more and less than 0.525 and an expression (3) is satisfied, r/p is 0.525 or more and less than 0.725 and an expression (4) is satisfied, or r/p is 0.725 or more and less than 1.5 and an expression (5) is satisfied.

### TECHNICAL FIELD

The present disclosure relates to a display device and a method of manufacturing a display device.

### BACKGROUND ART

Recent display devices each of which includes multiple light-emitting portions, particularly, display devices each of which includes LEDs, which are called LED displays, are known. In particular, a display device that uses, as a light-emitting substrate, semiconductor on which multiple fine light-emitting diodes (LEDs) or wiring lines, for example, are formed as it is, a so-called micro LED display, has been developed. The micro LED display attracts attention as a small, light, thin display. An organic EL (OLED) display that includes an organic EL element is known.

As for the display devices described above, particularly, the micro LED display, light that is radiated from the light-emitting diodes is diffuse light, and accordingly, there is a problem in that the light cannot be efficiently used. A micro LED display that is disclosed in, for example, PTL 1 against this problem includes a linear array lens at a position at which light is emitted and collects light in a predetermined direction such as a front direction. The collection of the light in the predetermined direction enables the light that is emitted from the LEDs to be efficiently used.

### CITATION LIST

### Patent Literature

PTL 1: Japanese Unexamined Patent Application Publication No. 2019-197133

### SUMMARY OF INVENTION

It is necessary for a display device to increase luminance in a direction in which a user is supposed to visually recognize the display device to a certain degree or more. In particular, in order to increase the luminance in the direction in which the user is supposed to visually recognize the display device while light is efficiently used, it is necessary to collect the light in the direction and to increase the luminance in the direction in some cases. In other cases, supposing that the user visually recognizes the display device in a direction that is shifted from the direction, it is also necessary to increase the luminance in the direction that is shifted from the direction to a certain degree or more. For example, in some cases where the display device is used as a head-up display (HUD), particularly, a head-up display that projects an image on the windshield of an automobile, it is necessary to increase the luminance in the direction and to increase the luminance in the direction that is shifted from the direction.

The present invention has been accomplished in consideration for these matters, and it is an object of the present invention to increase the luminance in a direction in which a display device is visually recognized.

According to a first aspect of the present disclosure, a display device includes: a light-emitting substrate that includes a semiconductor layer that is divided into multiple unit regions and a light-emitting portion that is disposed in the multiple unit regions; and
an optical sheet that faces the light-emitting substrate.

The optical sheet includes multiple unit lenses that are arranged in a first direction and that extend in a second direction unparallel with the first direction,
the multiple unit regions are arranged in the first direction and the second direction, and
w/p is less than 0.025, and at least r/p is 0.2 or more and less than 0.525 and an expression (1) below is satisfied, r/p is 0.525 or more and less than 1.5 and an expression (2) below is satisfied, r/p is 0.2 or more and less than 0.525 and an expression (3) below is satisfied, r/p is 0.525 or more and less than 0.725 and an expression (4) below is satisfied, or r/p is 0.725 or more and less than 1.5 and an expression (5) below is satisfied, where p is a pitch of the light-emitting portion in the first direction, w is a width of the light-emitting portion in the first direction, r is a radius of curvature of a lens surface of the unit lenses, and d is a distance between the light-emitting portion and the unit lenses,
w/p is 0.025 or more and less than 0.075, and at least r/p is 0.2 or more and less than 0.525 and an expression (6) below is satisfied, r/p is 0.525 or more and less than 1.5 and an expression (7) below is satisfied, r/p is 0.2 or more and less than 0.525 and an expression (8) below is satisfied, r/p is 0.525 or more and less than 0.725 and an expression (9) below is satisfied, or r/p is 0.725 or more and less than 1.5 and an expression (10) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.075 or more and less than 0.15, and at least r/p is 0.2 or more and less than 0.375 and an expression (11) below is satisfied, r/p is 0.375 or more and less than 1.5 and an expression (12) below is satisfied, r/p is 0.2 or more and less than 0.725 and an expression (13) below is satisfied, or r/p is 0.725 or more and less than 1.5 and an expression (14) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.15 or more and less than 0.25, and at least r/p is 0.2 or more and less than 0.725 and an expression (15) below is satisfied, r/p is 0.725 or more and less than 1.5 and an expression (16) below is satisfied, or r/p is 0.2 or more and less than 1.5 and an expression (17) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.25 or more and less than 0.35, and at least r/p is 0.25 or more and less than 0.975 and an expression (18) below is satisfied, or r/p is 0.975 or more and less than 1.5 and an expression (19) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.35 or more and less than 0.45, and r/p is 0.3 or more and less than 1.5 and an expression (20) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.45 or more and less than 0.55, and r/p is 0.4 or more and less than 1.5 and an expression (21) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses, or
w/p is 0.55 or more and less than 0.65, and r/p is 0.45 or more and less than 1.5 and an expression (22) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses.

$$\begin{matrix}[ Math 1 ] & \\ 1.18 \times r / p - 0.29 \leq d / p \leq 1.36 \times r / p - 0.05 , & expression ( 1 )\end{matrix}$$

$$1.18 \times r / p - 0.29 \leq d / p \leq 2.08 \times r / p - 0.15 , \qquad expression ( 2 )$$

$$2.43 \times r / p + 0.05 \leq d / p \leq 4.64 \times r / p - 0.3 , \qquad expression ( 3 )$$

$$4.5 \times r / p - 0.85 \leq d / p \leq 4.64 \times r / p - 0.3 , \qquad expression ( 4 )$$

$$4.5 \times r / p - 0.85 \leq d / p \leq 1.2 \times r / p + 2.46 , \qquad expression ( 5 )$$

$$1.18 \times r / p - 0.29 \leq d / p \leq 1.36 \times r / p , \qquad expression ( 6 )$$

$$1.18 \times r / p - 0.29 \leq d / p \leq 2.05 \times r / p - 0.03 , \qquad expression ( 7 )$$

$$2.57 \times r / p - 0.01 \leq d / p \leq 4.65 \times r / p - 0.3 , \qquad expression ( 8 )$$

$$4.67 \times r / p - 0.98 \leq d / p \leq 4.65 \times r / p - 0.3 , \qquad expression ( 9 )$$

$$4.67 \times r / p - 0.98 \leq d / p \leq 1.2 \times r / p + 2.46 , \qquad expression ( 10 )$$

$$1.18 \times r / p - 0.29 \leq d / p \leq 4 \times r / p - 0.1 , \qquad expression ( 11 )$$

$$1.18 \times r / p - 0.29 \leq d / p \leq 2.17 \times r / p - 0.19 , \qquad expression ( 12 )$$

$$4.79 \times r / p - 1.09 \leq d / p \leq 5.07 \times r / p - 0.58 , \qquad expression ( 13 )$$

$$4.79 \times r / p - 1.09 \leq d / p \leq 1.8 \times r / p + 1.94 , \qquad expression ( 14 )$$

$$1.18 \times r / p - 0.29 \leq d / p \leq 4.84 \times r / p - 0.45 , \qquad expression ( 15 )$$

$$1.18 \times r / p - 0.29 \leq d / p \leq 1.69 \times r / p + 0.6 , \qquad expression ( 16 )$$

$$5.6 \times r / p - 1.84 \leq d / p \leq 1.8 \times r / p + 1.94 , \qquad expression ( 17 )$$

$$1.22 \times r / p - 0.33 \leq d / p \leq 4.55 \times r / p - 0.42 , \qquad expression ( 18 )$$

$$1.22 \times r / p - 0.33 \leq d / p \leq 1.04 \times r / p + 1.78 , \qquad expression ( 19 )$$

$$1.26 \times r / p - 0.37 \leq d / p \leq 5.56 \times r / p - 1.01 , \qquad expression ( 20 )$$

$$1.28 \times r / p - 0.39 \leq d / p \leq 5.83 \times r / p - 1.29 , \qquad expression ( 21 )$$

$$1.38 \times r / p - 0.45 \leq d / p \leq 5.8 \times r / p - 1.48 . \qquad expression ( 22 )$$

According to a second aspect of the present disclosure, a display device includes: a light-emitting substrate that includes a semiconductor layer that is divided into multiple unit regions and a light-emitting portion that is disposed in the multiple unit regions; and
an optical sheet that faces the light-emitting substrate.

The optical sheet includes multiple unit lenses that are arranged in a first direction and that extend in a second direction unparallel with the first direction,
the multiple unit regions are arranged in the first direction and the second direction, and
w/p is less than 0.025, and at least r/p is 0.2 or more and less than 0.525 and an expression (23) below is satisfied, or r/p is 0.525 or more and less than 1.5 and an expression (24) below is satisfied, where p is a pitch of the light-emitting portion in the first direction, w is a width of the light-emitting portion in the first direction, r is a radius of curvature of a lens surface of the unit lenses, and d is a distance between the light-emitting portion and the unit lenses,
w/p is 0.025 or more and less than 0.15, and at least r/p is 0.2 or more and less than 0.525 and an expression (25) below is satisfied, or r/p is 0.525 or more and less than 1.5 and an expression (26) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.15 or more and less than 0.25, and at least r/p is 0.2 or more and less than 0.525 and an expression (27) below is satisfied, or r/p is 0.525 or more and less than 1.5 and an expression (28) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.25 or more and less than 0.35, and at least r/p is 0.25 or more and less than 0.425 and an expression (29) below is satisfied, or r/p is 0.425 or more and less than 1.5 and an expression (30) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.35 or more and less than 0.45, and at least r/p is 0.3 or more and less than 0.525 and an expression (31) below is satisfied, or r/p is 0.525 or more and less than 1.5 and an expression (32) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.45 or more and less than 0.55, and at least r/p is 0.4 or more and less than 0.625 and an expression (33) below is satisfied, or r/p is 0.625 or more and less than 1.5 and an expression (34) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses, or
w/p is 0.55 or more and less than 0.65, and at least r/p is 0.45 or more and less than 0.625 and an expression (35) below is satisfied, or r/p is 0.625 or more and less than 1.5 and an expression (36) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses.

$$\begin{matrix}[ Math 2 ] & \\ 1.18 \times r / p - 0.29 \leq d / p \leq 1 \times r / p - 0.02 , & expression ( 23 )\end{matrix}$$

$$1.18 \times r / p - 0.29 \leq d / p \leq 1.33 \times r / p + 0.15 , \qquad expression ( 24 )$$

$$1.18 \times r / p - 0.29 \leq d / p \leq 1.14 \times r / p - 0.04 , \qquad expression ( 25 )$$

$$1.18 \times r / p - 0.29 \leq d / p \leq 1.3 \times r / p + 0.18 , \qquad expression ( 26 )$$

$$1.18 \times r / p - 0.29 \leq d / p \leq - 0.29 \times r / p + 0.73 , \qquad expression ( 27 )$$

$$1.18 \times r / p - 0.29 \leq d / p \leq 1.29 \times r / p + 0.28 , \qquad expression ( 28 )$$

$$1.22 \times r / p - 0.33 \leq d / p \leq 4.6 \times r / p - 0.52 , \qquad expression ( 29 )$$

$$1.22 \times r / p - 0.33 \leq d / p \leq 1.23 \times r / p + 0.38 , \qquad expression ( 30 )$$

$$1.26 \times r / p - 0.37 \leq d / p \leq 5.4 \times r / p - 0.96 , \qquad expression ( 31 )$$

$$1.26 \times r / p - 0.37 \leq d / p \leq 0.77 \times r / p + 1.08 , \qquad expression ( 32 )$$

$$1.28 \times r / p - 0.39 \leq d / p \leq 5.83 \times r / p - 1.29 , \qquad expression ( 33 )$$

$$1.28 \times r / p - 0.39 \leq d / p \leq 0.4 \times r / p + 1.77 , \qquad expression ( 34 )$$

$$1.38 \times r / p - 0.45 \leq d / p \leq 7.6 \times r / p - 2.44 , \qquad expression ( 35 )$$

$$1.38 \times r / p - 0.45 \leq d / p \leq 0.26 \times r / p + 2.2 9. \qquad expression ( 36 )$$

According to a third aspect of the present disclosure, a display device includes: a light-emitting substrate that includes a semiconductor layer that is divided into multiple unit regions and a light-emitting portion that is disposed in the multiple unit regions; and
an optical sheet that faces the light-emitting substrate.

The optical sheet includes multiple unit lenses that are arranged in a first direction and that extend in a second direction unparallel with the first direction,
the multiple unit regions are arranged in the first direction and the second direction, and
w/p is 0.01 or more and less than 0.05, and at least r/p is 0.2 or more and less than 0.525 and an expression (37) below is satisfied, r/p is 0.525 or more and less than 0.975 and an expression (38) below is satisfied, r/p is 0.975 or more and less than 1.5 and an expression (39) below is satisfied, r/p is 0.2 or more and less than 0.525 and an expression (40) below is satisfied, or r/p is 0.525 or more and less than 0.975 and an expression (41) below is satisfied, where p is a pitch of the light-emitting portion in the first direction, w is a width of the light-emitting portion in the first direction, r is a radius of curvature of a lens surface of the unit lenses, and d is a distance between the light-emitting portion and the unit lenses,
w/p is 0.05 or more and less than 0.1, and at least r/p is 0.2 or more and less than 0.525 and an expression (42) below is satisfied, r/p is 0.525 or more and less than 0.975 and an expression (43) below is satisfied, r/p is 0.975 or more and less than 1.5 and an expression (44) below is satisfied, r/p is 0.2 or more and less than 0.525 and an expression (45) below is satisfied, or r/p is 0.525 or more and less than 0.975 and an expression (46) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.1 or more and less than 0.2, and at least r/p is 0.2 or more and less than 0.375 and an expression (47) below is satisfied, r/p is 0.375 or more and less than 0.975 and an expression (48) below is satisfied, r/p is 0.975 or more and less than 1.5 and an expression (49) below is satisfied, or r/p is 0.375 or more and less than 0.975 and an expression (50) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.2 or more and less than 0.3, and at least r/p is 0.25 or more and less than 0.725 and an expression (51) below is satisfied, r/p is 0.725 or more and less than 0.975 and an expression (52) below is satisfied, r/p is 0.975 or more and less than 1.5 and an expression (53) below is satisfied, or r/p is 0.725 or more and less than 0.975 and an expression (54) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.3 or more and less than 0.4, and at least r/p is 0.35 or more and less than 0.975 and an expression (55) below is satisfied, or r/p is 0.975 or more and less than 1.5 and an expression (56) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.4 or more and less than 0.5, and at least r/p is 0.4 or more and less than 0.675 and an expression (57) below is satisfied, or r/p is 0.675 or more and less than 1.5 and an expression (58) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses, or
w/p is 0.5 or more and less than 0.6, and at least r/p is 0.5 or more and less than 0.675 and an expression (59) below is satisfied, or r/p is 0.675 or more and less than 1.5 and an expression (60) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses.

$$\begin{matrix}[ Math 3 ] & \\ 0.21 \times r / p + 0.01 \leq d / p \leq 1 \times r / p - 0.02 , & expression ( 37 )\end{matrix}$$

$$1.4 \times r / p - 0.45 \leq d / p \leq 2.23 \times r / p - 0 \text{.4} , \qquad expression ( 38 )$$

$$1.09 \times r / p - 0.18 \leq d / p \leq 1.53 \times r / p + 0.3 , \qquad expression ( 39 )$$

$$2.43 \times r / p + 0.05 \leq d / p \leq 3.57 \times r / p - 0.21 , \qquad expression ( 40 )$$

$$4.57 \times r / p - 0.89 \leq d / p \leq 4 \times r / p - 0 \text{.3} , \qquad expression ( 41 )$$

$$0.21 \times r / p + 0.01 \leq d / p \leq 0.79 \times r / p + 0.11 , \qquad expression ( 42 )$$

$$1.4 \times r / p - 0.45 \leq d / p \leq 2.23 \times r / p - 0 \text{.4} , \qquad expression ( 43 )$$

$$1.09 \times r / p - 0.18 \leq d / p \leq 1.56 \times r / p + 0.27 , \qquad expression ( 44 )$$

$$2.57 \times r / p - 0.01 \leq d / p \leq 3.43 \times r / p - 0.17 , \qquad expression ( 45 )$$

$$4.77 \times r / p - 1.04 \leq d / p \leq 4.13 \times r / p - 0.41 , \qquad expression ( 46 )$$

$$0.6 \times r / p - 0.09 \leq d / p \leq 4 \times r / p - 0 \text{.4} , \qquad expression ( 47 )$$

$$1.53 \times r / p - 0.56 \leq d / p \leq 2.27 \times r / p - 0.35 , \qquad expression ( 48 )$$

$$1.09 \times r / p - 0.18 \leq d / p \leq 1.56 \times r / p + 0.28 , \qquad expression ( 49 )$$

$$4.79 \times r / p - 1.09 \leq d / p \leq 4.41 \times r / p - 0.64 , \qquad expression ( 50 )$$

$$1.03 \times r / p - 0.26 \leq d / p \leq 4.39 \times r / p - 0.64 , \qquad expression ( 51 )$$

$$1.4 \times r / p - 0.45 \leq d / p \leq 0.4 \times r / p + 1.58 , \qquad expression ( 52 )$$

$$1.15 \times r / p - 0.24 \leq d / p \leq 1.49 \times r / p + 0.54 , \qquad expression ( 53 )$$

$$5.6 \times r / p - 1.84 \leq d / p \leq 4 \times r / p - 0.3 , \qquad expression ( 54 )$$

$$1.45 \times r / p - 0.5 \leq d / p \leq 4.45 \times r / p - 0.77 , \qquad expression ( 55 )$$

$$1.16 \times r / p - 0.25 \leq d / p \leq 0.35 \times r / p + 2.51 , \qquad expression ( 56 )$$

$$1.77 \times r / p - 0.68 \leq d / p \leq 5.43 \times r / p - 1.43 , \qquad expression ( 57 )$$

$$1.13 \times r / p - 0.22 \leq d / p \leq 3.23 \times r / p + 0.13 , \qquad expression ( 58 )$$

$$2.6 \times r / p - 1.17 \leq d / p \leq 6.6 \times r / p - 2.27 , \qquad expression ( 59 )$$

$$1.27 \times r / p - 0.33 \leq d / p \leq 3.3 \times r / p - 0.0 6. \qquad expression ( 60 )$$

According to a fourth aspect of the present disclosure, a display device includes: a light-emitting substrate that includes a semiconductor layer that is divided into multiple unit regions and a light-emitting portion that is disposed in the multiple unit regions; and an optical sheet that faces the light-emitting substrate.

The optical sheet includes multiple unit lenses that are arranged in a first direction and that extend in a second direction unparallel with the first direction,
the multiple unit regions are arranged in the first direction and the second direction, and
w/p is 0.01 or more and less than 0.05, and at least r/p is 0.2 or more and less than 0.525 and an expression (61) below is satisfied, or r/p is 0.525 or more and less than 1.5 and an expression (62) below is satisfied, where p is a pitch of the light-emitting portion in the first direction, w is a width of the light-emitting portion in the first direction, r is a radius of curvature of a lens surface of the unit lenses, and d is a distance between the light-emitting portion and the unit lenses,
w/p is 0.05 or more and less than 0.1, and at least r/p is 0.2 or more and less than 0.525 and an expression (63) below is satisfied, or r/p is 0.525 or more and less than 1.5 and an expression (64) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.1 or more and less than 0.2, and at least r/p is 0.2 or more and less than 0.525 and an expression (65) below is satisfied, or r/p is 0.525 or more and less than 1.5 and an expression (66) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.2 or more and less than 0.3, and at least r/p is 0.25 or more and less than 0.525 and an expression (67) below is satisfied, or r/p is 0.525 or more and less than 1.5 and an expression (68) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.3 or more and less than 0.4, and at least r/p is 0.35 or more and less than 0.675 and an expression (69) below is satisfied, or r/p is 0.675 or more and less than 1.5 and an expression (70) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
w/p is 0.4 or more and less than 0.5, and at least r/p is 0.4 or more and less than 0.675 and an expression (71) below is satisfied, or r/p is 0.675 or more and less than 1.5 and an expression (72) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses, or
w/p is 0.5 or more and less than 0.6, and at least r/p is 0.5 or more and less than 0.675 and an expression (73) below is satisfied, or r/p is 0.675 or more and less than 1.5 and an expression (74) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses.

$$\begin{matrix}[ Math 4 ] & \\ 0.21 \times r / p + 0.02 \leq d / p \leq 1 \times r / p - 0.08 , & expression ( 61 )\end{matrix}$$

$$1.17 \times r / p - 0.28 \leq d / p \leq 1.26 \times r / p + 0.13 , \qquad expression ( 62 )$$

$$0.21 \times r / p + 0.02 \leq d / p \leq 1 \times r / p - 0.08 , \qquad expression ( 63 )$$

$$1.17 \times r / p - 0.28 \leq d / p \leq 1.26 \times r / p + 0.14 , \qquad expression ( 64 )$$

$$0.21 \times r / p + 0.01 \leq d / p \leq 0.71 \times r / p + 0.05 , \qquad expression ( 65 )$$

$$1.17 \times r / p - 0.28 \leq d / p \leq 1.26 \times r / p + 0.14 , \qquad expression ( 66 )$$

$$0.29 \times r / p - 0.05 \leq d / p \leq - 0.23 \times r / p + 0.62 , \qquad expression ( 67 )$$

$$1.2 \times r / p - 0.3 \leq d / p \leq 1.2 \times r / p + 0.21 , \qquad expression ( 68 )$$

$$1.43 \times r / p - 0.49 \leq d / p \leq 1.07 \times r / p + 0.45 , \qquad expression ( 69 )$$

$$1.19 \times r / p - 0.28 \leq d / p \leq 1 \times r / p + 0.5 , \qquad expression ( 70 )$$

$$1.77 \times r / p - 0.68 \leq d / p \leq 2.86 \times r / p - 0.23 , \qquad expression ( 71 )$$

$$1.15 \times r / p - 0.23 \leq d / p \leq 0.64 \times r / p + 1.13 , \qquad expression ( 72 )$$

$$2.6 \times r / p - 1.17 \leq d / p \leq 6.6 \times r / p - 2.27 , \qquad expression ( 73 )$$

$$1.27 \times r / p - 0.33 \leq d / p \leq 0.35 \times r / p + 1.7 8. \qquad expression ( 74 )$$

According to a fifth aspect of the present disclosure, during observation in a normal direction to a plate surface of the light-emitting substrate, one of the unit lenses may correspond to one of unit region second direction columns that are formed by the multiple unit regions that are arranged in the second direction, as for the display device according to the first aspect described above to the fourth aspect described above.

According to a sixth aspect of the present disclosure, during observation in the normal direction to the plate surface of the light-emitting substrate, a center in the first direction of the one of the unit lenses may be shifted from a center in the first direction of the light-emitting portion in the unit region that forms the corresponding one of the unit region second direction columns, as for the display device according to the fifth aspect described above.

According to a seventh aspect of the present disclosure, the optical sheet may have a first surface that faces the light-emitting substrate and a second surface that is opposite the first surface, and
a light deflection layer that faces the second surface of the optical sheet and that deflects light from the optical sheet such that a travelling direction changes during observation in the second direction may be further included, as for the display device according to the first aspect described above to the fourth aspect described above.

According to an eighth aspect of the present disclosure, the optical sheet may have a first surface that faces the light-emitting substrate and a second surface that is opposite the first surface, and a light angle adjustment layer that is located along the second surface of the optical sheet and that adjusts an angle of a travelling direction of light from the optical sheet with respect to a normal direction to a plate surface of the light-emitting substrate may be further included, as for the display device according to the first aspect described above to the seventh aspect described above.

According to a ninth aspect of the present disclosure, the light-emitting substrate may include, as the light-emitting portion, a first light-emitting portion and a second light-emitting portion that emits light at a wavelength that differs from that of the first light-emitting portion, as for the display device according to the first aspect described above to the eighth aspect described above.

According to a tenth aspect of the present disclosure, a minimum value m of luminance when an angle that is formed with respect to a light collection direction of the optical sheet may be in a range of −5° or more and +5° or less is 50% or more of a maximum value M of luminance when the angle that is formed with respect to the light collection direction of the optical sheet is in the range of −5° or more and +5° or less, as for the display device according to the first aspect described above or the third aspect described above.

According to an eleventh aspect of the present disclosure, a minimum value m2 of luminance when an angle that is formed with respect to a light collection direction of the optical sheet may be in a range of −10° or more and +10° or less is 50% or more of a maximum value M2 of luminance when the angle that is formed with respect to the light collection direction of the optical sheet is in the range of −10° or more and +10° or less, as for the display device according to the second aspect described above or the fourth aspect described above.

A twelfth aspect of the present disclosure is a method of manufacturing a display device including: a light-emitting substrate that includes a semiconductor layer that is divided into multiple unit regions and a light-emitting portion that is disposed in the multiple unit regions; and an optical sheet that faces the light-emitting substrate,
the optical sheet includes multiple unit lenses that are arranged in a first direction and that extend in a second direction unparallel with the first direction,
the multiple unit regions are arranged in the first direction and the second direction, and
the method includes an adjustment step of adjusting a radius of curvature r and a distance d depending on a value of w/p, where p is a pitch of the light-emitting portion in the first direction, w is a width of the light-emitting portion in the first direction, r is a radius of curvature of a lens surface of the unit lenses, and d is a distance between the light-emitting portion and the unit lenses.

In the adjustment step, in a case where w/p is less than 0.025, the radius of curvature r and the distance d are adjusted such that at least r/p is 0.2 or more and less than 0.525 and an expression (1) below is satisfied, r/p is 0.525 or more and less than 1.5 and an expression (2) below is satisfied, r/p is 0.2 or more and less than 0.525 and an expression (3) below is satisfied, r/p is 0.525 or more and less than 0.725 and an expression (4) below is satisfied, or r/p is 0.725 or more and less than 1.5 and an expression (5) below is satisfied,
in the adjustment step, in a case where w/p is 0.025 or more and less than 0.075, the radius of curvature r and the distance d are adjusted such that at least r/p is 0.2 or more and less than 0.525 and an expression (6) below is satisfied, r/p is 0.525 or more and less than 1.5 and an expression (7) below is satisfied, r/p is 0.2 or more and less than 0.525 and an expression (8) below is satisfied, r/p is 0.525 or more and less than 0.725 and an expression (9) below is satisfied, or r/p is 0.725 or more and less than 1.5 and an expression (10) below is satisfied,
in the adjustment step, in a case where w/p is 0.075 or more and less than 0.15, the radius of curvature r and the distance d are adjusted such that at least r/p is 0.2 or more and less than 0.375 and an expression (11) below is satisfied, r/p is 0.375 or more and less than 1.5 and an expression (12) below is satisfied, r/p is 0.2 or more and less than 0.725 and an expression (13) below is satisfied, or r/p is 0.725 or more and less than 1.5 and an expression (14) below is satisfied,
in the adjustment step, in a case where w/p is 0.15 or more and less than 0.25, the radius of curvature r and the distance d are adjusted such that at least r/p is 0.2 or more and less than 0.725 and an expression (15) below is satisfied, r/p is 0.725 or more and less than 1.5 and an expression (16) below is satisfied, or r/p is 0.2 or more and less than 1.5 and an expression (17) below is satisfied,
in the adjustment step, in a case where w/p is 0.25 or more and less than 0.35, the radius of curvature r and the distance d are adjusted such that at least r/p is 0.25 or more and less than 0.975 and an expression (18) below is satisfied, or r/p is 0.975 or more and less than 1.5 and an expression (19) below is satisfied,
in the adjustment step, in a case where w/p is 0.35 or more and less than 0.45, the radius of curvature r and the distance d are adjusted such that r/p is 0.3 or more and less than 1.5 and an expression (20) below is satisfied,
in the adjustment step, in a case where w/p is 0.45 or more and less than 0.55, the radius of curvature r and the distance d are adjusted such that r/p is 0.4 or more and less than 1.5 and an expression (21) below is satisfied, and
in the adjustment step, in a case where w/p is 0.55 or more and less than 0.65, the radius of curvature r and the distance d are adjusted such that r/p is 0.45 or more and less than 1.5 and an expression (22) below is satisfied.

$$\begin{matrix}[ Math 5 ] & \\ 1.18 \times r / p - 0.29 \leq d / p \leq 1.36 \times r / p - 0.05 , & expression ( 1 )\end{matrix}$$

$$1.18 \times r / p - 0.29 \leq d / p \leq 2.08 \times r / p - 0.15 , \qquad expression ( 2 )$$

$$2.43 \times r / p + 0.05 \leq d / p \leq 4.64 \times r / p - 0.3 , \qquad expression ( 3 )$$

$$4.5 \times r / p - 0.85 \leq d / p \leq 4.64 \times r / p - 0.3 , \qquad expression ( 4 )$$

$$4.5 \times r / p - 0.85 \leq d / p \leq 1.2 \times r / p + 2.46 , \qquad expression ( 5 )$$

$$1.18 \times r / p - 0.29 \leq d / p \leq 1.36 \times r / p , \qquad expression ( 6 )$$

$$1.18 \times r / p - 0.29 \leq d / p \leq 2.05 \times r / p - 0.03 , \qquad expression ( 7 )$$

$$2.57 \times r / p - 0.01 \leq d / p \leq 4.65 \times r / p - 0.3 , \qquad expression ( 8 )$$

$$4.67 \times r / p - 0.98 \leq d / p \leq 4.65 \times r / p - 0.3 , \qquad expression ( 9 )$$

$$4.67 \times r / p - 0.98 \leq d / p \leq 1.2 \times r / p + 2.46 , \qquad expression ( 10 )$$

$$1.18 \times r / p - 0.29 \leq d / p \leq 4 \times r / p - 0.1 , \qquad expression ( 11 )$$

$$1.18 \times r / p - 0.29 \leq d / p \leq 2.17 \times r / p - 0.19 , \qquad expression ( 12 )$$

$$4.79 \times r / p - 1.09 \leq d / p \leq 5.07 \times r / p - 0.58 , \qquad expression ( 13 )$$

$$4.79 \times r / p - 1.09 \leq d / p \leq 1.8 \times r / p + 1.94 , \qquad expression ( 14 )$$

$$1.18 \times r / p - 0.29 \leq d / p \leq 4.84 \times r / p - 0.45 , \qquad expression ( 15 )$$

$$1.18 \times r / p - 0.29 \leq d / p \leq 1.69 \times r / p + 0.6 , \qquad expression ( 16 )$$

$$5.6 \times r / p - 1.84 \leq d / p \leq 1.8 \times r / p + 1.94 , \qquad expression ( 17 )$$

$$1.22 \times r / p - 0.33 \leq d / p \leq 4.55 \times r / p - 0.42 , \qquad expression ( 18 )$$

$$1.22 \times r / p - 0.33 \leq d / p \leq 1.04 \times r / p + 1.78 , \qquad expression ( 19 )$$

$$1.26 \times r / p - 0.37 \leq d / p \leq 5.56 \times r / p - 1.01 , \qquad expression ( 20 )$$

$$1.28 \times r / p - 0.39 \leq d / p \leq 5.83 \times r / p - 1.29 , \qquad expression ( 21 )$$

$$1.38 \times r / p - 0.45 \leq d / p \leq 5.8 \times r / p - 1.4 8. \qquad expression ( 22 )$$

A thirteenth aspect of the present disclosure is a method of manufacturing a display device including: a light-emitting substrate that includes a semiconductor layer that is divided into multiple unit regions and a light-emitting portion that is disposed in the multiple unit regions; and an optical sheet that faces the light-emitting substrate,
the optical sheet includes multiple unit lenses that are arranged in a first direction and that extend in a second direction unparallel with the first direction,
the multiple unit regions are arranged in the first direction and the second direction, and
the method includes an adjustment step of adjusting a radius of curvature r and a distance d depending on a value of w/p, where p is a pitch of the light-emitting portion in the first direction, w is a width of the light-emitting portion in the first direction, r is a radius of curvature of a lens surface of the unit lenses, and d is a distance between the light-emitting portion and the unit lenses.

In the adjustment step, in a case where w/p is less than 0.025, the radius of curvature r and the distance d are adjusted such that at least r/p is 0.2 or more and less than 0.525 and an expression (23) below is satisfied, or r/p is 0.525 or more and less than 1.5 and an expression (24) below is satisfied, in the adjustment step, in a case where w/p is 0.025 or more and less than 0.15, the radius of curvature r and the distance d are adjusted such that at least r/p is 0.2 or more and less than 0.525 and an expression (25) below is satisfied, or r/p is 0.525 or more and less than 1.5 and an expression (26) below is satisfied,
in the adjustment step, in a case where w/p is 0.15 or more and less than 0.25, the radius of curvature r and the distance d are adjusted such that at least r/p is 0.2 or more and less than 0.525 and an expression (27) below is satisfied, or r/p is 0.525 or more and less than 1.5 and an expression (28) below is satisfied,
in the adjustment step, in a case where w/p is 0.25 or more and less than 0.35, the radius of curvature r and the distance d are adjusted such that at least r/p is 0.25 or more and less than 0.425 and an expression (29) below is satisfied, or r/p is 0.425 or more and less than 1.5 and an expression (30) below is satisfied,
in the adjustment step, in a case where w/p is 0.35 or more and less than 0.45, the radius of curvature r and the distance d are adjusted such that at least r/p is 0.3 or more and less than 0.525 and an expression (31) below is satisfied, or r/p is 0.525 or more and less than 1.5 and an expression (32) below is satisfied,
in the adjustment step, in a case where w/p is 0.45 or more and less than 0.55, the radius of curvature r and the distance d are adjusted such that at least r/p is 0.4 or more and less than 0.625 and an expression (33) below is satisfied, or r/p is 0.625 or more and less than 1.5 and an expression (34) below is satisfied, and
in the adjustment step, in a case where w/p is 0.55 or more and less than 0.65, the radius of curvature r and the distance d are adjusted such that at least r/p is 0.45 or more and less than 0.625 and an expression (35) below is satisfied, or r/p is 0.625 or more and less than 1.5 and an expression (36) below is satisfied.

$$\begin{matrix}[ Math 6 ] & \\ 1.18 \times r / p - 0.29 \leq d / p \leq 1 \times r / p - 0.02 , & expression ( 23 )\end{matrix}$$

$$1.18 \times r / p - 0.29 \leq d / p \leq 1.33 \times r / p + 0.15 , \qquad expression ( 24 )$$

$$1.18 \times r / p - 0.29 \leq d / p \leq 1.14 \times r / p - 0.04 , \qquad expression ( 25 )$$

$$1.18 \times r / p - 0.29 \leq d / p \leq 1.3 \times r / p + 0.18 , \qquad expression ( 26 )$$

$$1.18 \times r / p - 0.29 \leq d / p \leq - 0.29 \times r / p + 0.73 , \qquad expression ( 27 )$$

$$1.18 \times r / p - 0.29 \leq d / p \leq 1.29 \times r / p + 0.28 , \qquad expression ( 28 )$$

$$1.22 \times r / p - 0.33 \leq d / p \leq 4.6 \times r / p - 0.52 , \qquad expression ( 29 )$$

$$1.22 \times r / p - 0.33 \leq d / p \leq 1.23 \times r / p + 0.38 , \qquad expression ( 30 )$$

$$1.26 \times r / p - 0.37 \leq d / p \leq 5.4 \times r / p - 0.96 , \qquad expression ( 31 )$$

$$1.26 \times r / p - 0.37 \leq d / p \leq 0.77 \times r / p + 1.08 , \qquad expression ( 32 )$$

$$1.28 \times r / p - 0.39 \leq d / p \leq 5.83 \times r / p - 1.29 , \qquad expression ( 33 )$$

$$1.28 \times r / p - 0.39 \leq d / p \leq 0.4 \times r / p + 1.77 , \qquad expression ( 34 )$$

$$1.38 \times r / p - 0.45 \leq d / p \leq 7.6 \times r / p - 2.44 , \qquad expression ( 35 )$$

$$1.38 \times r / p - 0.45 \leq d / p \leq 0.26 \times r / p + 2.2 9. \qquad expression ( 36 )$$

A fourteenth aspect of the present disclosure is a method of manufacturing a display device including: a light-emitting substrate that includes a semiconductor layer that is divided into multiple unit regions and a light-emitting portion that is disposed in the multiple unit regions; and an optical sheet that faces the light-emitting substrate,
the optical sheet includes multiple unit lenses that are arranged in a first direction and that extend in a second direction unparallel with the first direction,
the multiple unit regions are arranged in the first direction and the second direction, and
the method includes an adjustment step of adjusting a radius of curvature r and a distance d depending on a value of w/p, where p is a pitch of the light-emitting portion in the first direction, w is a width of the light-emitting portion in the first direction, r is a radius of curvature of a lens surface of the unit lenses, and d is a distance between the light-emitting portion and the unit lenses.

In the adjustment step, in a case where w/p is 0.01 or more and less than 0.05, the radius of curvature r and the distance d are adjusted such that at least r/p is 0.2 or more and less than 0.525 and an expression (37) below is satisfied, r/p is 0.525 or more and less than 0.975 and an expression (38) below is satisfied, r/p is 0.975 or more and less than 1.5 and an expression (39) below is satisfied, r/p is 0.2 or more and less than 0.525 and an expression (40) below is satisfied, or r/p is 0.525 or more and less than 0.975 and an expression (41) below is satisfied,
in a case where w/p is 0.05 or more and less than 0.1, the radius of curvature r and the distance d are adjusted such that at least r/p is 0.2 or more and less than 0.525 and an expression (42) below is satisfied, r/p is 0.525 or more and less than 0.975 and an expression (43) below is satisfied, r/p is 0.975 or more and less than 1.5 and an expression (44) below is satisfied, r/p is 0.2 or more and less than 0.525 and an expression (45) below is satisfied, or r/p is 0.525 or more and less than 0.975 and an expression (46) below is satisfied,
in a case where w/p is 0.1 or more and less than 0.2, the radius of curvature r and the distance d are adjusted such that at least r/p is 0.2 or more and less than 0.375 and an expression (47) below is satisfied, r/p is 0.375 or more and less than 0.975 and an expression (48) below is satisfied, r/p is 0.975 or more and less than 1.5 and an expression (49) below is satisfied, or r/p is 0.375 or more and less than 0.975 and an expression (50) below is satisfied,
in a case where w/p is 0.2 or more and less than 0.3, the radius of curvature r and the distance d are adjusted such that at least r/p is 0.25 or more and less than 0.725 and an expression (51) below is satisfied, r/p is 0.725 or more and less than 0.975 and an expression (52) below is satisfied, r/p is 0.975 or more and less than 1.5 and an expression (53) below is satisfied, or r/p is 0.725 or more and less than 0.975 and an expression (54) below is satisfied,
in a case where w/p is 0.3 or more and less than 0.4, the radius of curvature r and the distance d are adjusted such that at least r/p is 0.35 or more and less than 0.975 and an expression (55) below is satisfied, or r/p is 0.975 or more and less than 1.5 and an expression (56) below is satisfied,
in a case where w/p is 0.4 or more and less than 0.5, the radius of curvature r and the distance d are adjusted such that at least r/p is 0.4 or more and less than 0.675 and an expression (57) below is satisfied, or r/p is 0.675 or more and less than 1.5 and an expression (58) below is satisfied, and
in a case where w/p is 0.5 or more and less than 0.6, the radius of curvature r and the distance d are adjusted such that at least r/p is 0.5 or more and less than 0.675 and an expression (59) below is satisfied, or r/p is 0.675 or more and less than 1.5 and an expression (60) below is satisfied.

$$\begin{matrix}[ Math 7 ] & \\ 0.21 \times r / p + 0.01 \leq d / p \leq 1 \times r / p - 0.02 , & expression ( 37 )\end{matrix}$$

$$1.4 \times r / p - 0.45 \leq d / p \leq 2.23 \times r / p - 0.4 , \qquad expression ( 38 )$$

$$1.09 \times r / p - 0.18 \leq d / p \leq 1.53 \times r / p + 0.3 , \qquad expression ( 39 )$$

$$2.43 \times r / p + 0.05 \leq d / p \leq 3.57 \times r / p - 0.21 , \qquad expression ( 40 )$$

$$4.57 \times r / p - 0.89 \leq d / p \leq 4 \times r / p - 0.3 , \qquad expression ( 41 )$$

$$0.21 \times r / p + 0.01 \leq d / p \leq 0.79 \times r / p + 0.11 , \qquad expression ( 42 )$$

$$1.4 \times r / p - 0.45 \leq d / p \leq 2.23 \times r / p - 0.4 , \qquad expression ( 43 )$$

$$1.09 \times r / p - 0.18 \leq d / p \leq 1.56 \times r / p + 0.27 , \qquad expression ( 44 )$$

$$2.57 \times r / p - 0.01 \leq d / p \leq 3.43 \times r / p - 0.17 , \qquad expression ( 45 )$$

$$4.77 \times r / p - 1.04 \leq d / p \leq 4.13 \times r / p - 0.41 , \qquad expression ( 46 )$$

$$0.6 \times r / p - 0.09 \leq d / p \leq 4 \times r / p - 0.4 , \qquad expression ( 47 )$$

$$1.53 \times r / p - 0.56 \leq d / p \leq 2.27 \times r / p - 0.35 , \qquad expression ( 48 )$$

$$1.09 \times r / p - 0.18 \leq d / p \leq 1.56 \times r / p + 0.28 , \qquad expression ( 49 )$$

$$4.79 \times r / p - 1.09 \leq d / p \leq 4.41 \times r / p - 0.64 , \qquad expression ( 50 )$$

$$1.03 \times r / p - 0.26 \leq d / p \leq 4.39 \times r / p - 0.64 , \qquad expression ( 51 )$$

$$1.4 \times r / p - 0.45 \leq d / p \leq 0.4 \times r / p + 1.58 , \qquad expression ( 52 )$$

$$1.15 \times r / p - 0.24 \leq d / p \leq 1.49 \times r / p + 0.54 , \qquad expression ( 53 )$$

$$5.6 \times r / p - 1.84 \leq d / p \leq 4 \times r / p - 0.3 , \qquad expression ( 54 )$$

$$1.45 \times r / p - 0.5 \leq d / p \leq 4.45 \times r / p - 0.77 , \qquad expression ( 55 )$$

$$1.16 \times r / p - 0.25 \leq d / p \leq 0.35 \times r / p + 2.51 , \qquad expression ( 56 )$$

$$1.77 \times r / p - 0.68 \leq d / p \leq 5.43 \times r / p - 1.43 , \qquad expression ( 57 )$$

$$1.13 \times r / p - 0.22 \leq d / p \leq 3.23 \times r / p + 0.13 , \qquad expression ( 58 )$$

$$2.6 \times r / p - 1.17 \leq d / p \leq 6.6 \times r / p - 2.27 , \qquad expression ( 59 )$$

$$1.27 \times r / p - 0.33 \leq d / p \leq 3.3 \times r / p - 0.0 6. \qquad expression ( 60 )$$

A fifteenth aspect of the present disclosure is a method of manufacturing a display device including: a light-emitting substrate that includes a semiconductor layer that is divided into multiple unit regions and a light-emitting portion that is disposed in the multiple unit regions; and an optical sheet that faces the light-emitting substrate,
the optical sheet includes multiple unit lenses that are arranged in a first direction and that extend in a second direction unparallel with the first direction,
the multiple unit regions are arranged in the first direction and the second direction, and
the method includes an adjustment step of adjusting a radius of curvature r and a distance d depending on a value of w/p, where p is a pitch of the light-emitting portion in the first direction, w is a width of the light-emitting portion in the first direction, r is a radius of curvature of a lens surface of the unit lenses, and d is a distance between the light-emitting portion and the unit lenses.

In the adjustment step, in a case where w/p is 0.01 or more and less than 0.05, the radius of curvature r and the distance d are adjusted such that at least r/p is 0.2 or more and less than 0.525 and an expression (61) below is satisfied, or r/p is 0.525 or more and less than 1.5 and an expression (62) below is satisfied,
in a case where w/p is 0.05 or more and less than 0.1, the radius of curvature r and the distance d are adjusted such that at least r/p is 0.2 or more and less than 0.525 and an expression (63) below is satisfied, or r/p is 0.525 or more and less than 1.5 and an expression (64) below is satisfied,
in a case where w/p is 0.1 or more and less than 0.2, the radius of curvature r and the distance d are adjusted such that at least r/p is 0.2 or more and less than 0.525 and an expression (65) below is satisfied, or r/p is 0.525 or more and less than 1.5 and an expression (66) below is satisfied,
in a case where w/p is 0.2 or more and less than 0.3, the radius of curvature r and the distance d are adjusted such that at least r/p is 0.25 or more and less than 0.525 and an expression (67) below is satisfied, or r/p is 0.525 or more and less than 1.5 and an expression (68) below is satisfied,
in a case where w/p is 0.3 or more and less than 0.4, the radius of curvature r and the distance d are adjusted such that at least r/p is 0.35 or more and less than 0.675 and an expression (69) below is satisfied, or r/p is 0.675 or more and less than 1.5 and an expression (70) below is satisfied,
in a case where w/p is 0.4 or more and less than 0.5, the radius of curvature r and the distance d are adjusted such that at least r/p is 0.4 or more and less than 0.675 and an expression (71) below is satisfied, or r/p is 0.675 or more and less than 1.5 and an expression (72) below is satisfied, and
in a case where w/p is 0.5 or more and less than 0.6, the radius of curvature r and the distance d are adjusted such that at least r/p is 0.5 or more and less than 0.675 and an expression (73) below is satisfied, or r/p is 0.675 or more and less than 1.5 and an expression (74) below is satisfied.

$$\begin{matrix}[ Math 8 ] & \\ 0.21 \times r / p + 0.02 \leq d / p \leq 1 \times r / p - 0.08 , & expression ( 61 )\end{matrix}$$

$$1.17 \times r / p - 0.28 \leq d / p \leq 1.26 \times r / p + 0.13 , \qquad expression ( 62 )$$

$$0.21 \times r / p + 0.02 \leq d / p \leq 1 \times r / p - 0.08 , \qquad expression ( 63 )$$

$$1.17 \times r / p - 0.28 \leq d / p \leq 1.26 \times r / p + 0.14 , \qquad expression ( 64 )$$

$$0.21 \times r / p + 0.01 \leq d / p \leq 0.71 \times r / p + 0.05 , \qquad expression ( 65 )$$

$$1.17 \times r / p - 0.28 \leq d / p \leq 1.26 \times r / p + 0.14 , \qquad expression ( 66 )$$

$$0.29 \times r / p - 0.05 \leq d / p \leq - 0.23 \times r / p + 0.62 , \qquad expression ( 67 )$$

$$1.2 \times r / p - 0.3 \leq d / p \leq 1.2 \times r / p + 0.21 , \qquad expression ( 68 )$$

$$1.43 \times r / p - 0.49 \leq d / p \leq 1.07 \times r / p + 0.45 , \qquad expression ( 69 )$$

$$1.19 \times r / p - 0.28 \leq d / p \leq 1 \times r / p + 0.5 , \qquad expression ( 70 )$$

$$1.77 \times r / p - 0.68 \leq d / p \leq 2.86 \times r / p - 0.23 , \qquad expression ( 71 )$$

$$1.15 \times r / p - 0.23 \leq d / p \leq 0.64 \times r / p + 1.13 , \qquad expression ( 72 )$$

$$2.6 \times r / p - 1.17 \leq d / p \leq 6.6 \times r / p - 2.27 , \qquad expression ( 73 )$$

$$1.27 \times r / p - 0.33 \leq d / p \leq 0.35 \times r / p + 1.7 8. \qquad expression ( 74 )$$

According to the present disclosure, luminance in a direction in which a display device is visually recognized can be increased.

### BRIEF DESCRIPTION OF DRAWINGS

FIG. 1 schematically illustrates an exploded perspective view of elements of a display device.

FIG. 2 is an enlarged sectional view of a portion of a light-emitting substrate of the display device.

FIG. 3 is an enlarged plan view of a portion of the light-emitting substrate of the display device.

FIG. 4 is a sectional view of the display device taken along a line IV-IV in FIG. 3.

FIG. 5 illustrates a situation in which the display device is observed in a second direction.

FIG. 6 illustrates an example of the distribution of luminance in a direction perpendicular to the second direction of the display device.

FIG. 7a illustrates the result of a test in which the distribution of the luminance in the direction perpendicular to the second direction is simulated regarding the display device.

FIG. 7b illustrates the result of a test in which the distribution of the luminance in the direction perpendicular to the second direction is simulated regarding the display device.

FIG. 8 illustrates the result of a test in which the distribution of the luminance in the direction perpendicular to the second direction is simulated regarding the display device.

FIG. 9 illustrates the result of a test in which the distribution of the luminance in the direction perpendicular to the second direction is simulated regarding the display device.

FIG. 10 illustrates the result of a test in which the distribution of the luminance in the direction perpendicular to the second direction is simulated regarding the display device.

FIG. 11 illustrates the result of a test in which the distribution of the luminance in the direction perpendicular to the second direction is simulated regarding the display device.

FIG. 12 illustrates the result of a test in which the distribution of the luminance in the direction perpendicular to the second direction is simulated regarding the display device.

FIG. 13 illustrates the result of a test in which the distribution of the luminance in the direction perpendicular to the second direction is simulated regarding the display device.

FIG. 14 illustrates an example of a light path when light that is emitted from a light-emitting portion of the light-emitting substrate passes through an optical sheet.

FIG. 15 illustrates an example of a light path when light that is emitted from the light-emitting portion of the light-emitting substrate passes through the optical sheet.

FIG. 16 illustrates an example of a light path when light that is emitted from the light-emitting portion of the light-emitting substrate passes through the optical sheet.

FIG. 17a illustrates the result of a test in which the distribution of the luminance in the direction perpendicular to the second direction is simulated regarding the display device.

FIG. 17b illustrates the result of a test in which the distribution of the luminance in the direction perpendicular to the second direction is simulated regarding the display device.

FIG. 17c illustrates the result of a test in which the distribution of the luminance in the direction perpendicular to the second direction is simulated regarding the display device.

FIG. 17d illustrates the result of a test in which the distribution of the luminance in the direction perpendicular to the second direction is simulated regarding the display device.

FIG. 17e illustrates the result of a test in which the distribution of the luminance in the direction perpendicular to the second direction is simulated regarding the display device.

FIG. 17f illustrates the result of a test in which the distribution of the luminance in the direction perpendicular to the second direction is simulated regarding the display device.

FIG. 17g illustrates the result of a test in which the distribution of the luminance in the direction perpendicular to the second direction is simulated regarding the display device.

FIG. 18a illustrates the result of a test in which the distribution of the luminance in the direction perpendicular to the second direction is simulated regarding the display device.

FIG. 18b illustrates the result of a test in which the distribution of the luminance in the direction perpendicular to the second direction is simulated regarding the display device.

FIG. 18c illustrates the result of a test in which the distribution of the luminance in the direction perpendicular to the second direction is simulated regarding the display device.

FIG. 19 illustrates the result of a test in which the distribution of the luminance in the direction perpendicular to the second direction is simulated regarding the display device.

FIG. 20 illustrates the result of a test in which the distribution of the luminance in the direction perpendicular to the second direction is simulated regarding the display device.

FIG. 21 illustrates the result of a test in which the distribution of the luminance in the direction perpendicular to the second direction is simulated regarding the display device.

FIG. 22 illustrates the result of a test in which the distribution of the luminance in the direction perpendicular to the second direction is simulated regarding the display device.

FIG. 23 illustrates the result of a test in which the distribution of the luminance in the direction perpendicular to the second direction is simulated regarding the display device.

FIG. 24a is a sectional view of a section perpendicular to the second direction of a display device according to a second modification.

FIG. 24b illustrates the result of a test in which the distribution of the luminance in the direction perpendicular to the second direction is simulated regarding the display device according to the second modification.

FIG. 25 illustrates an example of an aspect in which the display device is used as a head-up display.

FIG. 26a is a sectional view of a section perpendicular to the second direction of a display device according to a third modification.

FIG. 26b illustrates the result of a test in which the distribution of the luminance in the direction perpendicular to the second direction is simulated regarding the display device according to the third modification.

FIG. 27 illustrates the result of a test in which the distribution of the luminance in the direction perpendicular to the second direction is simulated regarding the display device.

FIG. 28 illustrates the result of a test in which the distribution of the luminance in the direction perpendicular to the second direction is simulated regarding the display device.

FIG. 29 illustrates the result of a test in which the distribution of the luminance in the direction perpendicular to the second direction is simulated regarding the display device.

FIG. 30 illustrates the result of a test in which the distribution of the luminance in the direction perpendicular to the second direction is simulated regarding the display device.

FIG. 31 illustrates the result of a test in which the distribution of the luminance in the direction perpendicular to the second direction is simulated regarding the display device.

FIG. 32 illustrates the result of a test in which the distribution of the luminance in the direction perpendicular to the second direction is simulated regarding the display device.

FIG. 33 illustrates the result of a test in which the distribution of the luminance in the direction perpendicular to the second direction is simulated regarding the display device.

FIG. 34 illustrates the result of a test in which the distribution of the luminance in the direction perpendicular to the second direction is simulated regarding the display device.

FIG. 35 illustrates the result of a test in which the distribution of the luminance in the direction perpendicular to the second direction is simulated regarding the display device.

FIG. 36 illustrates the result of a test in which the distribution of the luminance in the direction perpendicular to the second direction is simulated regarding the display device.

FIG. 37 illustrates the result of a test in which the distribution of the luminance in the direction perpendicular to the second direction is simulated regarding the display device.

FIG. 38 illustrates the result of a test in which the distribution of the luminance in the direction perpendicular to the second direction is simulated regarding the display device.

FIG. 39 illustrates the result of a test in which the distribution of the luminance in the direction perpendicular to the second direction is simulated regarding the display device.

FIG. 40 illustrates the result of a test in which the distribution of the luminance in the direction perpendicular to the second direction is simulated regarding the display device.

### DESCRIPTION OF EMBODIMENTS

An embodiment will now be described with reference to the drawings. FIG. 1 to FIG. 5 illustrate an embodiment. The drawings described later are schematically illustrated. For this reason, the sizes and shapes of components are appropriately exaggerated in order to make understanding easy. Modifications can be appropriately made without departing from a technical idea. In the figures described later, like portions are designated by using like reference signs, and a detailed description is omitted in some cases. Material names and numerals such as dimensions of members described in the present specification are examples according to embodiments, are not limited thereto, and can be appropriately selected and used.

A “plate surface (a sheet surface, or a film surface)” means a surface that extends in a plane direction of a plate member (a sheet member, or a film member) of interest when the plate (sheet or film) member of interest is viewed as a whole and in perspective.

The words “parallel”, “perpendicular”, and “same” and values of lengths and angles that are used for specifying shapes, geometrical conditions, and the degree thereof in the present specification, for example, are not limited by strict meanings and are interpreted to such an extent that the same function can be expected.

FIG. 1 schematically illustrates an exploded perspective view of a display device 1 according to the present invention. In FIG. 1, an illustration for a sealing layer 40, an adhesive layer 50, and a base layer 60 described later is omitted. As illustrated in FIG. 1, the display device 1 includes a light-emitting substrate 10 and an optical sheet 20 that faces the light-emitting substrate 10. The sealing layer 40, the adhesive layer 50, and the base layer 60 are provided between the light-emitting substrate 10 and the optical sheet 20 although this is not illustrated in FIG. 1. In an example illustrated in FIG. 1, the optical sheet 20 has a first surface 20a that faces the light-emitting substrate 10 and a second surface 20b that is opposite the first surface 20a. For example, the display device 1 according to the present embodiment is a display device that includes LEDs, which is called a LED display. In the case described below, the display device 1 is a so-called micro LED display that uses light that is emitted from one or multiple light-emitting diodes as a single pixel.

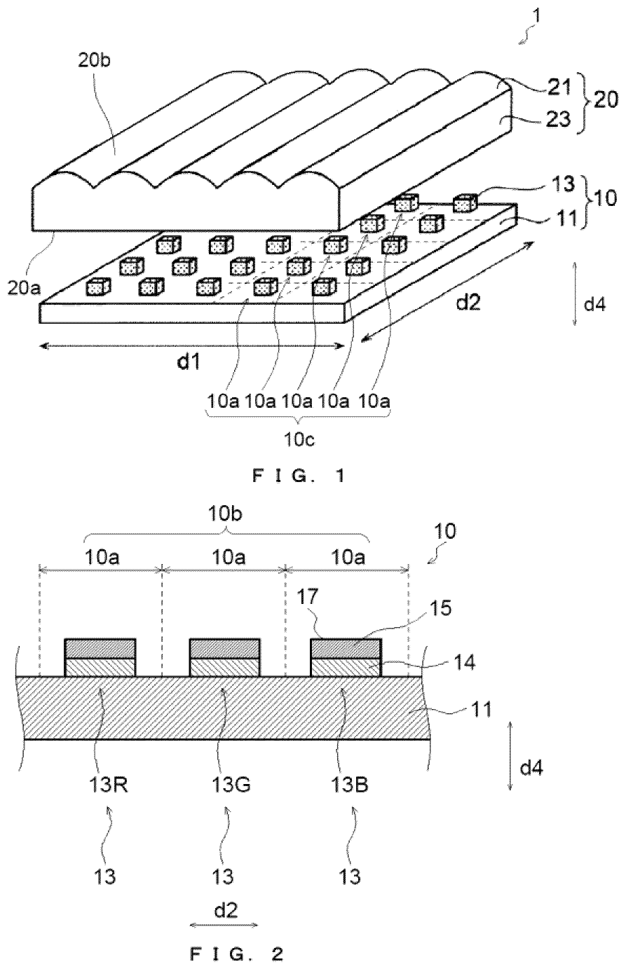

The light-emitting substrate 10 emits light for forming an image. FIG. 2 is an enlarged sectional view of the structure of the light-emitting substrate 10. As illustrated in FIG. 2, the light-emitting substrate 10 includes a semiconductor layer 11 and multiple light-emitting portions 13 that are provided on the semiconductor layer 11. The light-emitting portions 13 include active layers 14 that are in contact with the semiconductor layer 11 and second semiconductor layers 15 that are in contact with the active layers 14. That is, the semiconductor layer 11, the active layers 14, and the second semiconductor layers 15 are stacked in this order at positions on the light-emitting substrate 10 at which the light-emitting portions 13 are provided.

A voltage is applied between the semiconductor layer 11 and the second semiconductor layers 15, and consequently, the active layers 14 can emit light. In order to apply the voltage between the semiconductor layer 11 and the second semiconductor layers 15, the semiconductor layer 11 and the second semiconductor layers 15 include electrodes not illustrated and are connected to an external power source with a circuit that is formed in the semiconductor layer 11 interposed therebetween. Upper surfaces of the light-emitting portions 13 are light-emitting surfaces 17 via which the light that is emitted from the active layers 14 is radiated. In an example illustrated in FIG. 2, surfaces of the second semiconductor layers 15 opposite surfaces that are in contact with the active layers 14 are the light-emitting surfaces 17 via which the light that is emitted from the active layers 14 is radiated.

According to the present embodiment, the light-emitting substrate 10 includes, as the light-emitting portions 13, first light-emitting portions 13R that emit light at a wavelength and second light-emitting portions 13G that emit light at a wavelength that differs from that of the first light-emitting portions 13R. In the example illustrated in FIG. 2, the light-emitting substrate 10 further includes, as the light-emitting portions 13, third light-emitting portions 13B that emit light at a wavelength that differs from those of the first light-emitting portions 13R and the second light-emitting portions 13G. The light-emitting substrate 10 includes, as the multiple light-emitting portions 13, the multiple first light-emitting portions 13R, the multiple second light-emitting portions 13G, and the multiple third light-emitting portions 13B. The first light-emitting portions 13R, the second light-emitting portions 13G, and the third light-emitting portions 13B are light-emitting diodes.

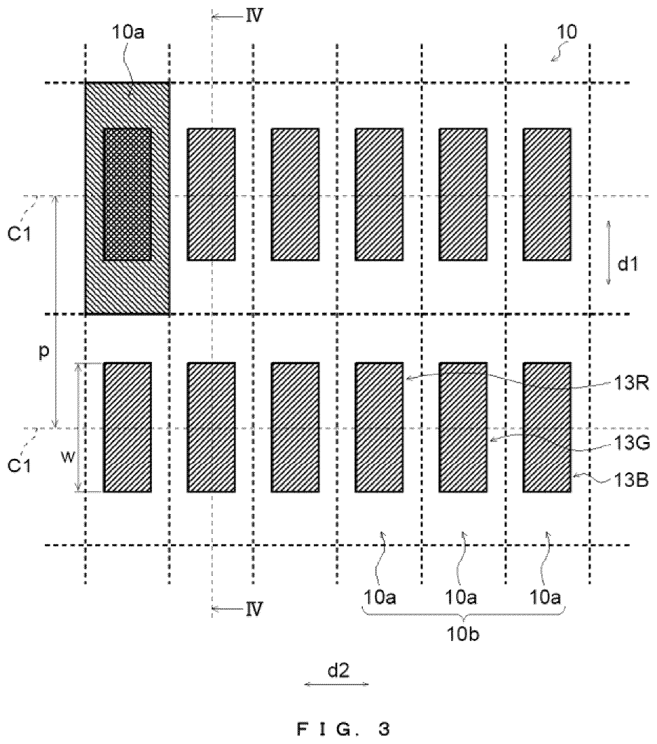

FIG. 3 is an enlarged plan view of a portion of the light-emitting substrate 10 of the display device 1. As illustrated in FIG. 2 and FIG. 3, the semiconductor layer 11 is divided into multiple unit regions 10a. In an example illustrated in FIG. 3, the unit regions 10a are arranged in a first direction d1 and a second direction d2 that is unparallel with the first direction d1. In the illustrated example, the first direction d1 and the second direction d2 are perpendicular to each other. In the illustrated example, the multiple unit regions 10a are arranged so as to be in contact with each other in the first direction d1 and the second direction d2. In FIG. 3, one of the unit regions 10a is illustrated by using oblique lines. The light-emitting portions 13 are disposed in the multiple unit regions 10a. In the illustrated example, the light-emitting portions 13 are disposed in all of the unit regions 10a. One of the light-emitting portions 13 is disposed in one of the unit regions 10a. In the illustrated example, the light-emitting portions 13 are disposed at the centers of the unit regions 10a. The light-emitting portions 13 are arranged at regular intervals in the first direction d1 and the second direction d2.

In the example illustrated in FIG. 3, the light-emitting substrate 10 includes, as the light-emitting portions 13, the first light-emitting portions 13R, the second light-emitting portions 13G, and the third light-emitting portions 13B. In the example illustrated in FIG. 3, the light-emitting substrate 10 includes unit region sets 10b, and one of the unit region sets 10b includes one of the unit regions 10a in which the first light-emitting portion 13R is disposed, one of the unit regions 10a in which the second light-emitting portion 13G is disposed, and one of the unit regions 10a in which the third light-emitting portion 13B is disposed. In the example illustrated in FIG. 3, the light-emitting substrate 10 includes the multiple unit region sets 10b that are arranged in the first direction d1 and the second direction d2. In one of the unit region sets 10b, the unit region 10a in which the first light-emitting portion 13R is disposed, the unit region 10a in which the second light-emitting portion 13G is disposed, and the unit region 10a in which the third light-emitting portion 13B is disposed are arranged in the second direction d2. The unit region sets 10b are pixel regions of the display device 1. The light-emitting portions 13 that are disposed in the unit region sets 10b form pixels of the display device 1.

In the example illustrated in FIG. 3, the widths of the unit regions 10a in the first direction d1 in which multiple unit lenses 21 described later are arranged are greater than the widths of the unit regions 10a in the second direction d2 in which the unit lenses 21 extend. The widths of the light-emitting portions 13 in the first direction d1 are greater than the widths of the light-emitting portions 13 in the second direction d2. The widths of the unit regions 10a in the first direction d1 in which the multiple unit lenses 21 described later may be arranged are less than the widths of the unit regions 10a in the second direction d2 in which the unit lenses 21 extend although this is not illustrated. The widths of the light-emitting portions 13 in the first direction d1 may be less than the widths of the light-emitting portions 13 in the second direction d2.

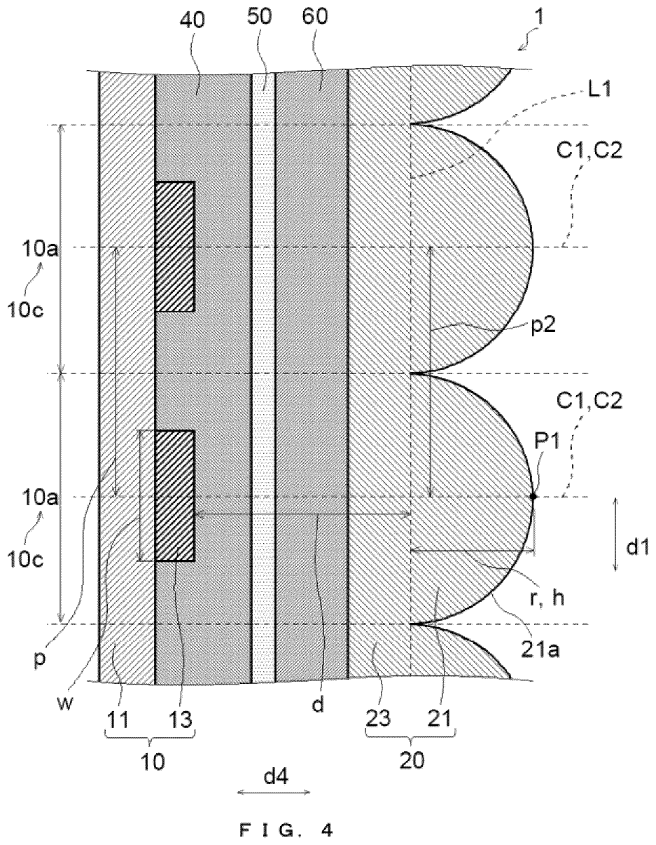

FIG. 4 is a sectional view of the display device 1 taken along a line IV-IV in FIG. 3. As illustrated in FIG. 3 and FIG. 4, p is the pitch of the light-emitting portions 13 in the first direction d1. Dashed lines designated by a symbol of C1 illustrated in FIG. 3 and FIG. 4 represent the centers of the light-emitting portions 13 in the first direction d1. The pitch p of the light-emitting portions 13 corresponds to a distance from the center C1 in the first direction d1 of the light-emitting portion 13 of a unit region 10a to the center C1 in the first direction d1 of the light-emitting portion 13 of a unit region 10a adjacent to the unit region 10a in the first direction d1. For example, the pitch p of the light-emitting portions 13 is 10 μm or more and 2000 μm or less. The pitch p of the light-emitting portions 13 may be 10 μm or more and 500 μm or less. For example, the lengths of the unit regions 10a in the first direction d1 and the second direction d2 are 10 μm or more and 2000 μm or less. In the example illustrated in FIG. 3 and FIG. 4, the lengths of the unit regions 10a in the first direction d1 are equal to the pitch p of the light-emitting portions 13. As illustrated in FIG. 3 and FIG. 4, w is the widths of the light-emitting portions 13 in the first direction d1. In other words, the widths w of the light-emitting portions 13 correspond to the lengths of the light-emitting portions 13 in the first direction d1. For example, the widths w of the light-emitting portions 13 are 1 μm or more and 1200 μm or less. For example, the lengths of the light-emitting portions 13 in the second direction d2 are 1 μm or more and 1200 μm or less.

The optical sheet 20 changes the travelling direction of the light that is emitted from the light-emitting substrate 10. The optical sheet 20 collects the light that is emitted from the light-emitting substrate 10 in a predetermined direction. In particular, the optical sheet 20 illustrated collects the light that is emitted from the light-emitting substrate 10 and that is diffused in a direction perpendicular to the second direction d2 in a predetermined direction perpendicular to the second direction d2. In other words, the optical sheet 20 changes the travelling direction of the light that is emitted from the light-emitting substrate 10 such that the light is seen so as to be collected in the predetermined direction during observation in the second direction d2. The direction in which the optical sheet 20 collects the light that is emitted from the light-emitting substrate 10 is referred to as a light collection direction. The light collection direction is a direction that maximizes luminance in the distribution of the luminance of the light that is emitted from the light-emitting substrate 10 and that passes through the optical sheet 20.

The optical sheet 20 collects the light that is emitted from the light-emitting substrate 10 in a direction in which a user is supposed to visually recognize the display device 1 with high frequency. In some cases, the user of the display device 1 visually recognizes light from the display device 1 via a member that reflects the light. In this case, the light from the display device 1 is emitted toward the member that reflects the light, is reflected at the member that reflects the light, and subsequently reaches the eyes of the user. For example, in the case where the display device 1 is used as a head-up display that projects an image on the windshield of an automobile, the user visually recognizes the light from the display device 1 via the windshield. In this case, the direction of an assumable light path that extends from the display device 1 to the member that reflects the light can be regarded as the direction in which the user is supposed to visually recognize the display device 1. In this case, the optical sheet 20 collects the light that is emitted from the light-emitting substrate 10 in the direction of the assumable light path that extends from the display device 1 to the member that reflects the light.

For example, the direction in which the user is supposed to visually recognize the display device 1 with high frequency can be the front direction of the display device 1. In this case, the optical sheet 20 collects the light that is emitted from the light-emitting substrate 10 and that is diffused in the direction perpendicular to the second direction d2 in the front direction of the display device 1. In other words, the light collection direction in which the optical sheet 20 collects the light that is diffused in the direction perpendicular to the second direction d2 is the front direction of the display device 1. The front direction corresponds to a normal direction d4 to a plate surface of the light-emitting substrate 10. In an example of the optical sheet 20 according to the present embodiment described below, the optical sheet 20 collects the light that is emitted from the light-emitting substrate 10 and that is diffused in the direction perpendicular to the second direction d2 in the front direction of the display device 1.

As illustrated in FIG. 4, the optical sheet 20 includes the multiple unit lenses 21. In an example illustrated in FIG. 4, the optical sheet 20 includes the multiple unit lenses 21 and a body 23. The multiple unit lenses 21 are provided on the body 23. A dashed line designated by a symbol of L1 illustrated in FIG. 4 is an imaginary line that represents the boundary between the multiple unit lenses 21 and the body 23. In the example illustrated in FIG. 4, the unit lenses 21 adjacent to each other in the first direction d1 are in contact with each other. In this case, a plane that passes through positions at which lens surfaces 21a of the unit lenses 21 adjacent to each other are connected to each other and that is perpendicular to the front direction (the normal direction d4) of the display device 1 can be regarded as the boundary L1 between the unit lenses 21 and the body 23. The unit lenses 21 adjacent to each other in the first direction d1 may be spaced from each other as described later although this is not illustrated. In this case, a plane that passes through positions at which the surface of the optical sheet 20 that is formed between the unit lenses 21 adjacent to each other and the lens surfaces 21a of the unit lenses 21 are connected to each other and that is perpendicular to the front direction (the normal direction d4) of the display device 1 can be regarded as the boundary L1 between the unit lenses 21 and the body 23.

For example, the thickness of the optical sheet 20 is 10 μm or more and 4000 μm or less. For example, the refractive index of the optical sheet 20 is 1.4 or more and less than 1.7. The refractive index of the optical sheet 20 is preferably 1.45 or more and less than 1.65, more preferably 1.50 or more and less than 1.60. The refractive index of the optical sheet 20 may be 1.45 or more and less than 1.54. The material of the optical sheet 20 is not particularly limited, but an example thereof is a material that is optically transparent such as resin or glass. Examples of the optical sheet 20 include polyethylene terephthalate, polyolefin, polycarbonate, polyacrylate, polyamide, triacetylcellulose, and glass. For example, the optical sheet 20 may be composed of glass or film the main component of which is polyethylene terephthalate, polyolefin, polycarbonate, polyacrylate, polyamide, or triacetylcellulose. In the example illustrated in FIG. 4, the unit lenses 21 and the body 23 of the optical sheet 20 are formed in a single piece by using the same material. The words “transparent” and “being optically transparent” described herein mean being transparent to such an extent that the optical sheet 20 can be seen through from a surface to another surface via the optical sheet 20. For example, the optical sheet 20 has a visible light transmittance of 30% or more, more preferably, 70% or more. The visible light transmittance is measured at a measurement wavelength ranging from 380 nm to 780 nm by using a spectrophotometer (“UV-3100PC” conforming JIS K 0115 made by SHIMADZU CORPORATION) and is specified as the average value of transmittance at wavelengths.

The unit lenses 21 are elements that refract incident light at the lens surfaces 21a that are the surfaces thereof and change the travelling direction of the light. According to the present embodiment, the unit lenses 21 collect the light that is emitted from the light-emitting substrate 10 and that is diffused in the direction perpendicular to the second direction d2 in the front direction of the display device 1.

The multiple unit lenses 21 are arranged in the first direction d1 and extend in the second direction d2 that is unparallel with the first direction d1. According to the present embodiment, the multiple unit lenses 21 form a linear array lens.

In the illustrated example, the unit lenses 21 linearly extend in the second direction d2. In the illustrated example, the first direction d1 and the second direction d2 are perpendicular to each other. For this reason, the multiple unit lenses 21 are arranged in a direction perpendicular to a direction in which the unit lenses 21 linearly extend.

The multiple unit lenses 21 are disposed so as to face the unit regions 10a. According to the present embodiment, the multiple unit regions 10a are arranged in the first direction d1 and the second direction d2. Columns of the unit regions 10a that are formed by the multiple unit regions 10a illustrated in FIG. 1 that are arranged in the second direction d2 are referred to as unit region second direction columns 10c. According to the present embodiment, one of the unit lenses 21 corresponds to one of the unit region second direction columns 10c during observation in the normal direction d4 to the plate surface of the light-emitting substrate 10. According to the present embodiment, each of the multiple unit lenses 21 corresponds to a respective one of the multiple unit region second direction columns 10c. The phrase the “unit lenses 21 corresponding to the unit region second direction columns 10c” means that the unit lenses 21 overlap, in the normal direction d4, the centers in the first direction d1 of the light-emitting portions 13 in the unit regions 10a that form the unit region second direction columns 10c. According to the present embodiment, as illustrated in FIG. 4, the multiple unit lenses 21 overlap, in the normal direction d4, the centers C1 in the first direction d1 of the light-emitting portions 13 in the unit regions 10a that form the respective unit region second direction columns 10c. In the example illustrated in FIG. 4, the centers C2 in the first direction d1 of the multiple unit lenses 21 overlap the centers C1 in the first direction d1 of the light-emitting portions 13 in the unit regions 10a that form the respective unit region second direction columns 10c.

In the example illustrated in FIG. 3, the unit region 10a in which the first light-emitting portion 13R is disposed and the unit region 10a in which the second light-emitting portion 13G is disposed are arranged in the second direction d2 in which the unit lenses 21 extend as described above. In this case, one of the unit lenses 21 overlaps, in the normal direction d4, the first light-emitting portion 13R and the second light-emitting portion 13G. In the example illustrated in FIG. 3, in particular, the unit region 10a in which the first light-emitting portion 13R is disposed, the unit region 10a in which the second light-emitting portion 13G is disposed, and the unit region 10a in which the third light-emitting portion 13B is disposed are arranged in the second direction d2. In this case, one of the unit lenses 21 overlaps, in the normal direction d4, the first light-emitting portion 13R, the second light-emitting portion 13G, and the third light-emitting portion 13B.

In the illustrated example, the unit lenses 21 change the travelling direction of the light due to refraction at the lens surfaces 21a. The unit lenses 21 have a shape corresponding to a portion of a circle or a portion of an eclipse in a section perpendicular to the longitudinal direction (the second direction d2) thereof. According to the present embodiment, the unit lenses 21 have a shape corresponding to a portion of a circle in a section perpendicular to the second direction d2. In the example illustrated in FIG. 4, the unit lenses 21 have a semicircular shape in a section perpendicular to the second direction d2. According to the present embodiment, the unit lenses 21 refract the light that is emitted from the light-emitting substrate 10 such that the travelling direction of the light changes during observation in the second direction d2.

Here, r is the radii of curvature of the lens surfaces 21a of the unit lenses 21. According to the present embodiment, the radii of curvature r of the lens surfaces 21a of the unit lenses 21 are determined from the shapes of the lens surfaces 21a viewed in sections of the unit lenses 21 perpendicular to the second direction d2. In the example illustrated in FIG. 4, the lens surfaces 21a of the unit lenses 21 have a semicircular shape in a section perpendicular to the second direction d2 as described above. For this reason, the radii of curvature r are equal to the heights h of the unit lenses 21 illustrated in FIG. 4. The heights h of the unit lenses 21 correspond to the distance from vertexes P1 of the unit lenses 21 to the boundary L1 between the unit lenses 21 and the body 23. The vertexes P1 of the unit lenses 21 are points farthest from the light-emitting substrate 10 on the lens surfaces 21a viewed in sections of the unit lenses 21 perpendicular to the second direction d2. In the case where the shapes of the lens surfaces 21a viewed in sections of the unit lenses 21 perpendicular to the second direction d2 differ from a shape corresponding to a portion of a circle, the radii of curvature at the vertexes P1 can be determined as the radii of curvature r although this is not illustrated.

In addition, d is distances between the light-emitting portions 13 and the unit lenses 21.

According to the present embodiment, as illustrated in FIG. 4, the distances d correspond to distances between the light-emitting portions 13 and the boundary L1 between the unit lenses 21 and the body 23.

The radii of curvature r of the lens surfaces 21a of the unit lenses 21 and the distances d between the light-emitting portions 13 and the unit lenses 21 are determined such that the luminance in the direction in which the display device 1 is visually recognized is sufficiently increased depending on the pitch p of the light-emitting portions 13 and the widths w of the light-emitting portions 13. For example, the radii of curvature r are 2 μm or more and 3000 μm or less. For example, the distances d are 1 μm or more and 7000 μm or less.

The lengths (the widths) of the unit lenses 21 in the first direction d1 are appropriately determined depending on, for example, the radii of curvature r. For example, the lengths (the widths) of the unit lenses 21 in the first direction d1 are 10 μm or more and 2000 μm or less. The lengths of the unit lenses 21 in the second direction d2 are appropriately determined depending on, for example, the widths of regions in which the light-emitting portions 13 of the light-emitting substrate 10 are provided.

As illustrated in FIG. 3 and FIG. 4, p2 is the pitch of the unit lenses 21 in the first direction d1. The pitch p2 of the unit lenses 21 corresponds to a distance from the center C2 in the first direction d1 of a unit lens 21 to the center C2 in the first direction d1 of a unit lens 21 adjacent to the unit lens 21 in the first direction d1. For example, the pitch p2 of the unit lenses 21 is 10 μm or more and 2000 μm or less. According to the present embodiment, the pitch p2 of the unit lenses 21 is equal to the pitch p of the light-emitting portions 13.

In the example illustrated in FIG. 4, the unit lenses 21 adjacent to each other in the first direction d1 are in contact with each other. The unit lenses 21 adjacent to each other in the first direction d1 may be spaced from each other although this is not illustrated. In this case, the widths in the first direction d1 of spaces between the unit lenses 21 adjacent to each other in the first direction d1 are appropriately determined depending on the radii of curvature r and the pitch p2 of the unit lenses 21.

The sealing layer 40 covers a surface of the light-emitting substrate 10 on which the light-emitting portions 13 are provided. The sealing layer 40 covers the surface of the light-emitting substrate 10 on which the light-emitting portions 13 are provided and consequently protects the light-emitting portions 13. The sealing layer 40 is composed of a transparent member. The material of the sealing layer 40 is not particularly limited, but examples thereof include resin and silicone. For example, the refractive index of the sealing layer 40 is 1.4 or more and less than 1.8. For example, the thicknesses of portions of the sealing layer 40 that overlap the light-emitting portions 13 in the first direction d1 are 1 μm or more and 7000 μm or less.

The base layer 60 is a layer of a base on which the optical sheet 20 is provided. According to the present embodiment, the body 23 of the optical sheet 20 is provided on the base layer 60 and is supported by the base layer 60. The base layer 60 is composed of a transparent member. The material of the base layer 60 is not particularly limited, but an example thereof is glass. For example, the refractive index of the base layer 60 is 1.4 or more and less than 1.8. For example, the thickness of the base layer 60 is 1 μm or more and 7000 μm or less.

The adhesive layer 50 joins the sealing layer 40 and the base layer 60 to each other due to adhesion. The adhesive layer 50 is composed of a transparent member. The material of the adhesive layer 50 is not particularly limited, but an example thereof is an optically clear adhesive sheet (OCA). The adhesive layer 50 may not be provided, and the sealing layer 40 and the base layer 60 may be joined to each other due to characteristics of the sealing layer 40. For example, the refractive index of the adhesive layer 50 is 1.4 or more and less than 1.8. For example, the thickness of the adhesive layer 50 is 1 μm or more and 7000 μm or less.

In the example illustrated in FIG. 4, the sealing layer 40, the adhesive layer 50, and the base layer 60 are filled between the light-emitting substrate 10 and the optical sheet 20. Consequently, no air layer is formed between the light-emitting substrate 10 and the optical sheet 20. For example, the total thickness of portions of the sealing layer 40, the adhesive layer 50, and the base layer 60 that overlap the light-emitting portions 13 in the first direction d1 is 1 μm or more and 7000 μm or less.

As for the display device 1 according to the present embodiment, the radii of curvature r and the distances d described above are determined such that the luminance in the direction in which the display device 1 is visually recognized is sufficiently increased depending on the pitch p of the light-emitting portions 13 and the widths w of the light-emitting portions 13 described above.

An example of the condition of the luminance according to the present embodiment that enables the luminance in the direction in which the user is supposed to visually recognize the display device 1 to be sufficiently increased will be described. In particular, in order to increase the luminance in the direction in which the user is supposed to visually recognize the display device 1 while light is efficiently used, it is necessary for the display device 1 to collect the light in the direction and to increase the luminance in the direction. In particular, the light is collected in the direction in which the user is supposed to visually recognize the display device 1, and consequently, the luminance in the direction can be relatively increased in comparison with the case where the light is emitted from the light-emitting substrate 10 in a state in which the optical sheet 20 does not overlap the light-emitting substrate 10. For example, the luminance in the light collection direction of the optical sheet 20 is preferably 150% or more of the luminance in the normal direction d4 in the case where the light is emitted from the light-emitting substrate 10 in a state in which the optical sheet 20 does not overlap the light-emitting substrate 10. The luminance in the normal direction d4 in the case where the light is emitted from the light-emitting substrate 10 in a state in which the optical sheet 20 does not overlap the light-emitting substrate 10 can be the average value of the luminance of the light-emitting substrate 10 that the optical sheet 20 does not overlap when an angle θ that is formed with respect to the front direction (the normal direction d4) is in the range of −5° or more and +5° or less.

Also, the user is supposed to visually recognize the display device 1 in a direction that forms an angle with respect to the light collection direction of the optical sheet 20. Based on the supposition, it is necessary for the display device 1 to increase the luminance in a direction when an angle that is formed with respect to the light collection direction has a certain value or less to a certain degree or more.

FIG. 5 illustrates a situation in which the display device 1 is observed in the second direction d2. As for the display device 1, an illustration for the components of the display device 1 such as the light-emitting substrate 10 and the optical sheet 20 is omitted, and only the outline of the display device 1 is illustrated in FIG. 5. A dashed line designated by a symbol of L2 illustrated in FIG. 5 is an imaginary line that is perpendicular to the second direction d2 and that extends in a direction that forms the angle θ with respect to the front direction of the display device 1.

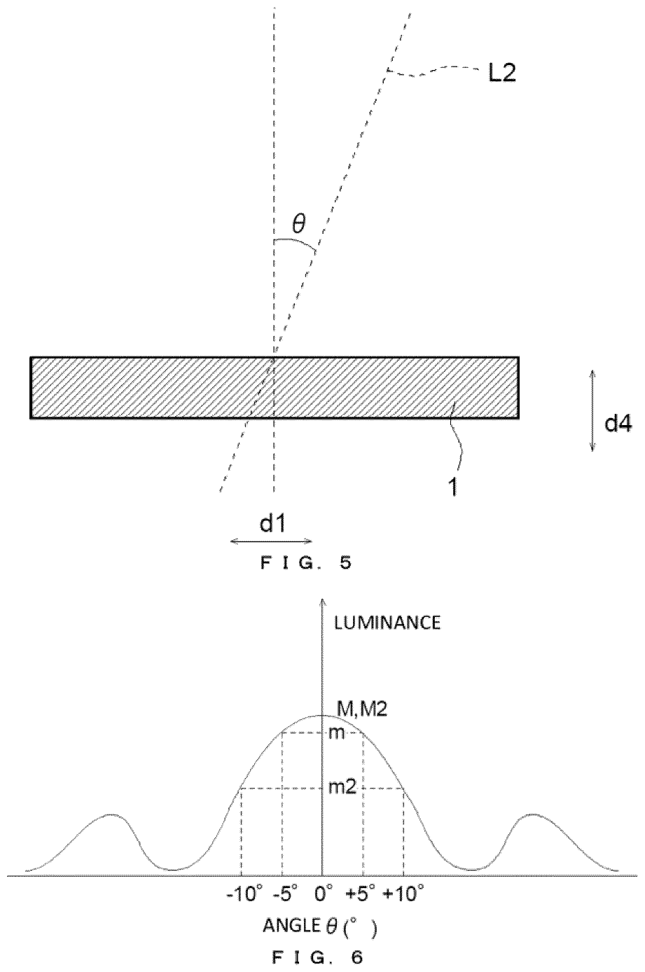

FIG. 6 illustrates an example of the distribution of the luminance in the direction perpendicular to the second direction d2 of the display device 1 illustrated in FIG. 1 to FIG. 5. The vertical axis in FIG. 6 represents the magnitude of the luminance. The horizontal axis in FIG. 6 represents the angle θ (corresponding to an angle that is formed with respect to the light collection direction of the optical sheet 20) that is formed by a direction in which the luminance illustrated in the vertical axis is observed with respect to the front direction of the display device 1.

In the distribution of the luminance illustrated in FIG. 6, M is the maximum value of the luminance when the angle (the angle θ that is formed with respect to the front direction of the display device 1) that is formed with respect to the light collection direction of the optical sheet 20 is in the range of −5° or more and +5° or less. The maximum value M corresponds to the maximum value of the luminance of the display device 1 in a direction that is perpendicular to the second direction d2 when the angle that is formed with respect to the light collection direction of the optical sheet 20 is −5° or more and +5° or less. In the distribution of the luminance illustrated in FIG. 6, m is the minimum value of the luminance when the angle (the angle θ that is formed with respect to the front direction of the display device 1) that is formed with respect to the light collection direction of the optical sheet 20 is in the range of −5° or more and +5° or less. The minimum value m corresponds to the minimum value of the luminance of the display device 1 in a direction that is perpendicular to the second direction d2 when the angle that is formed with respect to the light collection direction of the optical sheet 20 is −5° or more and +5° or less. The minimum value m illustrated in FIG. 6 is preferably 50% or more of the maximum value M. This enables the luminance in the direction in which the user visually recognizes the display device 1 to be ensured even in the case where the user visually recognizes the display device 1 in a direction that forms an angle with respect to the light collection direction of the optical sheet 20. In particular, in the case where the angle that is formed by the direction of the line of sight in which the user visually recognizes the display device 1 during observation in the second direction d2 with respect to the light collection direction of the optical sheet 20 is −5° or more and +5° or less, the luminance in the direction in which the user visually recognizes the display device 1 can be ensured. When the minimum value m is 50% or more of the maximum value M, a difference between the minimum value m and the maximum value M decreases, the uniformness of the luminance when the angle that is formed with respect to the light collection direction of the optical sheet 20 is in the range of −5° or more and +5° or less increases. This enables a change in the luminance that is visually recognized by the user to be decreased, for example, in the case where the direction in which the user visually recognizes the display device 1 is changed when the angle θ is in the range of −5° or more and +5° or less.

When the luminance in the light collection direction of the optical sheet 20 is 150% or more of the luminance of the light-emitting substrate 10 that the optical sheet 20 does not overlap, and the minimum value m described above is 50% or more of the maximum value M as described above, the following effects are exerted. When the luminance in the light collection direction of the optical sheet 20 is 150% or more of the luminance of the light-emitting substrate 10 that the optical sheet 20 does not overlap, the luminance in the light collection direction of the optical sheet 20 can be sufficiently increased. This enables the luminance that is visually recognized by the user to be sufficiently increased in the case where the user visually recognizes the display device 1 in the light collection direction. In addition to this, when the minimum value m described above is 50% or more of the maximum value M, the luminance of the display device 1 in the direction when the angle that is formed with respect to the light collection direction of the optical sheet 20 is −5° or more and +5° or less can be at least 75% or more of the luminance of the light-emitting substrate 10 that the optical sheet 20 does not overlap. This enables the luminance that is visually recognized by the user to be sufficiently increased in the case where the user visually recognizes the display device 1 in the direction when the angle that is formed with respect to the light collection direction of the optical sheet 20 is −5° or more and +5° or less. In the above manner, the visibility of display on the display device 1 in the case where the user visually recognizes the display device 1 in the direction when the angle that is formed with respect to the light collection direction of the optical sheet 20 is −5° or more and +5° or less can be sufficiently ensured.

In the above manner, the condition of the luminance of the display device 1 is preferably determined, for example, such that the luminance of the display device 1 is 150% or more of the luminance of the light-emitting substrate 10 that the optical sheet 20 does not overlap, and the minimum value m described above is 50% or more of the maximum value M, as described above. The display device 1 that satisfies the condition of the luminance described above is preferably used particularly as a head-up display. The display device 1 that satisfies the condition of the luminance described above is preferably used particularly as a head-up display that projects an image on the windshield of an automobile.

The present inventors have diligently researched the display device 1 that can sufficiently increase the luminance in the direction in which the user is supposed to visually recognize the display device 1, particularly, the display device 1 that satisfies the condition of the luminance described above. As a result, the present inventors have found that the display device 1 that satisfies the condition of the luminance described above can be provided in a manner in which the radii of curvature r and the distances d are adjusted depending on the values of the pitch p of the light-emitting portions 13 and the widths w of the light-emitting portions 13 of the light-emitting substrate 10. In particular, it has been found that the display device 1 that satisfies the condition of the luminance described above can be provided in a manner in which the radii of curvature r and the distances d are adjusted depending on the ratio of the width w of each light-emitting portion 13 to the pitch p of the light-emitting portions 13, that is, the value of w/p.

The following description contains the conditions of the values of the radii of curvature r and the distances d that enable the luminance of the display device 1 to be 150% or more of the luminance of the light-emitting substrate 10 that the optical sheet 20 does not overlap and that enable the minimum value m described above to be 50% or more of the maximum value M for every value of w/p. In particular, the following description contains the values of the radii of curvature r and the distances d that enable the condition of the luminance described above to be satisfied regarding the display device 1 configured such that the light collection direction of the optical sheet 20 is the front direction of the display device 1.

In the case where w/p is less than 0.025, what is preferable is that r/p is 0.2 or more and less than 0.525 and an expression (1) below is satisfied, r/p is 0.525 or more and less than 1.5 and an expression (2) below is satisfied, r/p is 0.2 or more and less than 0.525 and an expression (3) below is satisfied, r/p is 0.525 or more and less than 0.725 and an expression (4) below is satisfied, or r/p is 0.725 or more and less than 1.5 and an expression (5) below is satisfied. This enables the luminance of the display device 1 to be 150% or more of the luminance of the light-emitting substrate 10 that the optical sheet 20 does not overlap and enables the minimum value m described above to be 50% or more of the maximum value M.

$$\begin{matrix}[ Math 9 ] & \\ 1.18 \times r / p - 0.29 \leq d / p \leq 1.36 \times r / p - 0.05 & expression ( 1 )\end{matrix}$$

$$1.18 \times r / p - 0.29 \leq d / p \leq 2.08 \times r / p - 0.15 \qquad expression ( 2 )$$

$$2.43 \times r / p + 0.05 \leq d / p \leq 4.64 \times r / p - 0.3 \qquad expression ( 3 )$$

$$4.5 \times r / p - 0.85 \leq d / p \leq 4.64 \times r / p - 0.3 \qquad expression ( 4 )$$

$$4.5 \times r / p - 0.85 \leq d / p \leq 1.2 \times r / p + 2.46 \qquad expression ( 5 )$$

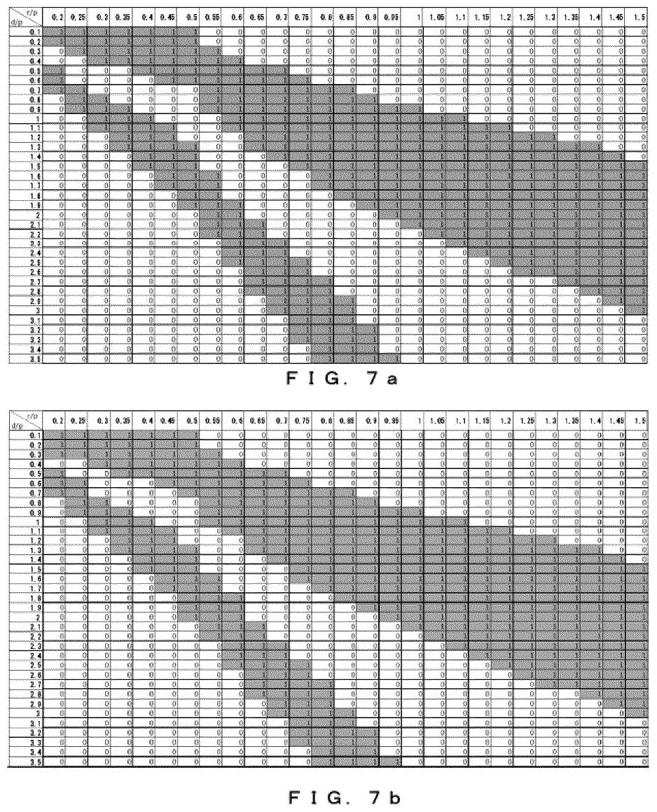

FIG. 7a is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test, the refractive index of the optical sheet 20 is set at 1.50. In the simulation test described later, the radii of curvature r are set on the premise that the lens surfaces 21a of the unit lenses 21 have a shape corresponding to a portion of a circle. FIG. 7a illustrates the result of a test in which the pitch p of the light-emitting portions 13 and the widths w of the light-emitting portions 13 are determined particularly such that the value of w/p is 0.01, the radii of curvature r and the distances d are changed, the values of r/p and d/p are consequently changed, and the distribution of the luminance is simulated. In the table illustrated in FIG. 7a, “1” means that the luminance of the display device 1 is 150% or more of the luminance of the light-emitting substrate 10 that the optical sheet 20 does not overlap, and the minimum value m described above is 50% or more of the maximum value M for the corresponding values of r/p and d/p. For example, “1” is illustrated in a column in the table where r/p is 0.2, and d/p is 0.1. This means that the radii of curvature r and the distances d are determined such that r/p is 0.2, and d/p is 0.1, the distribution of the luminance is simulated, and consequently, the condition of the luminance described above is satisfied. In the table illustrated in FIG. 7a, “0” means that at least the luminance of the display device 1 is not 150% or more of the luminance of the light-emitting substrate 10 that the optical sheet 20 does not overlap, or the minimum value m described above is not 50% or more of the maximum value M for the corresponding values of r/p and d/p. For example, “0” is illustrated in a column in the table where r/p is 0.2, and d/p is 0.3. This means that the radii of curvature r and the distances d are determined such that r/p is 0.2, and d/p is 0.3, the distribution of the luminance is simulated, and consequently, the condition of the luminance described above is not satisfied.

It can be understood also from the result of the test illustrated in FIG. 7a that when at least r/p is 0.2 or more and less than 0.525 and the expression (1) is satisfied, r/p is 0.525 or more and less than 1.5 and the expression (2) is satisfied, r/p is 0.2 or more and less than 0.525 and the expression (3) is satisfied, r/p is 0.525 or more and less than 0.725 and the expression (4) is satisfied, or r/p is 0.725 or more and less than 1.5 and the expression (5) is satisfied, the condition of the luminance described above is satisfied.

In the case where w/p is 0.025 or more and less than 0.075, what is preferable is that at least r/p is 0.2 or more and less than 0.525 and an expression (6) below is satisfied, r/p is 0.525 or more and less than 1.5 and an expression (7) below is satisfied, r/p is 0.2 or more and less than 0.525 and an expression (8) below is satisfied, r/p is 0.525 or more and less than 0.725 and an expression (9) below is satisfied, or r/p is 0.725 or more and less than 1.5 and an expression (10) below is satisfied. This enables the luminance of the display device 1 to be 150% or more of the luminance of the light-emitting substrate 10 that the optical sheet 20 does not overlap and enables the minimum value m described above to be 50% or more of the maximum value M.

$$\begin{matrix}[ Math 10 ] & \\ 1.18 \times r / p - 0.29 \leq d / p \leq 1.36 \times r / p & expression ( 6 )\end{matrix}$$

$$1.18 \times r / p - 0.29 \leq d / p \leq 2.05 \times r / p - 0.03 \qquad expression ( 7 )$$

$$2.57 \times r / p - 0.01 \leq d / p \leq 4.65 \times r / p - 0.3 \qquad expression ( 8 )$$

$$4.67 \times r / p - 0.98 \leq d / p \leq 4.65 \times r / p - 0.3 \qquad expression ( 9 )$$

$$4.67 \times r / p - 0.98 \leq d / p \leq 1.2 \times r / p + 2 \text{.46} \qquad expression ( 10 )$$

FIG. 7b is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test, the refractive index of the optical sheet 20 is set at 1.50. FIG. 7b illustrates the result of a test in which the pitch p of the light-emitting portions 13 and the widths w of the light-emitting portions 13 are determined particularly such that the value of w/p is 0.05, the radii of curvature r and the distances d are changed, the values of r/p and d/p are consequently changed, and the distribution of the luminance is simulated. In the table illustrated in FIG. 7b, “1” and “0” mean the same as “1” and “0” in the table illustrated in FIG. 7a.

It can be understood also from the result of the test illustrated in FIG. 7b that when at least r/p is 0.2 or more and less than 0.525 and the expression (6) is satisfied, r/p is 0.525 or more and less than 1.5 and the expression (7) is satisfied, r/p is 0.2 or more and less than 0.525 and the expression (8) is satisfied, r/p is 0.525 or more and less than 0.725 and the expression (9) is satisfied, or r/p is 0.725 or more and less than 1.5 and the expression (10) is satisfied, the condition of the luminance described above is satisfied.

In the case where w/p is 0.075 or more and less than 0.15, what is preferable is that at least r/p is 0.2 or more and less than 0.375 and an expression (11) below is satisfied, r/p is 0.375 or more and less than 1.5 and an expression (12) below is satisfied, r/p is 0.2 or more and less than 0.725 and an expression (13) below is satisfied, or r/p is 0.725 or more and less than 1.5 and an expression (14) below is satisfied. This enables the luminance of the display device 1 to be 150% or more of the luminance of the light-emitting substrate 10 that the optical sheet 20 does not overlap and enables the minimum value m described above to be 50% or more of the maximum value M.

$$\begin{matrix}[ Math 11 ] & \\ 1.18 \times r / p - 0.29 \leq d / p \leq 4 \times r / p - 0.1 & expression ( 11 )\end{matrix}$$

$$1.18 \times r / p - 0.29 \leq d / p \leq 2.17 \times r / p - 0 \text{.19} \qquad expression ( 12 )$$

$$4.79 \times r / p - 1.09 \leq d / p \leq 5.07 \times r / p - 0 \text{.58} \qquad expression ( 13 )$$

$$4.79 \times r / p - 1.09 \leq d / p \leq 1.8 \times r / p + 1 \text{.94} \qquad expression ( 14 )$$

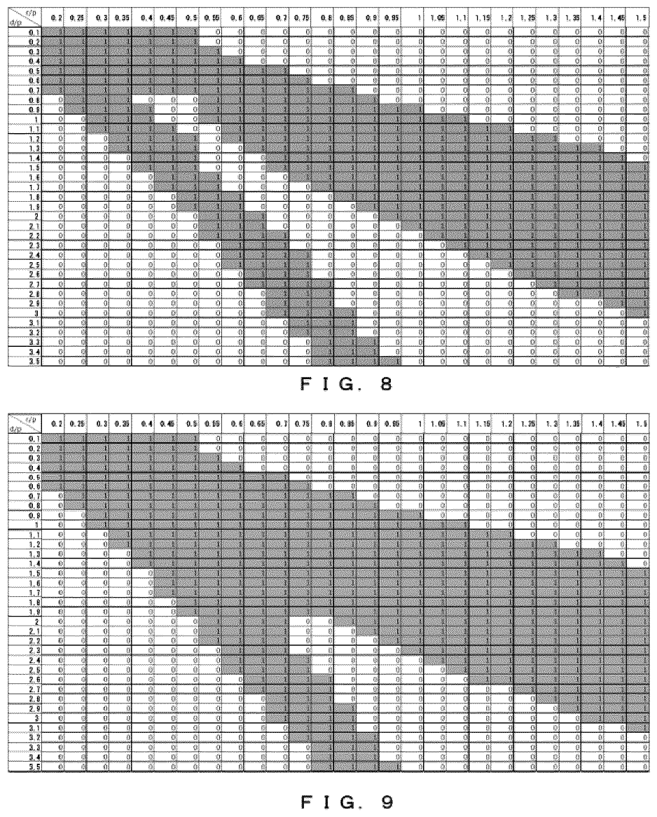

FIG. 8 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test, the refractive index of the optical sheet 20 is set at 1.50. FIG. 8 illustrates the result of a test in which the pitch p of the light-emitting portions 13 and the widths w of the light-emitting portions 13 are determined particularly such that the value of w/p is 0.1, the radii of curvature r and the distances d are changed, the values of r/p and d/p are consequently changed, and the distribution of the luminance is simulated. In the table illustrated in FIG. 8, “1” and “0” mean the same as “1” and “0” in the table illustrated in FIG. 7a.

It can be understood also from the result of the test illustrated in FIG. 8 that when at least r/p is 0.2 or more and less than 0.375 and the expression (11) is satisfied, r/p is 0.375 or more and less than 1.5 and the expression (12) is satisfied, r/p is 0.2 or more and less than 0.725 and the expression (13) is satisfied, or r/p is 0.725 or more and less than 1.5 and the expression (14) is satisfied, the condition of the luminance described above is satisfied.

In the case where w/p is 0.15 or more and less than 0.25, what is preferable is that at least r/p is 0.2 or more and less than 0.725 and an expression (15) below is satisfied, r/p is 0.725 or more and less than 1.5 and an expression (16) below is satisfied, or r/p is 0.2 or more and less than 1.5 and an expression (17) below is satisfied. This enables the luminance of the display device 1 to be 150% or more of the luminance of the light-emitting substrate 10 that the optical sheet 20 does not overlap and enables the minimum value m described above to be 50% or more of the maximum value M.

$$\begin{matrix}[ Math 12 ] & \\ 1.18 \times r / p - 0.29 \leq d / p \leq 4.84 \times r / p - 0.45 & expression ( 15 )\end{matrix}$$

$$1.18 \times r / p - 0.29 \leq d / p \leq 1.69 \times r / p + 0.6 \qquad expression ( 16 )$$

$$5.6 \times r / p - 1.84 \leq d / p \leq 1.8 \times r / p + 1 \text{.94} \qquad expression ( 17 )$$

FIG. 9 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test, the refractive index of the optical sheet 20 is set at 1.50. FIG. 9 illustrates the result of a test in which the pitch p of the light-emitting portions 13 and the widths w of the light-emitting portions 13 are determined particularly such that the value of w/p is 0.2, the radii of curvature r and the distances d are changed, the values of r/p and d/p are consequently changed, and the distribution of the luminance is simulated. In the table illustrated in FIG. 9, “1” and “0” mean the same as “1” and “0” in the table illustrated in FIG. 7a.

It can be understood also from the result of the test illustrated in FIG. 9 that when at least r/p is 0.2 or more and less than 0.725 and the expression (15) is satisfied, r/p is 0.725 or more and less than 1.5 and the expression (16) is satisfied, or r/p is 0.2 or more and less than 1.5 and the expression (17) is satisfied, the condition of the luminance described above is satisfied.

In the case where w/p is 0.25 or more and less than 0.35, what is preferable is that at least r/p is 0.25 or more and less than 0.975 and an expression (18) below is satisfied, or r/p is 0.975 or more and less than 1.5 and an expression (19) below is satisfied. This enables the luminance of the display device 1 to be 150% or more of the luminance of the light-emitting substrate 10 that the optical sheet 20 does not overlap and enables the minimum value m described above to be 50% or more of the maximum value M.

$$\begin{matrix}[ Math 13 ] & \\ 1.22 \times r / p - 0.33 \leq d / p \leq 4.55 \times r / p - 0.42 & expression ( 18 )\end{matrix}$$

$$1.22 \times r / p - 0.33 \leq d / p \leq 1.04 \times r / p + 1 \text{.78} \qquad expression ( 19 )$$

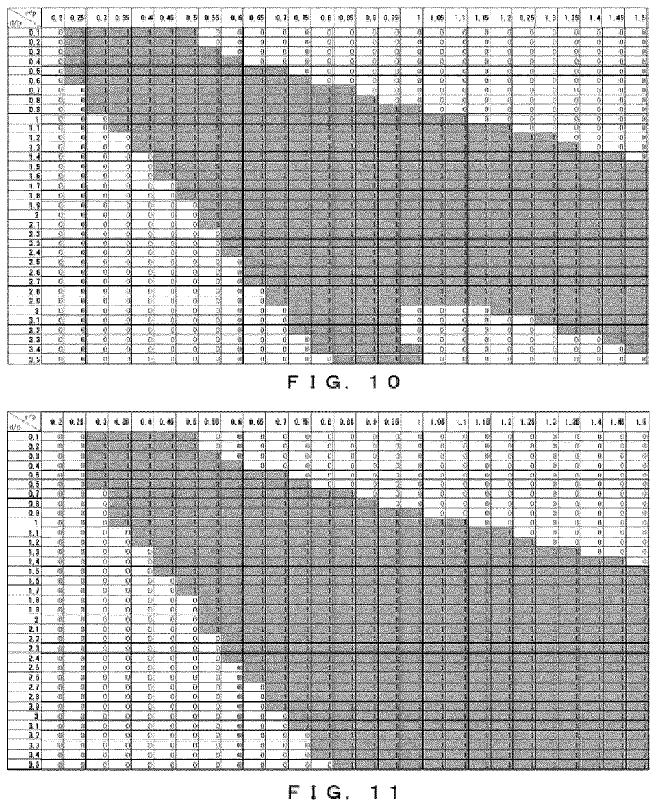

FIG. 10 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test, the refractive index of the optical sheet 20 is set at 1.50. FIG. 10 illustrates the result of a test in which the pitch p of the light-emitting portions 13 and the widths w of the light-emitting portions 13 are determined particularly such that the value of w/p is 0.3, the radii of curvature r and the distances d are changed, the values of r/p and d/p are consequently changed, and the distribution of the luminance is simulated. In the table illustrated in FIG. 10, “1” and “0” mean the same as “1” and “0” in the table illustrated in FIG. 7a.

It can be understood also from the result of the test illustrated in FIG. 10 that when at least r/p is 0.25 or more and less than 0.975 and the expression (18) is satisfied, or r/p is 0.975 or more and less than 1.5 and the expression (19) is satisfied, the condition of the luminance described above is satisfied.

In the case where w/p is 0.35 or more and less than 0.45, what is preferable is that r/p is 0.3 or more and less than 1.5 and an expression (20) below is satisfied. This enables the luminance of the display device 1 to be 150% or more of the luminance of the light-emitting substrate 10 that the optical sheet 20 does not overlap and enables the minimum value m described above to be 50% or more of the maximum value M.

$$\begin{matrix}[ Math 14 ] & \\ 1.26 \times r / p - 0.37 \leq d / p \leq 5.56 \times r / p - 1 \text{.01} & expression ( 20 )\end{matrix}$$

FIG. 11 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test, the refractive index of the optical sheet 20 is set at 1.50. FIG. 11 illustrates the result of a test in which the pitch p of the light-emitting portions 13 and the widths w of the light-emitting portions 13 are determined particularly such that the value of w/p is 0.4, the radii of curvature r and the distances d are changed, the values of r/p and d/p are consequently changed, and the distribution of the luminance is simulated. In the table illustrated in FIG. 11, “1” and “0” mean the same as “1” and “0” in the table illustrated in FIG. 7a.

It can be understood also from the result of the test illustrated in FIG. 11 that when r/p is 0.3 or more and less than 1.5 and the expression (20) is satisfied, the condition of the luminance described above is satisfied.

In the case where w/p is 0.45 or more and less than 0.55, what is preferable is that r/p is 0.4 or more and less than 1.5 and an expression (21) below is satisfied. This enables the luminance of the display device 1 to be 150% or more of the luminance of the light-emitting substrate 10 that the optical sheet 20 does not overlap and enables the minimum value m described above to be 50% or more of the maximum value M.

$$\begin{matrix}[ Math 15 ] & \\ 1.28 \times r / p - 0.39 \leq d / p \leq 5.83 \times r / p - 1 \text{.29} & expression ( 21 )\end{matrix}$$

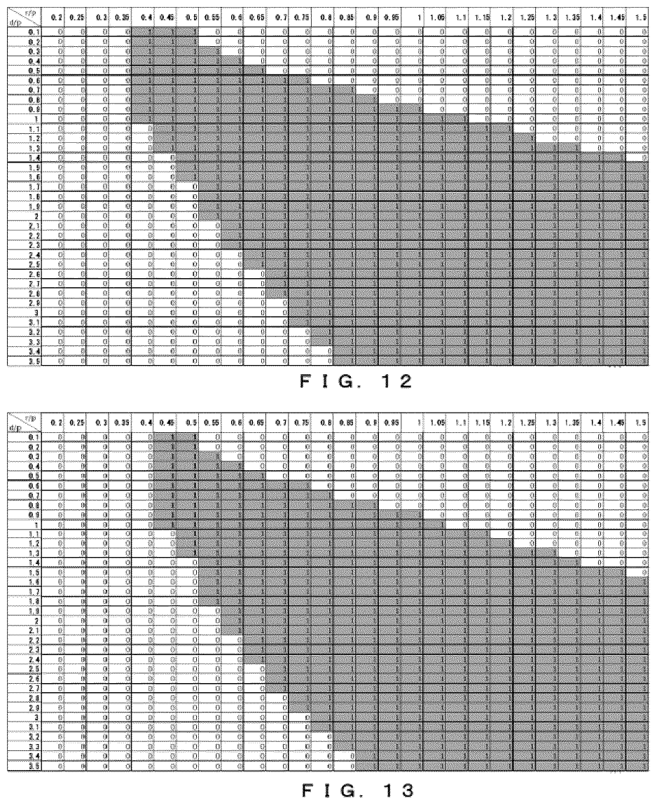

FIG. 12 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test, the refractive index of the optical sheet 20 is set at 1.50. FIG. 12 illustrates the result of a test in which the pitch p of the light-emitting portions 13 and the widths w of the light-emitting portions 13 are determined particularly such that the value of w/p is 0.5, the radii of curvature r and the distances d are changed, the values of r/p and d/p are consequently changed, and the distribution of the luminance is simulated. In the table illustrated in FIG. 12, “1” and “0” mean the same as “1” and “0” in the table illustrated in FIG. 7a.

It can be understood also from the result of the test illustrated in FIG. 12 that when r/p is 0.4 or more and less than 1.5 and the expression (21) is satisfied, the condition of the luminance described above is satisfied.

In the case where w/p is 0.55 or more and less than 0.65, what is preferable is that r/p is 0.45 or more and less than 1.5 and an expression (22) below is satisfied. This enables the luminance of the display device 1 to be 150% or more of the luminance of the light-emitting substrate 10 that the optical sheet 20 does not overlap and enables the minimum value m described above to be 50% or more of the maximum value M.

$$\begin{matrix}[ Math 16 ] & \\ 1.38 \times r / p - 0.45 \leq d / p \leq 5.8 \times r / p - 1 \text{.48} & expression ( 22 )\end{matrix}$$

FIG. 13 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test, the refractive index of the optical sheet 20 is set at 1.50. FIG. 13 illustrates the result of a test in which the pitch p of the light-emitting portions 13 and the widths w of the light-emitting portions 13 are determined particularly such that the value of w/p is 0.6, the radii of curvature r and the distances d are changed, the values of r/p and d/p are consequently changed, and the distribution of the luminance is simulated. In the table illustrated in FIG. 13, “1” and “0” mean the same as “1” and “0” in the table illustrated in FIG. 7a.

It can be understood also from the result of the test illustrated in FIG. 13 that when r/p is 0.45 or more and less than 1.5 and the expression (22) is satisfied, the condition of the luminance described above is satisfied.

r/p may be determined to be 0.2 or more. r/p may be determined to be 1.5 or less. d/p may be determined to be 0.1 or more. d/p may be determined to be 3.5 or less.

As for the reason why the display device 1 that satisfies the condition of the luminance described above can be provided in a manner in which the radii of curvature r and the distances d are adjusted depending on the values of the pitch p of the light-emitting portions 13 and the widths w of the light-emitting portions 13 as described above, conceivable matters will be described.

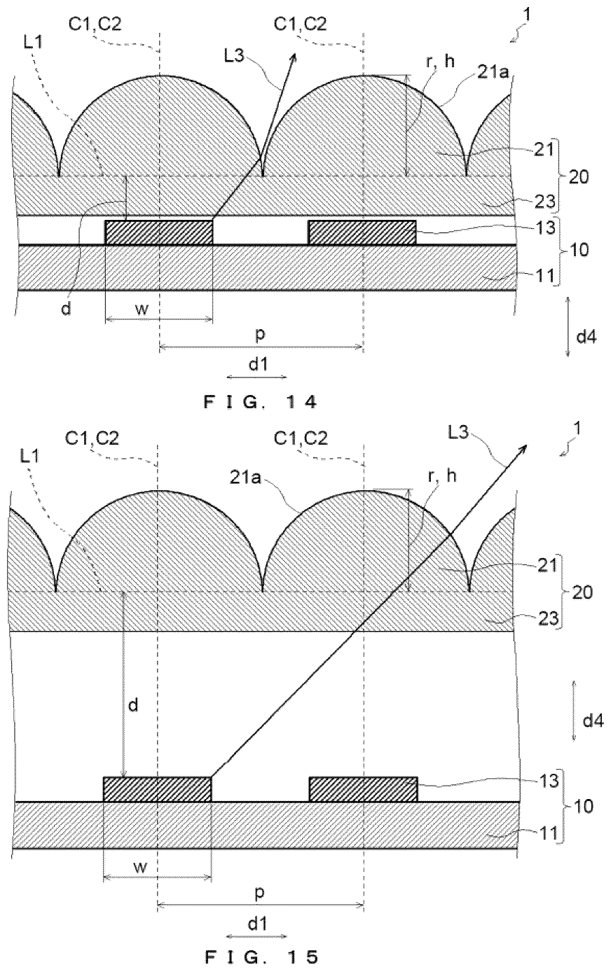

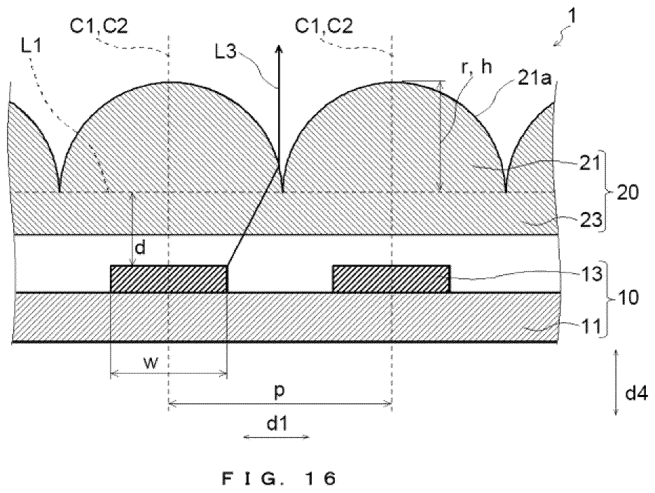

FIG. 14 to FIG. 16 illustrate examples of a light path when the light that is emitted from the light-emitting portions 13 of the light-emitting substrate 10 passes through the optical sheet 20. In FIG. 14 to FIG. 16, an illustration for the sealing layer 40, the adhesive layer 50, and the base layer 60 is omitted. FIG. 14 to FIG. 16 illustrate a situation in which the display device 1 is observed in the second direction d2. FIG. 14 illustrates an example of the light path in the case where the ratios of the distances d to the pitch p of the light-emitting portions 13 are particularly low. FIG. 15 illustrates an example of the light path in the case where the ratios of the distances d to the pitch p of the light-emitting portions 13 are particularly high. FIG. 16 illustrates an example of the light path in the case where the ratios of the distances d to the pitch p of the light-emitting portions 13 are higher than the ratios in FIG. 14 and are lower than the ratios in FIG. 15. Lines designated by a symbol of L3 illustrated in FIG. 14 to FIG. 16 represent light paths in the figures.

In the example illustrated in FIG. 14, the ratios of the distances d to the pitch p of the light-emitting portions 13 are particularly low. For this reason, in the example illustrated in FIG. 14, part of the light that is emitted from the light-emitting portions 13 reaches the lens surfaces 21a at a small incident angle. For this reason, in the example illustrated in FIG. 14, the unit lenses 21 cannot collect the part of the light in the front direction.

In the example illustrated in FIG. 15, the ratios of the distances d to the pitch p of the light-emitting portions 13 are particularly high. For this reason, part of the light that is emitted from the light-emitting portions 13 also reaches unit lenses 21 other than the unit lenses 21 that are located in the front direction of the light-emitting portions 13. For this reason, in the example illustrated in FIG. 15, the unit lenses 21 cannot collect the part of the light in the front direction.

In contrast, in the example illustrated in FIG. 16, the ratios of the distances d to the pitch p of the light-emitting portions 13 are higher than the ratios in FIG. 14 and are lower than the ratios in FIG. 15. For this reason, it is thought that in the example illustrated in FIG. 16, the amount of the light that reaches the lens surfaces 21a at a small incident angle is smaller than that in the example illustrated in FIG. 14 and that the amount of the light that reaches unit lenses 21 other than the unit lenses 21 that are located in the front direction of the light-emitting portions 13 is smaller than that in the example illustrated in FIG. 15. Consequently, it is thought that the effect of collecting the light that is emitted from the light-emitting portions 13 in the front direction in the example illustrated in FIG. 16 is stronger than that in the examples illustrated in FIG. 14 and FIG. 15.

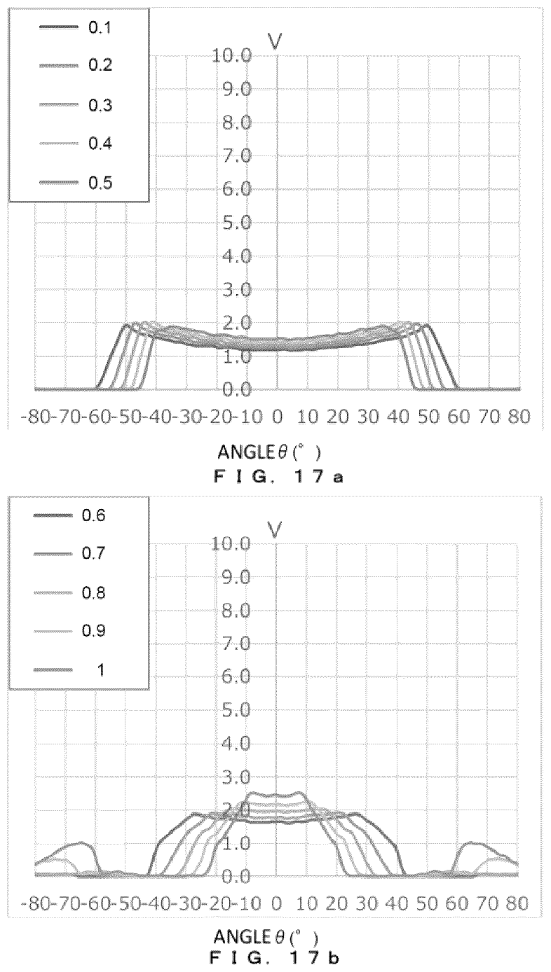

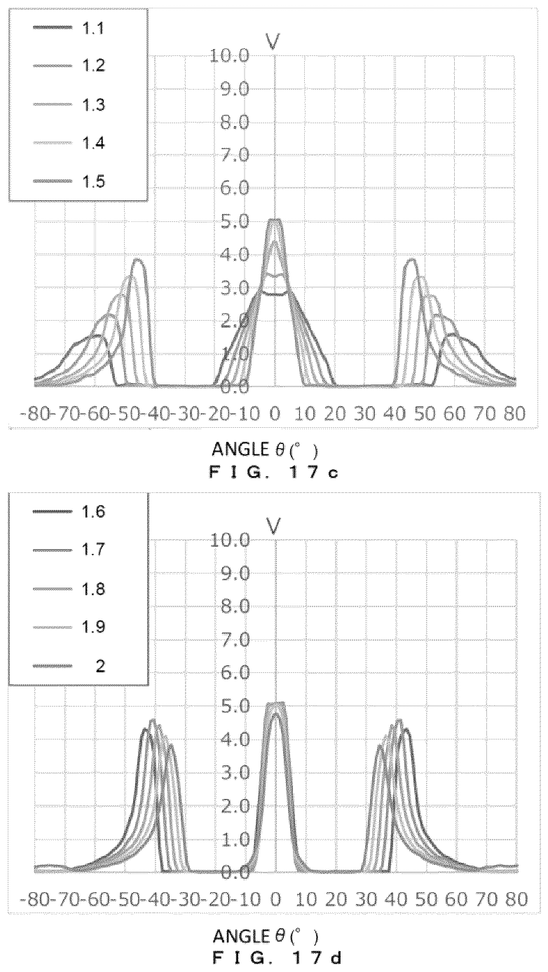

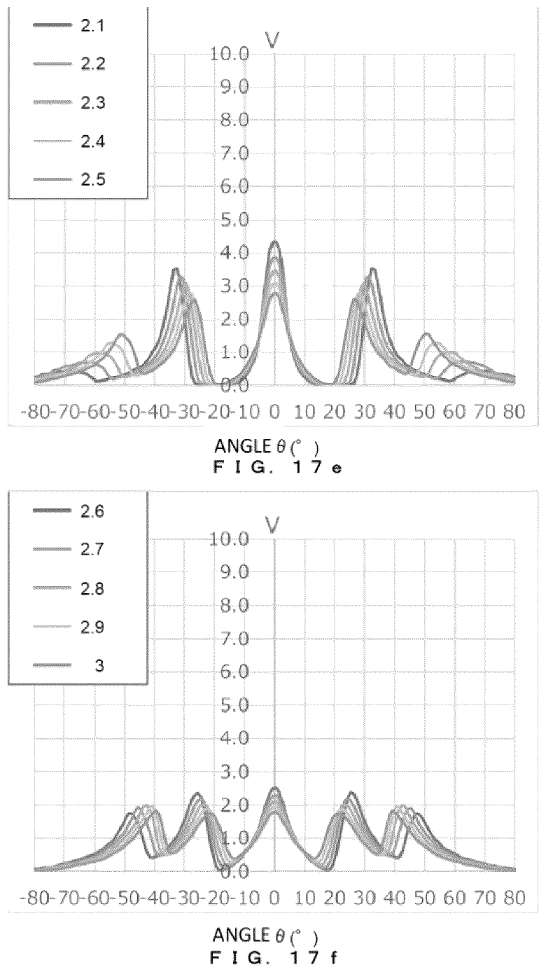

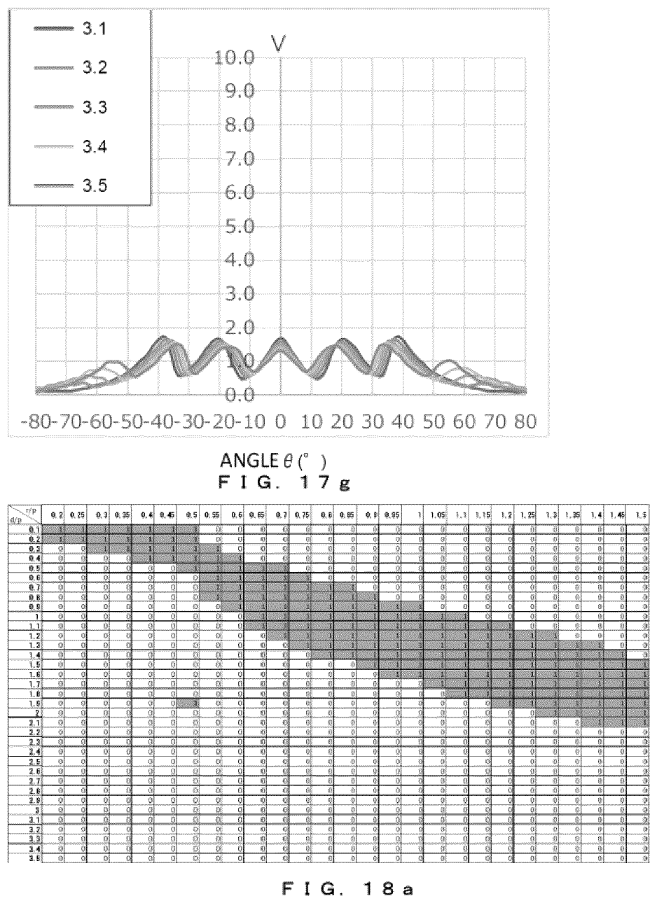

FIG. 17a to FIG. 17g are graphs illustrating the result of a test in which the pitch p of the light-emitting portions 13, the widths w of the light-emitting portions 13, the radii of curvature r, and the distances d are appropriately set regarding the display device 1 illustrated in FIG. 1 to FIG. 5, and the distribution of the luminance in the direction perpendicular to the second direction d2 is simulated. In the simulation test, the refractive index of the optical sheet 20 is set at 1.50. The vertical axis designated by a symbol of V in FIG. 17a to FIG. 17g represents the magnitude of the luminance by using a ratio to the average value of the luminance of the light-emitting substrate 10 that the optical sheet 20 does not overlap when the angle θ that is formed with respect to the front direction (the normal direction d4) is in the range of −5° or more and +5° or less. The horizontal axis in FIG. 17a to FIG. 17g represents the angle θ (′) that is formed by the direction in which the luminance that is represented by the vertical axis is observed with respect to the front direction (the normal direction d4) of the display device 1.

FIG. 17a to FIG. 17g illustrate the result of the test in which when the pitch p of the light-emitting portions 13, the widths w of the light-emitting portions 13, and the radii of curvature r have constant values, and the distances d are changed, the distribution of the luminance of the display device 1 in the direction perpendicular to the second direction d2 is simulated. FIG. 17a to FIG. 17g illustrate the result of the test in which the pitch p of the light-emitting portions 13, the widths w of the light-emitting portions 13, and the radii of curvature r are determined such that the value of w/p is 0.2, and the value of r/p is 0.7, the distances d are changed, the value of d/p is consequently changed, and the distribution of the luminance is simulated.

Five curved lines illustrated in FIG. 17a represent the distribution of the luminance when the distances d are determined such that the value of d/p is 0.1, 0.2, 0.3, 0.4, or 0.5. Five curved lines illustrated in FIG. 17b represent the distribution of the luminance when the distances d are determined such that the value of d/p is 0.6, 0.7, 0.8, 0.9, or 1. Five curved lines illustrated in FIG. 17c represent the distribution of the luminance when the distances d are determined such that the value of d/p is 1.1, 1.2, 1.3, 1.4, or 1.5. Five curved lines illustrated in FIG. 17d represent the distribution of the luminance when the distances d are determined such that the value of d/p is 1.6, 1.7, 1.8, 1.9, or 2. Five curved lines illustrated in FIG. 17e represent the distribution of the luminance when the distances d are determined such that the value of d/p is 2.1, 2.2, 2.3, 2.4, or 2.5. Five curved lines illustrated in FIG. 17f represent the distribution of the luminance when the distances d are determined such that the value of d/p is 2.6, 2.7, 2.8, 2.9, or 3. Five curved lines illustrated in FIG. 17g represent the distribution of the luminance when the distances d are determined such that the value of d/p is 3.1, 3.2, 3.3, 3.4, or 3.5.

Referring to FIG. 17a to FIG. 17g, the luminance in the front direction in FIG. 17a in which the value of d/p is particularly small is lower than that in FIG. 17d. The luminance in a direction that is shifted from the front direction in FIG. 17a is the maximum. As illustrated in FIG. 14, it is thought that this reflects that part of the light that is emitted from the light-emitting portions 13 reaches the lens surfaces 21a at a small incident angle, and accordingly, the unit lenses 21 cannot collect the part of the light in the front direction.

In FIG. 17g in which the value of d/p is particularly large, the luminance in the front direction is lower than that in FIG. 17d. The distribution of the luminance illustrated in FIG. 17a has a local maximum value of the luminance in the front direction and has a local maximum value of the luminance in multiple directions that are shifted from the front direction. As illustrated in FIG. 15, it is thought that this reflects that part of the light that is emitted from the light-emitting portions 13 reaches also unit lenses 21 other than the unit lenses 21 that are located in the front direction of the light-emitting portions 13.

In contrast, in FIG. 17d in which the value of d/p is larger than that in FIG. 17a and is smaller than that in FIG. 17g, the luminance in the front direction is higher than that in FIG. 17a and FIG. 17g. It is thought that this reflects that the effect of collecting the light that is emitted from the light-emitting portions 13 in the front direction in FIG. 17d is stronger than that in FIG. 17a and FIG. 17g as in the example illustrated in FIG. 16. The condition of the value of d/p that increases the effect of collecting the light that is emitted from the light-emitting portions 13 in the front direction changes depending on the values of w/p and the radii of curvature r.

What is considered herein is the condition of the luminance of the display device 1 that enables the luminance of the display device 1 to be 150% or more of the luminance of the light-emitting substrate 10 that the optical sheet 20 does not overlap and that enables the minimum value m described above to be 50% or more of the maximum value M. As illustrated in FIG. 16 and FIG. 17d, the effect of collecting the light in the light collection direction (the front direction) is preferably strong in order for the luminance of the display device 1 to be 150% or more of the luminance of the light-emitting substrate 10 that the optical sheet 20 does not overlap. As illustrated in FIG. 14, FIG. 15, FIG. 17a, and FIG. 17g, the effect of collecting the light in the light collection direction is preferably weak in order for the minimum value m described above to be 50% or more of the maximum value M. The optical sheet 20 according to the present embodiment may be designed such that the effect of collecting the light in the light collection direction is decreased on purpose in consideration for the condition of the luminance.

The radii of curvature r and the distances d are adjusted depending on the values of the pitch p of the light-emitting portions 13 and the widths w of the light-emitting portions 13 as described above, and consequently, the degree of the effect of collecting the light due to the light optical sheet 20 can be changed. For example, the radii of curvature r and the distances d are adjusted depending on the values of the pitch p of the light-emitting portions 13 and the widths w of the light-emitting portions 13, and consequently, the effect of collecting the light in the light collection direction can be decreased. The adjustment enables the degree of the effect of collecting the light due to the optical sheet 20 to be increased to such an extent that the luminance of the display device 1 is 150% or more of the luminance of the light-emitting substrate 10 that the optical sheet 20 does not overlap. The degree of the effect of collecting the light due to the optical sheet 20 can be decreased to such an extent that the minimum value m described above is 50% or more of the maximum value M. It is thought that this enables the display device 1 that satisfies the condition of the luminance described above to be provided in a manner in which the radii of curvature r and the distances d are adjusted depending on the values of the pitch p of the light-emitting portions 13 and the widths w of the light-emitting portions 13 as described above. In particular, as for the display device 1 configured such that the light collection direction of the optical sheet 20 is the front direction of the display device 1, it is thought that the condition of the luminance described above is satisfied. In the above manner, the pitch p of the light-emitting portions 13, the widths w of the light-emitting portions 13, the radii of curvature r, and the distances d are adjusted as described above, and consequently, the luminance in a direction that forms an angle with respect to the light collection direction can be ensured while the luminance in the light collection direction is increased.

In particular, the present inventors have found from the result of the simulation test that adjustments in the pitch p of the light-emitting portions 13, the widths w of the light-emitting portions 13, the radii of curvature r, and the distances d as described above tend to ensure the luminance in a direction that forms an angle with respect to the light collection direction while the luminance in the light collection direction is increased when the refractive index of the optical sheet 20 is within the typical range of the refractive index of the optical sheet 20 that is included in the display device 1. In particular, it has been found that in the case where the material of the optical sheet 20 is resin, the luminance in a direction that forms an angle with respect to the light collection direction tends to be stably ensured while the luminance in the light collection direction is increased regardless of the kind of the resin. In addition, the present inventors have found from the result of the simulation test that the adjustments in the pitch p of the light-emitting portions 13, the widths w of the light-emitting portions 13, the radii of curvature r, and the distances d as described above tend to ensure the luminance in a direction that forms an angle with respect to the light collection direction while the luminance in the light collection direction is increased, provided that a layer that is provided between the light-emitting substrate 10 and the optical sheet 20 is a layer that is typically provided for the display device 1. In particular, it has been found that in the case where no air layer is formed between the light-emitting substrate 10 and the optical sheet 20, the luminance in a direction that forms an angle with respect to the light collection direction tends to be stably ensured while the luminance in the light collection direction is increased regardless of the kind of the layer that is provided between the light-emitting substrate 10 and the optical sheet 20. In particular, it has been found that in the case where the sealing layer 40, the adhesive layer 50, and the base layer 60 described above are provided between the light-emitting substrate 10 and the optical sheet 20, and the thicknesses and refractive indexes of the sealing layer 40, the adhesive layer 50, and the base layer 60 are in the range described above, the luminance in a direction that forms an angle with respect to the light collection direction tends to be stably ensured while the luminance in the light collection direction is increased.

As for existing techniques, an increase in the effect of collecting light in the light collection direction is pursued regarding optical sheets. However, the optical sheet 20 according to the present embodiment may be designed such that the effect of collecting the light in the light collection direction is decreased as described above. As for the optical sheet 20 according to the present embodiment, the effect of collecting the light in the light collection direction may be decreased in a manner in which the pitch p of the light-emitting portions 13, the widths w of the light-emitting portions 13, the radii of curvature r, and the distances d are adjusted. The optical sheet 20 according to the present embodiment, which includes such an idea, differs from the existing techniques.

The display device 1 according to the present embodiment can also exert the following effects by adjusting the radii of curvature r and the distances d depending on the values of the pitch p of the light-emitting portions 13 and the widths w of the light-emitting portions 13 as described above. As for the display device 1 that has the strong effect of collecting the light in the light collection direction, as illustrated in, for example, FIG. 17d, the width of a peak corresponding to the light collection direction of the optical sheet 20 decreases in the distribution of the luminance in the direction perpendicular to the second direction. For this reason, if the position of the optical sheet 20 with respect to the light-emitting substrate 10 is changed in the first direction d1, the luminance in the light collection direction of the optical sheet 20 greatly decreases even when the degree of the shift is low. As for the display device 1 configured such that the radii of curvature r and the distances d are adjusted depending on the values of the pitch p of the light-emitting portions 13 and the widths w of the light-emitting portions 13 as described above, however, the effect of collecting the light in the light collection direction is inhibited from being too strong. For this reason, even through the position of the optical sheet 20 with respect to the light-emitting substrate 10 is changed, the luminance in the light collection direction of the optical sheet 20 is unlikely to decrease. Consequently, the precision of adjustment in position required when the optical sheet 20 is mounted to the light-emitting substrate 10 is kept low.

In addition, the display device 1 according to the present embodiment can exert the following effects by adjusting the radii of curvature r and the distances d depending on the values of the pitch p of the light-emitting portions 13 and the widths w of the light-emitting portions 13 as described above. In the case that is particularly thought herein, one of the unit lenses 21 overlaps, in the normal direction d4, the second light-emitting portions 13G that emit light at a wavelength that differs from those of the first light-emitting portions 13R and the first light-emitting portions 13R. Here, the refractive indexes of the lens surfaces 21a of the unit lenses 21 change depending on the wavelength of the light. For this reason, the degree of the effect of collecting the light in the light collection direction due to the optical sheet 20 changes depending on the wavelength of the light. Consequently, the luminance in the light collection direction after the light passes through the optical sheet 20 changes, for example, even when the first light-emitting portions 13R and the second light-emitting portions 13G emit the light such that the luminance in the light collection direction is the same. As the effect of collecting the light in the light collection direction itself increases, the change in the effect of collecting the light depending on the wavelength of the light is more likely to increase. As for the display device 1 configured such that the radii of curvature r and the distances d are adjusted depending on the values of the pitch p of the light-emitting portions 13 and the widths w of the light-emitting portions 13 as described above, however, the effect of collecting the light in the light collection direction can be inhibited from being too strong. For this reason, the change in the effect of collecting the light depending on the wavelength of the light is kept small. This enables the percentage of the luminance for every wavelength of the light that is emitted from the display device 1 can be sufficiently controlled without consideration of the change in the effect of collecting the light depending on the wavelength of the light, for example, when the light that is emitted from the first light-emitting portions 13R and second light-emitting portions 13G is controlled.

An example of a method of manufacturing the display device 1 described above will now be described. The light-emitting substrate 10 is first prepared. The sealing layer 40 is formed so as to cover a surface on which the light-emitting portions 13 of the light-emitting substrate 10 are provided.

The optical sheet 20 is manufactured. When the optical sheet 20 is manufactured, the optical sheet 20 that includes the base layer 60 and the body 23 and the multiple unit lenses 21 that are provided on the base layer 60 is prepared. The optical sheet 20 that includes the body 23 and the unit lenses 21 can be manufactured in a manner in which the body 23 and the unit lenses 21 are integrally manufactured by shaping resin. The optical sheet 20 may be provided on the base layer 60 in a manner in which the multiple unit lenses 21 are provided on the body 23 after the body 23 is provided on the base layer 60. In this case, the body 23 may be manufactured by shaping resin, may be manufactured by performing a mechanical process such as cutting on a resin plate material, or may be manufactured by using a combination of resin shaping and a mechanical process such as cutting.

Subsequently, the sealing layer 40 that is formed so as to cover the surface on which the light-emitting portions 13 of the light-emitting substrate 10 are provided and the base layer 60 on which the optical sheet 20 is provided are joined to each other with the adhesive layer 50 interposed therebetween. Consequently, the display device 1 illustrated in FIG. 1 to FIG. 5 is manufactured.

In the method of manufacturing the display device 1 according to the present embodiment, the radii of curvature r and the distances d are adjusted depending on the value of w/p as described above. That is, the method of manufacturing the display device 1 according to the present embodiment includes an adjustment step of adjusting the radii of curvature r and the distances d depending on the value of w/p. The radii of curvature r can be adjusted in a manner in which the radii of curvature r of the unit lenses 21 to be manufactured are adjusted when the optical sheet 20 is manufactured. The distances d can be adjusted in a manner in which the thickness of at least the sealing layer 40, the adhesive layer 50, the base layer 60, or the body 23 of the optical sheet 20 to be manufactured is adjusted.

At the adjustment step according to the present embodiment, in the case where w/p is less than 0.025, the radii of curvature r and the distances d are adjusted such that at least r/p is 0.2 or more and less than 0.525 and the expression (1) described above is satisfied, r/p is 0.525 or more and less than 1.5 and the expression (2) described above is satisfied, r/p is 0.2 or more and less than 0.525 and the expression (3) described above is satisfied, r/p is 0.525 or more and less than 0.725 and the expression (4) described above is satisfied, or r/p is 0.725 or more and less than 1.5 and the expression (5) described above is satisfied.

At the adjustment step according to the present embodiment, in the case where w/p is 0.025 or more and less than 0.075, the radii of curvature r and the distances d are adjusted such that at least r/p is 0.2 or more and less than 0.525 and the expression (6) described above is satisfied, r/p is 0.525 or more and less than 1.5 and the expression (7) described above is satisfied, r/p is 0.2 or more and less than 0.525 and the expression (8) described above is satisfied, r/p is 0.525 or more and less than 0.725 and the expression (9) described above is satisfied, or r/p is 0.725 or more and less than 1.5 and the expression (10) described above is satisfied.

At the adjustment step according to the present embodiment, in the case where w/p is 0.075 or more and less than 0.15, the radii of curvature r and the distances d are adjusted such that at least r/p is 0.2 or more and less than 0.375 and the expression (11) described above is satisfied, r/p is 0.375 or more and less than 1.5 and the expression (12) described above is satisfied, r/p is 0.2 or more and less than 0.725 and the expression (13) described above is satisfied, or r/p is 0.725 or more and less than 1.5 and the expression (14) described above is satisfied.

At the adjustment step according to the present embodiment, in the case where w/p is 0.15 or more and less than 0.25, the radii of curvature r and the distances d are adjusted such that at least r/p is 0.2 or more and less than 0.725 and the expression (15) described above is satisfied, r/p is 0.725 or more and less than 1.5 and the expression (16) described above is satisfied, or r/p is 0.2 or more and less than 1.5 and the expression (17) described above is satisfied.

At the adjustment step according to the present embodiment, in the case where w/p is 0.25 or more and less than 0.35, the radii of curvature r and the distances d are adjusted such that at least r/p is 0.25 or more and less than 0.975 and the expression (18) described above is satisfied, or r/p is 0.975 or more and less than 1.5 and the expression (19) described above is satisfied.

At the adjustment step according to the present embodiment, in the case where w/p is 0.35 or more and less than 0.45, the radii of curvature r and the distances d are adjusted such that r/p is 0.3 or more and less than 1.5 and the expression (20) described above is satisfied.

At the adjustment step according to the present embodiment, in the case where w/p is 0.45 or more and less than 0.55, the radii of curvature r and the distances d are adjusted such that r/p is 0.4 or more and less than 1.5 and the expression (21) described above is satisfied.

At the adjustment step according to the present embodiment, in the case where w/p is 0.55 or more and less than 0.65, the radii of curvature r and the distances d are adjusted such that r/p is 0.45 or more and less than 1.5 and the expression (22) described above is satisfied.

The method of manufacturing the display device 1 according to the present embodiment including the adjustment step described above enables the display device 1 configured such that the luminance is 150% or more of the luminance of the light-emitting substrate 10 that the optical sheet 20 does not overlap, and the minimum value m described above is 50% or more of the maximum value M to be manufactured.

The embodiment described above can be modified in various ways. Examples of modifications will now be described with reference to the drawings. In the description below and the drawings used for the description below, portions that can be configured as in the specific examples described above are designated by reference signs like to the reference signs that are used for the corresponding portions in the specific examples described above, and a duplicated description is omitted in some cases. In the case where actions and effects that are obtained according to the embodiment described above can be clearly obtained also according to the modifications, the description thereof is omitted in some cases.

### (First Modification)

According to the embodiment described above, the display device 1 where the minimum value m described above is 50% or more of the maximum value M as illustrated in FIG. 6 is described. However, the condition of the luminance of the display device 1 is not limited thereto. In the distribution of the luminance illustrated in FIG. 6, M2 is the maximum value of the luminance when the angle (the angle θ that is formed with respect to the front direction of the display device 1) that is formed with respect to the light collection direction of the optical sheet 20 is in the range of −10° or more and +10° or less. The maximum value M2 corresponds to the maximum value of the luminance of the display device 1 in a direction perpendicular to the second direction d2 when the angle that is formed with respect to the light collection direction of the optical sheet 20 is −10° or more and +10° or less. In the distribution of the luminance illustrated in FIG. 6, m2 is the minimum value of the luminance when the angle (the angle θ that is formed with respect to the front direction of the display device 1) that is formed with respect to the light collection direction of the optical sheet 20 is in the range of −10° or more and +10° or less. The minimum value m2 corresponds to the minimum value of the luminance of the display device 1 in a direction perpendicular to the second direction d2 when the angle that is formed with respect to the light collection direction of the optical sheet 20 is −10° or more and +10° or less. According to the present modification, it is determined as the condition of the luminance of the display device 1 that the minimum value m2 illustrated in FIG. 6 is 50% or more of the maximum value M2. This enables the luminance in the direction in which the user visually recognizes the display device 1 to be ensured in the case where the angle that is formed by the direction of the line of sight in which the user visually recognizes the display device 1 during observation in the second direction d2 with respect to the light collection direction of the optical sheet 20 is −10° or more and +10° or less.

In the case where it is determined that the minimum value m2 is 50% or more of the maximum value M2, the following effects are exerted in comparison with the case where it is determined that the minimum value m is 50% or more of the maximum value M as in the embodiment described above. In the case where the angle that is formed by the direction of the line of sight in which the user visually recognizes the display device 1 during observation in the second direction d2 with respect to the light collection direction of the optical sheet 20 is −10° or more and +10° or less, the luminance in the direction in which the user visually recognizes the display device 1 can be ensured. For this reason, the luminance of the display device 1 can be ensured at an increased viewing angle. In the case where it is determined that the minimum value m2 is 50% or more of the maximum value M2, the width of a peak corresponding to the light collection direction of the optical sheet 20 increases in the distribution of the luminance in the direction perpendicular to the second direction in comparison with the case where it is determined that the minimum value m is 50% or more of the maximum value M. For this reason, in the case where it is determined that the minimum value m2 is 50% or more of the maximum value M2, the luminance in the light collection direction of the optical sheet 20 is more unlikely to decrease when the position of the optical sheet 20 with respect to the light-emitting substrate 10 is changed in the first direction d1. Consequently, the precision of adjustment in position required when the optical sheet 20 is mounted to the light-emitting substrate 10 is kept low.

Also, according to the present modification, it is determined that the luminance of the display device 1 is 150% or more of the luminance of the light-emitting substrate 10 that the optical sheet 20 does not overlap as in the embodiment described above. The luminance of the light-emitting substrate 10 that the optical sheet 20 does not overlap can be the average value of the luminance of the light-emitting substrate 10 that the optical sheet 20 does not overlap when the angle θ that is formed with respect to the front direction (the normal direction d4) is in the range of −10° or more and +10° or less. That is, according to the first modification, it is determined as the condition of the luminance of the display device 1 that the luminance of the display device 1 is 150% or more of the luminance of the light-emitting substrate 10 that the optical sheet 20 does not overlap, and the minimum value m2 described above is 50% or more of the maximum value M2. This exerts the following effects. When the luminance in the light collection direction of the optical sheet 20 is 150% or more of the luminance of the light-emitting substrate 10 that the optical sheet 20 does not overlap, the luminance in the light collection direction of the optical sheet 20 can be sufficiently increased. This enables the luminance that is visually recognized by the user to be sufficiently increased in the case where the user visually recognizes the display device 1 in the front direction. In addition to this, when the minimum value m described above is 50% or more of the maximum value M, the luminance of the luminance of the display device 1 in the direction when the angle that is formed with respect to the light collection direction of the optical sheet 20 is −10° or more and +10° or less can be at least 75% or more of the luminance of the light-emitting substrate 10 that the optical sheet 20 does not overlap. This enables the luminance that is visually recognized by the user to be sufficiently increased in the case where the user visually recognizes the display device 1 in the direction when the angle that is formed with respect to the light collection direction of the optical sheet 20 is −10° or more and +10° or less. In the above manner, the visibility of display on the display device 1 in the case where the user visually recognizes the display device 1 in the direction when the angle that is formed with respect to the light collection direction of the optical sheet 20 is −10° or more and +10° or less can be sufficiently ensured. The display device 1 that satisfies the condition of the luminance according to the first modification described above is preferably used particularly as a head-up display. The display device 1 that satisfies the condition of the luminance according to the first modification described above is preferably used particularly as a head-up display that projects an image on the windshield of an automobile.

The following description contains the conditions of the values of the radii of curvature r and the distances d that enable the condition of the luminance according to the first modification described above to be satisfied for every value of w/p. In particular, the following description contains the conditions of the values of the radii of curvature r and the distances d that enable the condition of the luminance according to the first modification to be satisfied regarding the display device 1 configured such that the light collection direction of the optical sheet 20 is the front direction of the display device 1.

In the case where w/p is less than 0.025, what is preferable is that at least r/p is 0.2 or more and less than 0.525 and an expression (23) below is satisfied, or r/p is 0.525 or more and less than 1.5 and an expression (24) below is satisfied. This enables the luminance of the display device 1 to be 150% or more of the luminance of the light-emitting substrate 10 that the optical sheet 20 does not overlap and enables the minimum value m2 described above to be 50% or more of the maximum value M2.

$$\begin{matrix}[ Math 17 ] & \\ 1.18 \times r / p - 0.29 \leq d / p \leq 1 \times r / p - 0.02 & expression ( 23 )\end{matrix}$$

$$1.18 \times r / p - 0.29 \leq d / p \leq 1.33 \times r / p + 0 \text{.15} \qquad expression ( 24 )$$

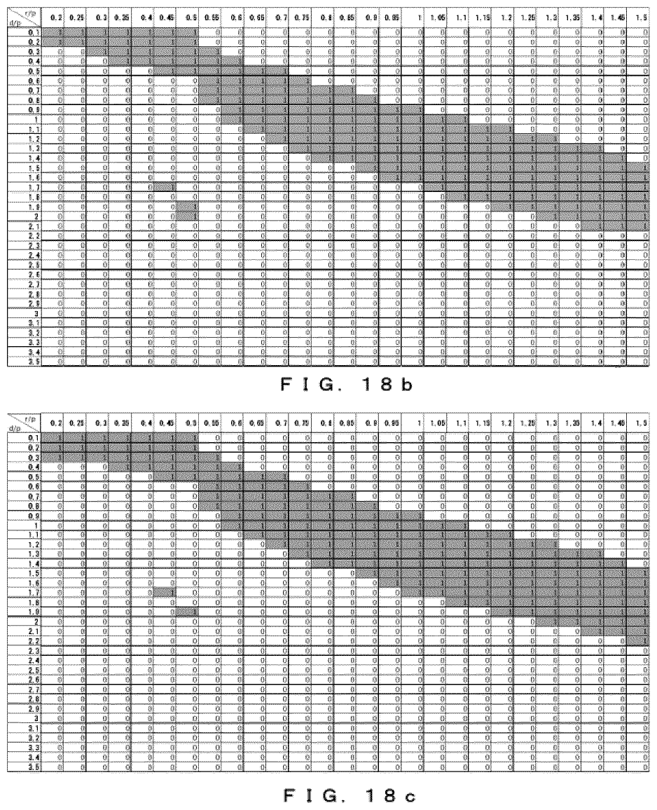

FIG. 18a is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test, the refractive index of the optical sheet 20 is set at 1.50. FIG. 18a illustrates the result of a test in which the pitch p of the light-emitting portions 13 and the widths w of the light-emitting portions 13 are determined particularly such that the value of w/p is 0.01, the radii of curvature r and the distances d are changed, the values of r/p and d/p are consequently changed, and the distribution of the luminance is simulated. In the table illustrated in FIG. 18a, “1” means that the luminance of the display device 1 is 150% or more of the luminance of the light-emitting substrate 10 that the optical sheet 20 does not overlap, and the minimum value m2 described above is 50% or more of the maximum value M2 for the corresponding values of r/p and d/p. For example, “1” is illustrated in a column in the table where r/p is 0.2, and d/p is 0.1. This means that the radii of curvature r and the distances d are determined such that r/p is 0.2, and d/p is 0.1, the distribution of the luminance is simulated, and consequently, the condition of the luminance according to the first modification described above is satisfied. In the table illustrated in FIG. 18a, “0” means that at least the luminance of the display device 1 is not 150% or more of the luminance of the light-emitting substrate 10 that the optical sheet 20 does not overlap, or the minimum value m2 described above is not 50% or more of the maximum value M2 for the corresponding values of r/p and d/p. For example, “0” is illustrated in a column in the table where r/p is 0.2, and d/p is 0.3. This means that the radii of curvature r and the distances d are determined such that r/p is 0.2, and d/p is 0.3, the distribution of the luminance is simulated, and consequently, the condition of the luminance according to the first modification described above is not satisfied.

It can be understood also from the result of the test illustrated in FIG. 18a that when at least r/p is 0.2 or more and less than 0.525 and the expression (23) is satisfied, or r/p is 0.525 or more and less than 1.5 and the expression (24) is satisfied, the condition of the luminance according to the first modification described above is satisfied.

In the case where w/p is 0.025 or more and less than 0.15, what is preferable is that at least r/p is 0.2 or more and less than 0.525 and an expression (25) below is satisfied, or r/p is 0.525 or more and less than 1.5 and an expression (26) below is satisfied. This enables the luminance of the display device 1 to be 150% or more of the luminance of the light-emitting substrate 10 that the optical sheet 20 does not overlap and enables the minimum value m2 described above to be 50% or more of the maximum

$$\begin{matrix}[ Math 18 ] & \\ 1.18 \times r / p - 0.29 \leq d / p \leq 1.14 \times r / p - 0.04 & expression ( 25 )\end{matrix}$$

$$1.18 \times r / p - 0.29 \leq d / p \leq 1.3 \times r / p + 0 \text{.18} \qquad expression ( 26 )$$

FIG. 18b is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test, the refractive index of the optical sheet 20 is set at 1.50. FIG. 18b illustrates the result of a test in which the pitch p of the light-emitting portions 13 and the widths w of the light-emitting portions 13 are determined particularly such that the value of w/p is 0.05, the radii of curvature r and the distances d are changed, the values of r/p and d/p are consequently changed, and the distribution of the luminance is simulated. In the table illustrated in FIG. 18b, “1” and “0” mean the same as “1” and “0” in the table illustrated in FIG. 18a.

FIG. 18c is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test, the refractive index of the optical sheet 20 is set at 1.50. FIG. 18c illustrates the result of a test in which the pitch p of the light-emitting portions 13 and the widths w of the light-emitting portions 13 are determined particularly such that the value of w/p is 0.1, the radii of curvature r and the distances d are changed, the values of r/p and d/p are consequently changed, and the distribution of the luminance is simulated. In the table illustrated in FIG. 18c “1” and “0” mean the same as “1” and “0” in the table illustrated in FIG. 18a.

It can be understood also from the results of the tests illustrated in FIG. 18b and FIG. 18c that when at least r/p is 0.2 or more and less than 0.525 and the expression (25) is satisfied, or r/p is 0.525 or more and less than 1.5 and the expression (26) is satisfied, the condition of the luminance according to the first modification described above is satisfied.

In the case where w/p is 0.15 or more and less than 0.25, what is preferable is that at least r/p is 0.2 or more and less than 0.525 and an expression (27) below is satisfied, or r/p is 0.525 or more and less than 1.5 and an expression (28) below is satisfied. This enables the luminance of the display device 1 to be 150% or more of the luminance of the light-emitting substrate 10 that the optical sheet 20 does not overlap and enables the minimum value m2 described above to be 50% or more of the maximum value M2.

$$\begin{matrix}[ Math 19 ] & \\ 1.18 \times r / p - 0.29 \leq d / p \leq - 0.29 \times r / p + 0.73 & expression ( 27 )\end{matrix}$$

$$1.18 \times r / p - 0.29 \leq d / p \leq 1.29 \times r / p + 0 \text{.28} \qquad expression ( 28 )$$

FIG. 19 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test, the refractive index of the optical sheet 20 is set at 1.50. FIG. 19 illustrates the result of a test in which the pitch p of the light-emitting portions 13 and the widths w of the light-emitting portions 13 are determined particularly such that the value of w/p is 0.2, the radii of curvature r and the distances d are changed, the values of r/p and d/p are consequently changed, and the distribution of the luminance is simulated. In the table illustrated in FIG. 19, “1” and “0” mean the same as “1” and “0” in the table illustrated in FIG. 18a.

It can be understood also from the result of the test illustrated in FIG. 19 that when at least r/p is 0.2 or more and less than 0.525 and the expression (27) is satisfied, or r/p is 0.525 or more and less than 1.5 and the expression (28) is satisfied, the condition of the luminance according to the first modification described above is satisfied.

In the case where w/p is 0.25 or more and less than 0.35, what is preferable is that at least r/p is 0.25 or more and less than 0.425 and an expression (29) below is satisfied, or r/p is 0.425 or more and less than 1.5 and an expression (30) below is satisfied. This enables the luminance of the display device 1 to be 150% or more of the luminance of the light-emitting substrate 10 that the optical sheet 20 does not overlap and enables the minimum value m2 described above to be 50% or more of the maximum

$$\begin{matrix}[ Math 20 ] & \\ 1.22 \times r / p - 0.33 \leq d / p \leq 4.6 \times r / p - 0.52 & expression ( 29 )\end{matrix}$$

$$1.22 \times r / p - 0.33 \leq d / p \leq 1.23 \times r / p + 0 \text{.38} \qquad expression ( 30 )$$

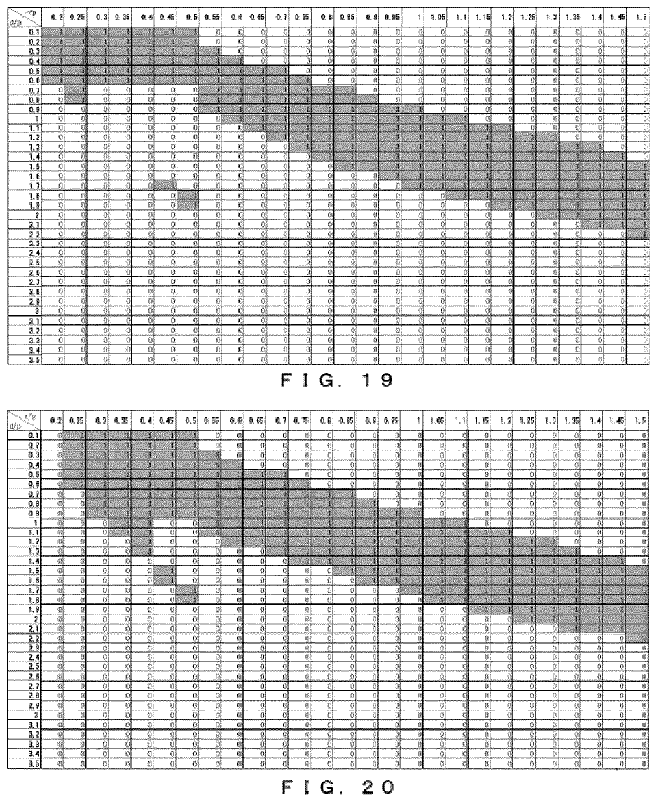

FIG. 20 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test, the refractive index of the optical sheet 20 is set at 1.50. FIG. 20 illustrates the result of a test in which the pitch p of the light-emitting portions 13 and the widths w of the light-emitting portions 13 are determined particularly such that the value of w/p is 0.3, the radii of curvature r and the distances d are changed, the values of r/p and d/p are consequently changed, and the distribution of the luminance is simulated. In the table illustrated in FIG. 20, “1” and “0” mean the same as “1” and “0” in the table illustrated in FIG. 18a.

It can be understood also from the result of the test illustrated in FIG. 20 that when at least r/p is 0.25 or more and less than 0.425 and the expression (29) is satisfied, or r/p is 0.425 or more and less than 1.5 and the expression (30) is satisfied, the condition of the luminance according to the first modification described above is satisfied.

In the case where w/p is 0.35 or more and less than 0.45, what is preferable is that at least r/p is 0.3 or more and less than 0.525 and an expression (31) below is satisfied, or r/p is 0.525 or more and less than 1.5 and an expression (32) below is satisfied. This enables the luminance of the display device 1 to be 150% or more of the luminance of the light-emitting substrate 10 that the optical sheet 20 does not overlap and enables the minimum value m2 described above to be 50% or more of the maximum

$$\begin{matrix}[ Math 21 ] & \\ 1.26 \times r / p - 0.37 \leq d / p \leq 5.4 \times r / p - 0.96 & expression ( 31 )\end{matrix}$$

$$1.26 \times r / p - 0.37 \leq d / p \leq 0.77 \times r / p + 1 \text{.08} \qquad expression ( 32 )$$

FIG. 21 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test, the refractive index of the optical sheet 20 is set at 1.50. FIG. 21 illustrates the result of a test in which the pitch p of the light-emitting portions 13 and the widths w of the light-emitting portions 13 are determined particularly such that the value of w/p is 0.4, the radii of curvature r and the distances d are changed, the values of r/p and d/p are consequently changed, and the distribution of the luminance is simulated. In the table illustrated in FIG. 21, “1” and “0” mean the same as “1” and “0” in the table illustrated in FIG. 18a.

It can be understood also from the result of the test illustrated in FIG. 21 that when at least r/p is 0.3 or more and less than 0.525 and the expression (31) is satisfied, or r/p is 0.525 or more and less than 1.5 and the expression (32) is satisfied, the condition of the luminance according to the first modification described above is satisfied.

In the case where w/p is 0.45 or more and less than 0.55, what is preferable is that at least r/p is 0.4 or more and less than 0.625 and an expression (33) below is satisfied, or r/p is 0.625 or more and less than 1.5 and an expression (34) below is satisfied. This enables the luminance of the display device 1 to be 150% or more of the luminance of the light-emitting substrate 10 that the optical sheet 20 does not overlap and enables the minimum value m2 described above to be 50% or more of the maximum

$$\begin{matrix}[ Math 22 ] & \\ 1.28 \times r / p - 0.39 \leq d / p \leq 5.83 \times r / p - 1.29 & expression ( 33 )\end{matrix}$$

$$1.28 \times r / p - 0.39 \leq d / p \leq 0.4 \times r / p + 1 \text{.77} \qquad expression ( 34 )$$

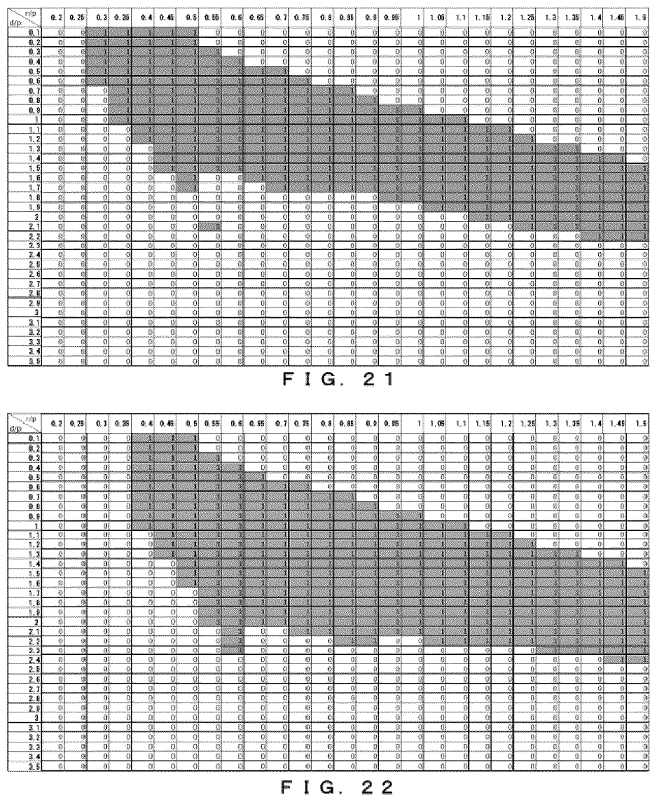

FIG. 22 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test, the refractive index of the optical sheet 20 is set at 1.50. FIG. 22 illustrates the result of a test in which the pitch p of the light-emitting portions 13 and the widths w of the light-emitting portions 13 are determined particularly such that the value of w/p is 0.5, the radii of curvature r and the distances d are changed, the values of r/p and d/p are consequently changed, and the distribution of the luminance is simulated. In the table illustrated in FIG. 22, “1” and “0” mean the same as “1” and “0” in the table illustrated in FIG. 18a.

It can be understood also from the result of the test illustrated in FIG. 22 that when at least r/p is 0.4 or more and less than 0.625 and the expression (33) is satisfied, or r/p is 0.625 or more and less than 1.5 and the expression (34) is satisfied, the condition of the luminance according to the first modification described above is satisfied.

In the case where w/p is 0.55 or more and less than 0.65, what is preferable is that at least r/p is 0.45 or more and less than 0.625 and an expression (35) below is satisfied, or r/p is 0.625 or more and less than 1.5 and an expression (36) below is satisfied. This enables the luminance of the display device 1 to be 150% or more of the luminance of the light-emitting substrate 10 that the optical sheet 20 does not overlap and enables the minimum value m2 described above to be 50% or more of the maximum

$$\begin{matrix}[ Math 23 ] & \\ 1.38 \times r / p - 0.45 \leq d / p \leq 7.6 \times r / p - 2.44 & expression ( 35 )\end{matrix}$$

$$1.38 \times r / p - 0.45 \leq d / p \leq 0.26 \times r / p + 2 \text{.29} \qquad expression ( 36 )$$

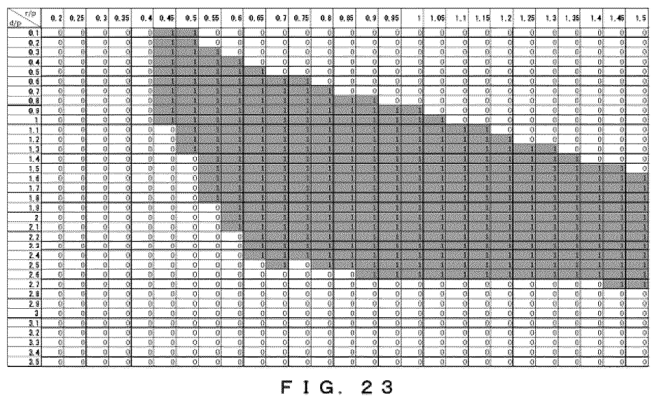

FIG. 23 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test, the refractive index of the optical sheet 20 is set at 1.50. FIG. 23 illustrates the result of a test in which the pitch p of the light-emitting portions 13 and the widths w of the light-emitting portions 13 are determined particularly such that the value of w/p is 0.6, the radii of curvature r and the distances d are changed, the values of r/p and d/p are consequently changed, and the distribution of the luminance is simulated. In the table illustrated in FIG. 23, “1” and “0” mean the same as “1” and “0” in the table illustrated in FIG. 18a.

It can be understood also from the result of the test illustrated in FIG. 23 that when at least r/p is 0.45 or more and less than 0.625 and the expression (35) is satisfied, or r/p is 0.625 or more and less than 1.5 and the expression (36) is satisfied, the condition of the luminance according to the first modification described above is satisfied.

An example of a method of manufacturing the display device 1 according to the first modification will now be described. The method of manufacturing the display device 1 according to the first modification includes the adjustment step of adjusting the radii of curvature r and the distances d depending on the value of w/p as in the display device 1 according to the embodiment described above. At the adjustment step according to the first modification, in the case where w/p is less than 0.025, the radii of curvature r and the distances d are adjusted such that at least r/p is 0.2 or more and less than 0.525 and the expression (23) described above is satisfied, or r/p is 0.525 or more and less than 1.5 and the expression (24) described above is satisfied.

At the adjustment step according to the first modification, in the case where w/p is 0.025 or more and less than 0.15, the radii of curvature r and the distances d are adjusted such that at least r/p is 0.2 or more and less than 0.525 and the expression (25) described above is satisfied, or r/p is 0.525 or more and less than 1.5 and the expression (26) described above is satisfied.

At the adjustment step according to the first modification, in the case where w/p is 0.15 or more and less than 0.25, the radii of curvature r and the distances d are adjusted such that at least r/p is 0.2 or more and less than 0.525 and the expression (27) described above is satisfied, or r/p is 0.525 or more and less than 1.5 and the expression (28) described above is satisfied.

At the adjustment step according to the first modification, in the case where w/p is 0.25 or more and less than 0.35, the radii of curvature r and the distances d are adjusted such that at least r/p is 0.25 or more and less than 0.425 and the expression (29) described above is satisfied, or r/p is 0.425 or more and less than 1.5 and the expression (30) described above is satisfied.

At the adjustment step according to the first modification, in the case where w/p is 0.35 or more and less than 0.45, the radii of curvature r and the distances d are adjusted such that at least r/p is 0.3 or more and less than 0.525 and the expression (31) described above is satisfied, or r/p is 0.525 or more and less than 1.5 and the expression (32) described above is satisfied.

At the adjustment step according to the first modification, in the case where w/p is 0.45 or more and less than 0.55, the radii of curvature r and the distances d are adjusted such that at least r/p is 0.4 or more and less than 0.625 and the expression (33) described above is satisfied, or r/p is 0.625 or more and less than 1.5 and the expression (34) described above is satisfied.

At the adjustment step according to the first modification, in the case where w/p is 0.55 or more and less than 0.65, the radii of curvature r and the distances d are adjusted such that at least r/p is 0.45 or more and less than 0.625 and the expression (35) described above is satisfied, or r/p is 0.625 or more and less than 1.5 and the expression (36) described above is satisfied.

The method of manufacturing the display device 1 according to the first modification including the adjustment step described above enables the display device 1 configured such that the luminance is 150% or more of the luminance of the light-emitting substrate 10 that the optical sheet 20 does not overlap, and the minimum value m2 described above is 50% or more of the maximum value M2 to be manufactured. In particular, as for the display device 1 configured such that the light collection direction of the optical sheet 20 is the front direction of the display device 1, it is thought that the condition of the luminance according to the first modification is satisfied. Also, in the above manner, the pitch p of the light-emitting portions 13, the widths w of the light-emitting portions 13, the radii of curvature r, and the distances d are adjusted as described according to the first modification, and consequently, the luminance in a direction that forms an angle with respect to the light collection direction can be ensured while the luminance in the light collection direction is increased.

### (Second Modification)

In the description according to the embodiment and the modification described above, the display device 1 collects the light that is emitted from the light-emitting substrate 10 and that is diffused in the direction perpendicular to the second direction d2 in the front direction of the display device 1 by using the optical sheet 20. However, the direction in which the display device 1 collects the light is not limited thereto.

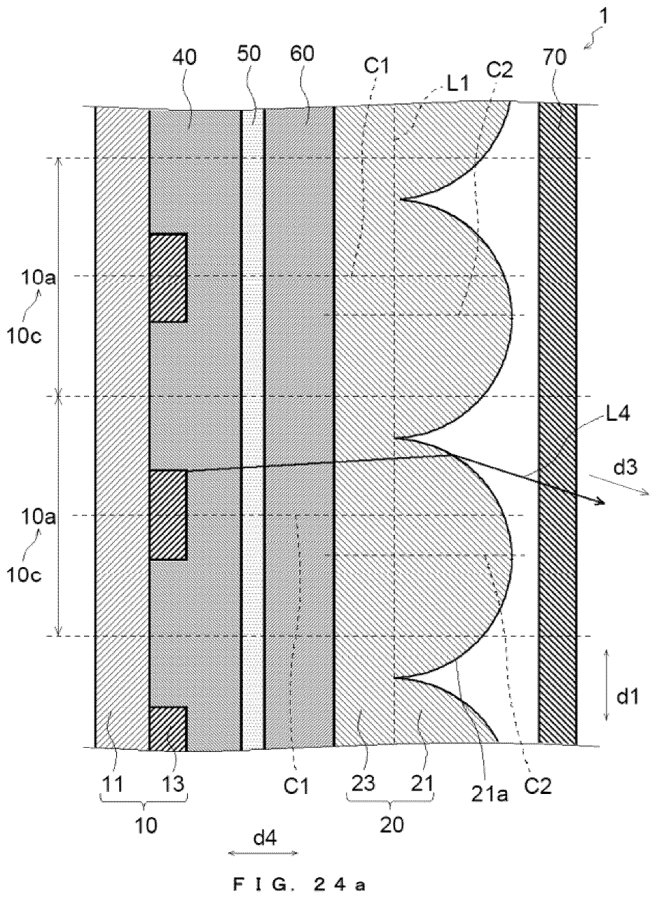

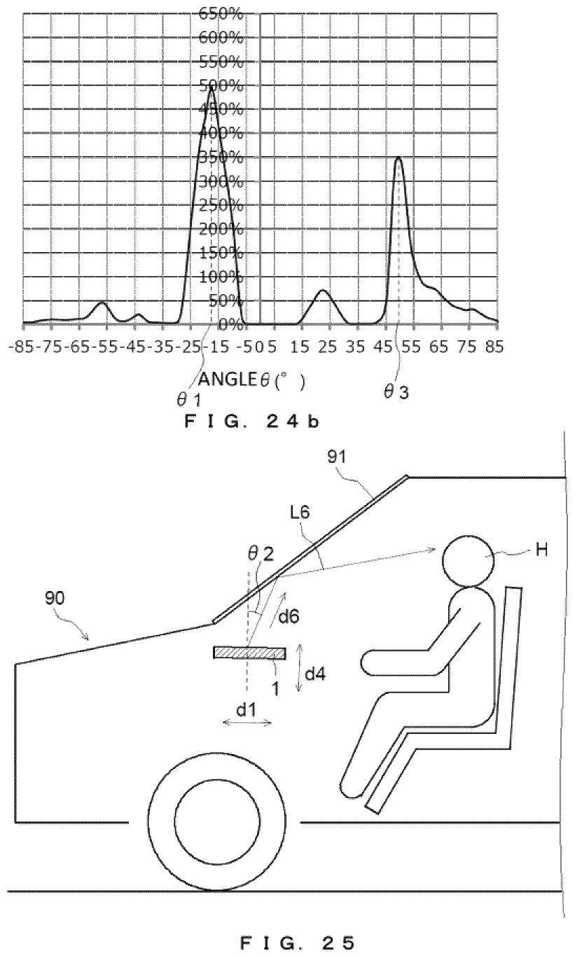

FIG. 24a is a sectional view illustrating a section perpendicular to the second direction d2 of a display device 1 according to a second modification. A line designated by a symbol of L4 illustrated in FIG. 24a represents an example of the light path when the light that is emitted from the light-emitting portions 13 of the light-emitting substrate 10 passes through the optical sheet 20 according to the second modification.

According to the second modification, the center C2 in the first direction d1 of one of the unit lenses 21 is shifted from the centers C1 in the first direction d1 of the light-emitting portions 13 in the unit regions 10a that form the corresponding one of the unit region second direction columns 10c during observation in the normal direction d4 to the plate surface of the light-emitting substrate 10. According to the second modification, the centers C2 in the first direction d1 of the unit lenses 21 are shifted from the centers C1 in the first direction d1 of the light-emitting portions 13 in the unit regions 10a that form the respective unit region second direction columns 10c. This can be understood also from FIG. 24a in which the center C2 in the first direction d1 of one of the unit lenses 21 and the centers C1 in the first direction d1 of the light-emitting portions 13 in the unit regions 10a that form the corresponding one of the unit region second direction columns 10c do not overlap in the normal direction d4.

According to the second modification, the centers C2 are shifted from the centers C1 as described above, and consequently, the light that is emitted from the light-emitting substrate 10 and that is diffused in the direction perpendicular to the second direction d2 is collected in a direction d3 that is perpendicular to the second direction d2 and that forms an angle with respect to the front direction (the normal direction d4) of the display device 1. The direction d3 in which the light that is emitted from the light-emitting substrate 10 is collected can be adjusted in a manner in which the degree of the shift of the centers C2 from the centers C1 in the first direction d1 is adjusted. FIG. 24b is a graph illustrating an example of the result of a test in which the distribution of the luminance in the direction perpendicular to the second direction d2 is simulated regarding the display device 1 illustrated in FIG. 24a. In the simulation test, the refractive index of the optical sheet 20 is set at 1.50. The vertical axis designated by a symbol of V in FIG. 24b represents the magnitude of the luminance by using a ratio to the average value of the luminance of the light-emitting substrate 10 that the optical sheet 20 does not overlap when the angle θ that is formed with respect to the front direction (the normal direction d4) is in the range of −5° or more and +5° or less. The horizontal axis in FIG. 24b represents the angle θ) (° that is formed by the direction in which the luminance that is represented by the vertical axis is observed with respect to the front direction (the normal direction d4) of the display device 1. In FIG. 24b, the light that is emitted from the light-emitting substrate 10 is collected in the direction d3 when the angle that is formed with respect to the front direction is 01. In other words, the direction d3 is the light collection direction of the optical sheet 20.

In an example illustrated in FIG. 24a, the display device 1 further includes a light angle adjustment layer 70. The light angle adjustment layer 70 is located along the second surface 20b of the optical sheet 20. In the example illustrated in FIG. 24a, the light angle adjustment layer 70 faces the second surface 20b of the optical sheet 20. The light angle adjustment layer 70 adjusts an angle of the travelling direction of the light from the optical sheet 20 with respect to the normal direction d4 to the plate surface of the light-emitting substrate 10. For example, the light angle adjustment layer 70 adjusts the angle of the travelling direction of the light from the optical sheet 20 with respect to the normal direction d4 such that the travelling direction changes during observation in the first direction d1. An example of the light angle adjustment layer 70 is the light angle adjustment layer 70 that has a function of collecting the light that is emitted from the light-emitting substrate 10, that passes through the optical sheet 20, and that is diffused in the direction perpendicular to the first direction d1 in a direction perpendicular to a surface of the light angle adjustment layer 70. The light angle adjustment layer 70 enables the travelling direction of the light that is observed in the first direction d1 to be directed in the direction perpendicular to the surface of the light angle adjustment layer 70.

An aspect in which the light angle adjustment layer 70 adjusts the angle of the travelling direction of the light with respect to the normal direction d4 is not limited to the aspect described above. The light angle adjustment layer 70 may adjust the angle of the travelling direction of the light from the optical sheet 20 with respect to the normal direction d4 such that the travelling direction changes during observation in the second direction d2. The light angle adjustment layer 70 may adjust the angle of the travelling direction of the light from the optical sheet 20 with respect to the normal direction d4 such that the travelling direction changes during observation in a direction intersecting with the first direction d1 and the second direction d2. The display device 1 may include multiple light angle adjustment layers 70 including a first light angle adjustment layer 70 that adjusts the angle of the travelling direction of the light with respect to the normal direction d4 such that the travelling direction changes during observation in a direction and a second light angle adjustment layer 70 that adjusts the angle of the travelling direction of the light with respect to the normal direction d4 such that the travelling direction changes during observation in another direction intersecting the direction.

For example, the light angle adjustment layer 70 is a louver sheet. In the case described as a specific example, the light angle adjustment layer 70 is a louver sheet that has a function of collecting the light that is diffused in the direction perpendicular to the first direction d1 in the direction perpendicular to the surface of the light angle adjustment layer 70. In this case, the louver sheet includes multiple light-absorbing portions that extend in the first direction d1 and multiple light-transmitting portions that extend in the first direction d1. The light-absorbing portions and the light-transmitting portions alternate in the second direction d2. The light-absorbing portions of the louver sheet have inclined surfaces that are inclined in the normal direction d4 and that can reflect the light that is diffused in the direction perpendicular to the first direction d1 in the direction perpendicular to the surface of the light angle adjustment layer 70. In this case, the inclined surfaces of the light-absorbing portions reflect light that is not perpendicular to the second direction d2, and consequently, the light is collected in the direction perpendicular to the surface of the light angle adjustment layer 70.

As for the display device 1, there is a possibility that the direction in which the user is supposed to visually recognize the display device 1 is not the front direction of the display device 1. According to the second modification, the light that is emitted from the light-emitting substrate 10 is collected in the direction d3 that forms an angle with respect to the front direction of the display device 1. This enables the light to be collected in the direction in a manner in which the direction d3 is adjusted to the direction even in the case where the direction in which the user is supposed to visually recognize the display device 1 is not the front direction of the display device 1.

The display device 1 according to the second modification can be preferably used as a head-up display. In particular, the display device 1 according to the second modification can be preferably used as a head-up display that projects an image on the windshield of an automobile. Actions and effects in the case where the display device 1 according to the second modification is used as a head-up display that projects an image on the windshield of an automobile will now be described.

FIG. 25 illustrates an example of an aspect in which the display device 1 is used as a head-up display that projects an image on a windshield 91 of an automobile 90. In FIG. 25, the display device 1 is disposed such that the second direction d2 is directed to a direction that is perpendicular to the front-rear direction of the automobile 90 and that is perpendicular to the up-down direction of the automobile 90. FIG. 25 illustrates a situation in which the display device 1 and the automobile 90 are observed in the second direction d2 of the display device 1. As for the display device 1 in FIG. 25, an illustration for components of the display device 1 such as the light-emitting substrate 10 and the optical sheet 20 is omitted, and only the outline of the display device 1 is illustrated. A line designated by a symbol of L6 illustrated in FIG. 25 represents an example of an assumable path of the light that is emitted from the display device 1.

In the case where the display device 1 is used as the head-up display of the automobile 90 as illustrated in FIG. 25, it can be said that a user H visually recognizes an image that is displayed by the display device 1 with the windshield 91 interposed therebetween. In this case, the light from the display device 1 is reflected at the windshield 91, and a direction d6 of an assumable path from the display device 1 to the windshield 91 in an assumable path L6 that reaches the eyes of the user H can be regarded as the direction in which the user is supposed to visually recognize the display device 1. In some cases where the display device 1 is used as the head-up display of the automobile 90 as illustrated in FIG. 25, it is necessary to dispose the display device 1 in a limited space in the automobile 90, and accordingly, an angle at which the display device 1 can be disposed is limited. In some cases, the angle of the windshield 91 on which the display device 1 projects the image cannot be freely designed only from the perspective that the display device 1 is easy to project the image.

The display device 1 according to the second modification enables the user H to visually recognize the image with the windshield 91 interposed therebetween by adjusting the direction d3 in which the light that is emitted from the light-emitting substrate 10 is collected even through the angle at which the display device 1 can be disposed and the angle of the windshield 91 are limited.

In the case where the display device 1 that collects the light that is emitted from the light-emitting substrate 10 is used as a typical head-up display of the automobile 90, the light from the display device 1 can be inhibited from directly reaching the eyes of the user H without the windshield 91.

### (Third Modification)

In the description according to the second modification described above, the centers C2 are shifted from the centers C1, and consequently, the display device 1 collects the light that is emitted from the light-emitting substrate 10 in the direction d3 that forms an angle with respect to the front direction of the display device 1. However, the aspect of the display device 1 that collects the light that is emitted from the light-emitting substrate 10 in a direction that forms an angle with respect to the front direction of the display device 1 is not limited thereto.

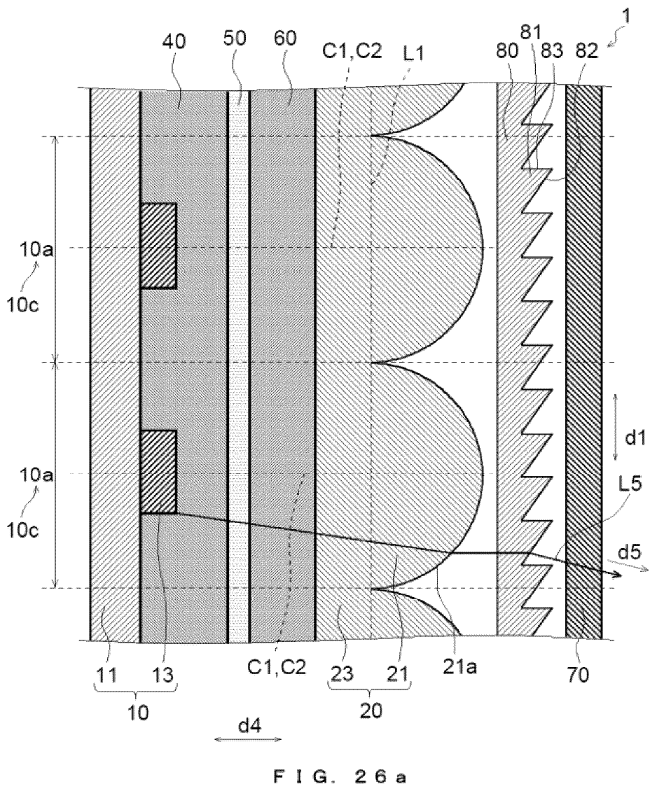

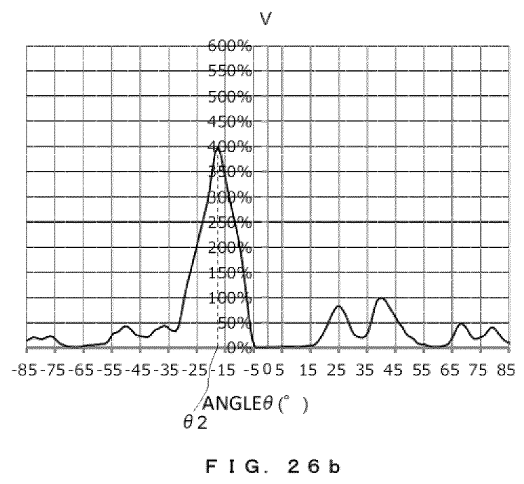

FIG. 26a is a sectional view of a section perpendicular to the second direction d2 of the display device 1 according to a third modification. A line designated by a symbol of L5 illustrated in FIG. 26a represents an example of the light path when the light that is emitted from the light-emitting portions 13 of the light-emitting substrate 10 passes through the optical sheet 20 according to the third modification.

According to the third modification, the centers C2 in the first direction d1 of the unit lenses 21 are not shifted from centers C1 in the first direction d1 of the light-emitting portions 13 in the unit regions 10a that form the respective unit region second direction columns 10c. The display device 1 according to the third modification further includes a light deflection layer 80 as illustrated in FIG. 26a. The light deflection layer 80 faces the second surface 20b of the optical sheet 20. In an example illustrated in FIG. 26a, the light deflection layer 80 is located between the optical sheet 20 and the light angle adjustment layer 70.

The light deflection layer 80 deflects the light from the optical sheet 20 such that the travelling direction changes during observation in the second direction d2. In the example illustrated in FIG. 26a, the light deflection layer 80 includes multiple linear prisms 81 that are arranged in the first direction d1 and that extend in the second direction d2. Each linear prism 81 has a first prism surface 82 that is inclined with respect to the front direction (the normal direction d4) of the display device 1 and a second prism surface 83 that is parallel with the front direction of the display device 1. In this case, the light deflection layer 80 refracts the light from the optical sheet 20 at the first prism surface 82 and consequently deflects the light such that the travelling direction changes during observation in the second direction d2.

As for the display device 1 according to the third modification, the light that is emitted from the light-emitting substrate 10 and that is diffused in the direction perpendicular to the second direction d2 is first collected by the optical sheet 20 in the front direction (the normal direction d4) of the display device 1. The light that is collected in the front direction of the display device 1 is deflected by the light deflection layer 80 in a direction d5 illustrated in FIG. 26a. Also, the display device 1 according to the third modification can collect the light that is emitted from the light-emitting substrate 10 in a direction that forms an angle with respect to the front direction of the display device 1 as in the display device 1 according to the second modification. FIG. 26b is a graph illustrating an example of the result of a test in which the distribution of the luminance in the direction perpendicular to the second direction d2 is simulated regarding the display device 1 illustrated in FIG. 26a. In the simulation test, the refractive index of the optical sheet 20 is set at 1.50. The vertical axis designated by a symbol of V in FIG. 26b represents the magnitude of the luminance by using a ratio to the average value of the luminance of the light-emitting substrate 10 that the optical sheet 20 does not overlap when the angle θ that is formed with respect to the front direction (the normal direction d4) is in the range of −5° or more and +5° or less. The horizontal axis in FIG. 26b represents the angle θ (′) that is formed by the direction in which the luminance that is represented by the vertical axis is observed with respect to the front direction (the normal direction d4) of the display device 1. In FIG. 26b, the light that is emitted from the light-emitting substrate 10 is collected in the direction d5 when the angle that is formed with respect to the front direction is θ2.

The display device 1 according to the second modification does not need to include the light deflection layer 80 unlike the display device 1 according to the third modification and has an advantage such that the light that is emitted from the light-emitting substrate 10 can be collected in a direction that forms an angle with respect to the front direction of the display device 1.

As for the display device 1 according to the second modification, as illustrated in FIG. 24a, the centers C2 are shifted from the centers C1. For this reason, as for the display device 1 according to the second modification, it is thought that the light that is emitted from the light-emitting portions 13 is likely to reach unit lenses 21 other than the unit lenses 21 that are located in the front direction of the light-emitting portions 13. Referring to FIG. 24b corresponding to the result of the test in which the distribution of the luminance is simulated regarding the display device 1 according to the second modification, the luminance is the maximum at the angle θ1, and the luminance has a local maximum value at the angle θ3. It is thought that the reason why the luminance has the local maximum value at the angle θ3 is that the light that is emitted from the light-emitting portions 13 and that passes through the lens surfaces 21a of the unit lenses 21 adjacent to the unit lenses 21 that are located in the front direction of the light-emitting portions 13 is collected in a direction when the angle that is formed with respect to the front direction is θ3. As for the display device 1 according to the third modification regarding this point, it is not necessary for the centers C2 to be shifted from the centers C1. For this reason, the display device 1 according to the third modification enables the light that is emitted from the light-emitting portions 13 to be inhibited from reaching unit lenses 21 other than the unit lenses 21 that are located in the front direction of the light-emitting portions 13 unlike the display device 1 according to the second modification. This results in an advantage such that the light that is emitted from the light-emitting portions 13 is inhibited from being collected also in a direction other than the desired direction as illustrated in FIG. 24b.

### (Fourth Modification)

A fourth modification relates to an example in which the conditions of the values of the radii of curvature r and the distances d that enable the luminance of the display device 1 to be 150% or more of the luminance of the light-emitting substrate 10 that the optical sheet 20 does not overlap and that enable the minimum value m described above to be 50% or more of the maximum value M for every value of w/p are determined from a perspective that differs from that according to the embodiment and the modifications described above.

The following description contains the conditions of the values of the radii of curvature r and the distances d that enable the luminance of the display device 1 to be 150% or more of the luminance of the light-emitting substrate 10 that the optical sheet 20 does not overlap and that enable the minimum value m described above to be 50% or more of the maximum value M for every value of w/p according to the fourth modification. In particular, the following description contains a modification to the conditions of the values of the radii of curvature r and the distances d that enable the condition of the luminance described above to be satisfied regarding the display device 1 configured such that the light collection direction of the optical sheet 20 is the front direction of the display device 1.

In the case where w/p is 0.01 or more and less than 0.05, what is preferable is that at least r/p is 0.2 or more and less than 0.525 and an expression (37) below is satisfied, r/p is 0.525 or more and less than 0.975 and an expression (38) below is satisfied, r/p is 0.975 or more and less than 1.5 and an expression (39) below is satisfied, r/p is 0.2 or more and less than 0.525 and an expression (40) below is satisfied, or r/p is 0.525 or more and less than 0.975 and an expression (41) below is satisfied. This enables the luminance of the display device 1 to be 150% or more of the luminance of the light-emitting substrate 10 that the optical sheet 20 does not overlap and enables the minimum value m described above to be 50% or more of the maximum value M.

$$\begin{matrix}[ Math 24 ] & \\ 0.21 \times r / p + 0.01 \leq d / p \leq 1 \times r / p - 0.02 & expression ( 37 )\end{matrix}$$

$$1.4 \times r / p - 0.45 \leq d / p \leq 2.23 \times r / p - 0.4 \qquad expression ( 38 )$$

$$1.09 \times r / p - 0.18 \leq d / p \leq 1.53 \times r / p + 0.3 \qquad expression ( 39 )$$

$$2.43 \times r / p + 0.05 \leq d / p \leq 3.57 \times r / p - 0.21 \qquad expression ( 40 )$$

$$4.57 \times r / p - 0.89 \leq d / p \leq 4 \times r / p - 0.3 \qquad expression ( 41 )$$

FIG. 27 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test the result of which is illustrated in FIG. 27, the distribution of the luminance is simulated in four conditions of first to fourth conditions regarding the refractive index of the optical sheet 20 and the value of w/p. In the simulation test the result of which is illustrated in FIG. 27, the first to fourth conditions are determined as follows. In the first condition, the refractive index of the optical sheet 20 is 1.50, the pitch p of the light-emitting portions 13 and the widths w of the light-emitting portions 13 are determined such that the value of w/p is 0.01, the radii of curvature r and the distances d are changed, the values of r/p and d/p are consequently changed, and the distribution of the luminance is simulated. In the second condition, the refractive index of the optical sheet 20 is 1.60, the pitch p of the light-emitting portions 13 and the widths w of the light-emitting portions 13 are determined such that the value of w/p is 0.01, the radii of curvature r and the distances d are changed, the values of r/p and d/p are consequently changed, and the distribution of the luminance is simulated. In the third condition, the refractive index of the optical sheet 20 is 1.50, the pitch p of the light-emitting portions 13 and the widths w of the light-emitting portions 13 are determined such that the value of w/p is 0.05, the radii of curvature r and the distances d are changed, the values of r/p and d/p are consequently changed, and the distribution of the luminance is simulated. In the fourth condition, the refractive index of the optical sheet 20 is 1.60, the pitch p of the light-emitting portions 13 and the widths w of the light-emitting portions 13 are determined such that the value of w/p is 0.05, the radii of curvature r and the distances d are changed, the values of r/p and d/p are consequently changed, and the distribution of the luminance is simulated. In the table illustrated in FIG. 27, “1” means that the luminance of the display device 1 is 150% or more of the luminance of the light-emitting substrate 10 that the optical sheet 20 does not overlap, and the minimum value m described above is 50% or more of the maximum value M for the corresponding values of r/p and d/p in all of the first to fourth conditions. For example, “1” is illustrated in a column in the table where r/p is 0.2, and d/p is 0.1. This means that the radii of curvature r and the distances d are determined such that r/p is 0.2, and d/p is 0.1 in the first to fourth conditions, the distribution of the luminance is simulated, and consequently, the condition of the luminance described above is satisfied in all of the first to fourth conditions. In the table illustrated in FIG. 27, “0” means that at least the luminance of the display device 1 is not 150% or more of the luminance of the light-emitting substrate 10 that the optical sheet 20 does not overlap, or the minimum value m described above is not 50% or more of the maximum value M for the corresponding values of r/p and d/p at least in any one of the first to fourth conditions. For example, “0” is illustrated in a column in the table where r/p is 0.2, and d/p is 0.2. This means that the radii of curvature r and the distances d are determined such that r/p is 0.2, and d/p is 0.2 in the first to fourth conditions, the distribution of the luminance is simulated, and consequently, the condition of the luminance described above is not satisfied at least in any one of the first to fourth conditions.

It can be understood also from the result of the test illustrated in FIG. 27 that when at least r/p is 0.2 or more and less than 0.525 and the expression (37) is satisfied, r/p is 0.525 or more and less than 0.975 and the expression (38) is satisfied, r/p is 0.975 or more and less than 1.5 and the expression (39) is satisfied, r/p is 0.2 or more and less than 0.525 and the expression (40) is satisfied, or r/p is 0.525 or more and less than 0.975 and the expression (41) is satisfied, the condition of the luminance described above is satisfied.

In particular, the present inventors have found a tendency described below from the result of the simulation test. In the case where the values of w/p, r/p, and d/p are constant, the condition of the luminance described above is satisfied when the refractive index of the optical sheet 20 is A1 and when the refractive index of the optical sheet 20 is A2. In this case, the condition of the luminance described above tends to be satisfied also when the refractive index of the optical sheet 20 is A3 that is A1 or more and A2 or less. In addition, the present inventors have found a tendency described below from the result of the simulation test. In the case where the refractive index of the optical sheet 20 and the values of r/p and d/p are constant, the condition of the luminance described above is satisfied when w/p is B1 and when w/p is B2. In this case, the condition of the luminance described above tends to be satisfied also when w/p is B3 that is B1 or more and B2 or less. In consideration for the tendencies described above, it can be understood from FIG. 27 illustrating whether the condition of the luminance described above is satisfied in the first to fourth conditions that in the case where the refractive index of the optical sheet 20 is 1.50 or more and 1.60 or less, and the value of w/p is 0.01 or more and less than 0.05, when at least r/p is 0.2 or more and less than 0.525 and the expression (37) is satisfied, r/p is 0.525 or more and less than 0.975 and the expression (38) is satisfied, r/p is 0.975 or more and less than 1.5 and the expression (39) is satisfied, r/p is 0.2 or more and less than 0.525 and the expression (40) is satisfied, or r/p is 0.525 or more and less than 0.975 and the expression (41) is satisfied, the condition of the luminance described above is stably satisfied.

In the case where w/p is 0.05 or more and less than 0.1, what is preferable is that at least r/p is 0.2 or more and less than 0.525 and an expression (42) below is satisfied, r/p is 0.525 or more and less than 0.975 and an expression (43) below is satisfied, r/p is 0.975 or more and less than 1.5 and an expression (44) below is satisfied, r/p is 0.2 or more and less than 0.525 and an expression (45) below is satisfied, or r/p is 0.525 or more and less than 0.975 and an expression (46) below is satisfied. This enables the luminance of the display device 1 to be 150% or more of the luminance of the light-emitting substrate 10 that the optical sheet 20 does not overlap and enables the minimum value m described above to be 50% or more of the maximum value M.

$$\begin{matrix}[ Math 25 ] & \\ 0.21 \times r / p + 0.01 \leq d / p \leq 0.79 \times r / p + 0.11 & expression ( 42 )\end{matrix}$$

$$1.4 \times r / p - 0.45 \leq d / p \leq 2.23 \times r / p - 0.4 \qquad expression ( 43 )$$

$$1.09 \times r / p - 0.18 \leq d / p \leq 1.56 \times r / p + 0.27 \qquad expression ( 44 )$$

$$2.57 \times r / p - 0.01 \leq d / p \leq 3.43 \times r / p - 0.17 \qquad expression ( 45 )$$

$$4.77 \times r / p - 1.04 \leq d / p \leq 4.13 \times r / p - 0 \text{.41} \qquad expression ( 46 )$$

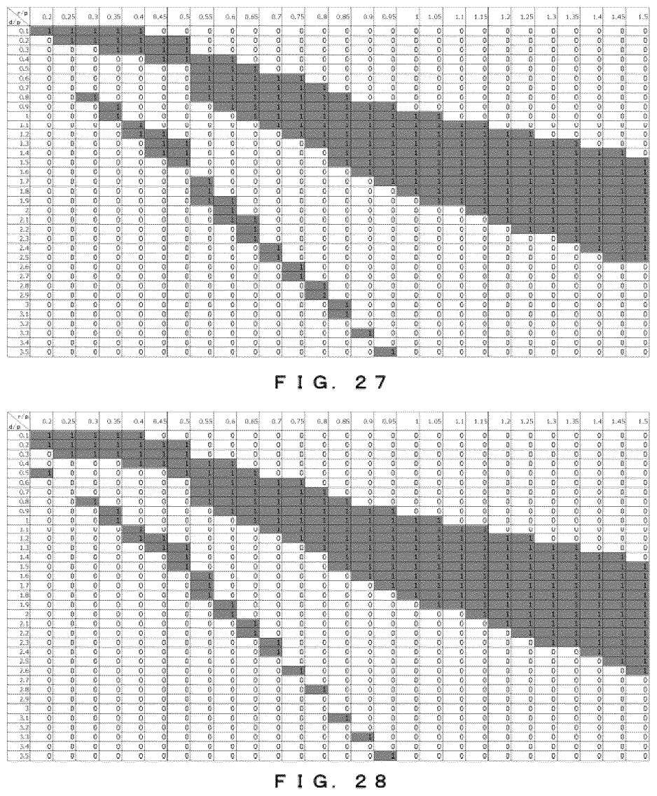

FIG. 28 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. Also, in the simulation test the result of which is illustrated in FIG. 28, the distribution of the luminance is simulated in four conditions of first to fourth conditions regarding the refractive index of the optical sheet 20 and the value of w/p as in the simulation test the result of which is illustrated in FIG. 27 except for matters described below. In the simulation test the result of which is illustrated in FIG. 28, the first to fourth conditions are determined as follows. In the first condition, the refractive index of the optical sheet 20 is 1.50, the pitch p of the light-emitting portions 13 and the widths w of the light-emitting portions 13 are determined such that the value of w/p is 0.05, the radii of curvature r and the distances d are changed, the values of r/p and d/p are consequently changed, and the distribution of the luminance is simulated. In the second condition, the refractive index of the optical sheet 20 is 1.60, the pitch p of the light-emitting portions 13 and the widths w of the light-emitting portions 13 are determined such that the value of w/p is 0.05, the radii of curvature r and the distances d are changed, the values of r/p and d/p are consequently changed, and the distribution of the luminance is simulated. In the third condition, the refractive index of the optical sheet 20 is 1.50, the pitch p of the light-emitting portions 13 and the widths w of the light-emitting portions 13 are determined such that the value of w/p is 0.1, the radii of curvature r and the distances d are changed, the values of r/p and d/p are consequently changed, and the distribution of the luminance is simulated. In the fourth condition, the refractive index of the optical sheet 20 is 1.60, the pitch p of the light-emitting portions 13 and the widths w of the light-emitting portions 13 are determined such that the value of w/p is 0.1, the radii of curvature r and the distances d are changed, the values of r/p and d/p are consequently changed, and the distribution of the luminance is simulated. In the table illustrated in FIG. 28, “1” and “0” mean the same as “1” and “0” in the table illustrated in FIG. 27.

It can be understood also from the result of the test illustrated in FIG. 28 that when at least r/p is 0.2 or more and less than 0.525 and the expression (42) is satisfied, r/p is 0.525 or more and less than 0.975 and the expression (43) is satisfied, r/p is 0.975 or more and less than 1.5 and the expression (44) is satisfied, r/p is 0.2 or more and less than 0.525 and the expression (45) is satisfied, or r/p is 0.525 or more and less than 0.975 and the expression (46) is satisfied, the condition of the luminance described above is satisfied.

In particular, it can be understood from FIG. 28 illustrating whether the condition of the luminance described above is satisfied in the first to fourth conditions that in the case where the refractive index of the optical sheet 20 is 1.50 or more and 1.60 or less, and the value of w/p is 0.05 or more and less than 0.1, when at least r/p is 0.2 or more and less than 0.525 and the expression (42) is satisfied, r/p is 0.525 or more and less than 0.975 and the expression (43) is satisfied, r/p is 0.975 or more and less than 1.5 and the expression (44) is satisfied, r/p is 0.2 or more and less than 0.525 and the expression (45) is satisfied, or r/p is 0.525 or more and less than 0.975 and the expression (46) is satisfied, the condition of the luminance described above is stably satisfied.

In the case where w/p is 0.1 or more and less than 0.2, what is preferable is that at least r/p is 0.2 or more and less than 0.375 and an expression (47) below is satisfied, r/p is 0.375 or more and less than 0.975 and an expression (48) below is satisfied, r/p is 0.975 or more and less than 1.5 and an expression (49) below is satisfied, or r/p is 0.375 or more and less than 0.975 and an expression (50) below is satisfied. This enables the luminance of the display device 1 to be 150% or more of the luminance of the light-emitting substrate 10 that the optical sheet 20 does not overlap and enables the minimum value m described above to be 50% or more of the maximum value M.

$$\begin{matrix}[ Math 26 ] & \\ 0.6 \times r / p - 0.09 \leq d / p \leq 4 \times r / p - 0.4 & expression ( 47 )\end{matrix}$$

$$1.53 \times r / p - 0.56 \leq d / p \leq 2.27 \times r / p - 0.35 \qquad expression ( 48 )$$

$$1.09 \times r / p - 0.18 \leq d / p \leq 1.56 \times r / p + 0.28 \qquad expression ( 49 )$$

$$4.79 \times r / p - 1.09 \leq d / p \leq 4.41 \times r / p - 0.64 \qquad expression ( 50 )$$

FIG. 29 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. Also, in the simulation test the result of which is illustrated in FIG. 29, the distribution of the luminance is simulated in four conditions of first to fourth conditions regarding the refractive index of the optical sheet 20 and the value of w/p as in the simulation test the result of which is illustrated in FIG. 27 except for matters described below. In the simulation test the result of which is illustrated in FIG. 29, the first to fourth conditions are determined as follows. In the first condition, the refractive index of the optical sheet 20 is 1.50, the pitch p of the light-emitting portions 13 and the widths w of the light-emitting portions 13 are determined such that the value of w/p is 0.1, the radii of curvature r and the distances d are changed, the values of r/p and d/p are consequently changed, and the distribution of the luminance is simulated. In the second condition, the refractive index of the optical sheet 20 is 1.60, the pitch p of the light-emitting portions 13 and the widths w of the light-emitting portions 13 are determined such that the value of w/p is 0.1, the radii of curvature r and the distances d are changed, the values of r/p and d/p are consequently changed, and the distribution of the luminance is simulated. In the third condition, the refractive index of the optical sheet 20 is 1.50, the pitch p of the light-emitting portions 13 and the widths w of the light-emitting portions 13 are determined such that the value of w/p is 0.2, the radii of curvature r and the distances d are changed, the values of r/p and d/p are consequently changed, and the distribution of the luminance is simulated. In the fourth condition, the refractive index of the optical sheet 20 is 1.60, the pitch p of the light-emitting portions 13 and the widths w of the light-emitting portions 13 are determined such that the value of w/p is 0.2, the radii of curvature r and the distances d are changed, the values of r/p and d/p are consequently changed, and the distribution of the luminance is simulated. In the table illustrated in FIG. 29, “1” and “0” mean the same as “1” and “0” in the table illustrated in FIG. 27.

It can be understood also from the result of the test illustrated in FIG. 29 that when at least r/p is 0.2 or more and less than 0.375 and the expression (47) is satisfied, r/p is 0.375 or more and less than 0.975 and the expression (48) is satisfied, r/p is 0.975 or more and less than 1.5 and the expression (49) is satisfied, or r/p is 0.375 or more and less than 0.975 and the expression (50) is satisfied, the condition of the luminance described above is satisfied.

In particular, it can be understood from FIG. 29 illustrating whether the condition of the luminance described above is satisfied in the first to fourth conditions that in the case where the refractive index of the optical sheet 20 is 1.50 or more and 1.60 or less, and the value of w/p is 0.1 or more and less than 0.2, when at least r/p is 0.2 or more and less than 0.375 and the expression (47) is satisfied, r/p is 0.375 or more and less than 0.975 and the expression (48) is satisfied, r/p is 0.975 or more and less than 1.5 and the expression (49) is satisfied, or r/p is 0.375 or more and less than 0.975 and the expression (50) is satisfied, the condition of the luminance described above is stably satisfied.

In the case where w/p is 0.2 or more and less than 0.3, what is preferable is that at least r/p is 0.25 or more and less than 0.725 and an expression (51) below is satisfied, r/p is 0.725 or more and less than 0.975 and an expression (52) below is satisfied, r/p is 0.975 or more and less than 1.5 and an expression (53) below is satisfied, or r/p is 0.725 or more and less than 0.975 and an expression (54) below is satisfied. This enables the luminance of the display device 1 to be 150% or more of the luminance of the light-emitting substrate 10 that the optical sheet 20 does not overlap and enables the minimum value m described above to be 50% or more of the maximum value M.

$$\begin{matrix}[ Math 26 ] & \\ 1.03 \times r / p - 0.26 \leq d / p \leq 4.39 \times r / p - 0.64 & expression ( 51 )\end{matrix}$$

$$1.4 \times r / p - 0.45 \leq d / p \leq 0.4 \times r / + 1.58 \qquad expression ( 52 )$$

$$1.15 \times r / p - 0.24 \leq d / p \leq 1.49 \times r / p + 0.54 \qquad expression ( 53 )$$

$$5.6 \times r / p - 1.34 \leq d / p \leq 4 \times r / p - 0.3 \qquad expression ( 54 )$$

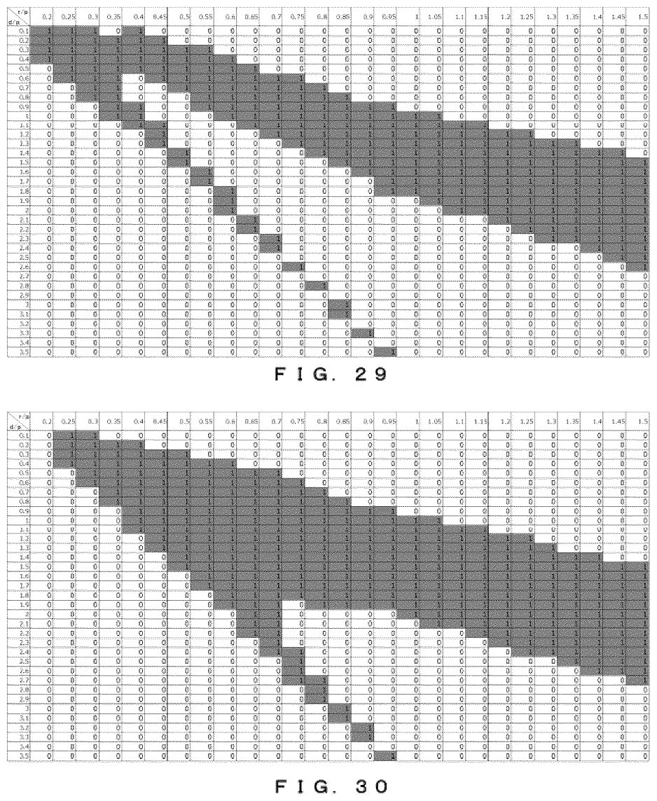

FIG. 30 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. Also, in the simulation test the result of which is illustrated in FIG. 30, the distribution of the luminance is simulated in four conditions of first to fourth conditions regarding the refractive index of the optical sheet 20 and the value of w/p as in the simulation test the result of which is illustrated in FIG. 27 except for matters described below. In the simulation test the result of which is illustrated in FIG. 30, the first to fourth conditions are determined as follows. In the first condition, the refractive index of the optical sheet 20 is 1.50, the pitch p of the light-emitting portions 13 and the widths w of the light-emitting portions 13 are determined such that the value of w/p is 0.2, the radii of curvature r and the distances d are changed, the values of r/p and d/p are consequently changed, and the distribution of the luminance is simulated. In the second condition, the refractive index of the optical sheet 20 is 1.60, the pitch p of the light-emitting portions 13 and the widths w of the light-emitting portions 13 are determined such that the value of w/p is 0.2, the radii of curvature r and the distances d are changed, the values of r/p and d/p are consequently changed, and the distribution of the luminance is simulated. In the third condition, the refractive index of the optical sheet 20 is 1.50, the pitch p of the light-emitting portions 13 and the widths w of the light-emitting portions 13 are determined such that the value of w/p is 0.3, the radii of curvature r and the distances d are changed, the values of r/p and d/p are consequently changed, and the distribution of the luminance is simulated. In the fourth condition, the refractive index of the optical sheet 20 is 1.60, the pitch p of the light-emitting portions 13 and the widths w of the light-emitting portions 13 are determined such that the value of w/p is 0.3, the radii of curvature r and the distances d are changed, the values of r/p and d/p are consequently changed, and the distribution of the luminance is simulated. In the table illustrated in FIG. 30, “1” and “0” mean the same as “1” and “0” in the table illustrated in FIG. 27.

It can be understood also from the result of the test illustrated in FIG. 30, when at least r/p is 0.25 or more and less than 0.725 and the expression (51) is satisfied, r/p is 0.725 or more and less than 0.975 and the expression (52) is satisfied, r/p is 0.975 or more and less than 1.5 and the expression (53) is satisfied, or r/p is 0.725 or more and less than 0.975 and the expression (54) is satisfied, the condition of the luminance described above is satisfied.

In particular, it can be understood from FIG. 30 illustrating whether the condition of the luminance described above is satisfied in the first to fourth conditions that in the case where the refractive index of the optical sheet 20 is 1.50 or more and 1.60 or less, and the value of w/p is 0.2 or more and less than 0.3, when at least r/p is 0.25 or more and less than 0.725 and the expression (51) is satisfied, r/p is 0.725 or more and less than 0.975 and the expression (52) is satisfied, r/p is 0.975 or more and less than 1.5 and the expression (53) is satisfied, or r/p is 0.725 or more and less than 0.975 and the expression (54) is satisfied, the condition of the luminance described above is stably satisfied.

In the case where w/p is 0.3 or more and less than 0.4, what is preferable is that at least r/p is 0.35 or more and less than 0.975 and an expression (55) below is satisfied, or r/p is 0.975 or more and less than 1.5 and an expression (56) below is satisfied. This enables the luminance of the display device 1 to be 150% or more of the luminance of the light-emitting substrate 10 that the optical sheet 20 does not overlap and enables the minimum value m described above to be 50% or more of the maximum value M.

$$\begin{matrix}[ Math 28 ] & \\ 1.45 \times r / p - 0.5 \leq d / p \leq 4.45 \times r / p - 0.77 & expression ( 55 )\end{matrix}$$

$$1.16 \times r / p - 0.25 \leq d / p \leq 0.35 \times r / p + 2.51 \qquad expression ( 56 )$$

FIG. 31 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. Also, in the simulation test the result of which is illustrated in FIG. 31, the distribution of the luminance is simulated in four conditions of first to fourth conditions regarding the refractive index of the optical sheet 20 and the value of w/p as in the simulation test the result of which is illustrated in FIG. 27 except for matters described below. In the simulation test the result of which is illustrated in FIG. 31, the first to fourth conditions are determined as follows. In the first condition, the refractive index of the optical sheet 20 is 1.50, the pitch p of the light-emitting portions 13 and the widths w of the light-emitting portions 13 are determined such that the value of w/p is 0.3, the radii of curvature r and the distances d are changed, the values of r/p and d/p are consequently changed, and the distribution of the luminance is simulated. In the second condition, the refractive index of the optical sheet 20 is 1.60, the pitch p of the light-emitting portions 13 and the widths w of the light-emitting portions 13 are determined such that the value of w/p is 0.3, the radii of curvature r and the distances d are changed, the values of r/p and d/p are consequently changed, and the distribution of the luminance is simulated. In the third condition, the refractive index of the optical sheet 20 is 1.50, the pitch p of the light-emitting portions 13 and the widths w of the light-emitting portions 13 are determined such that the value of w/p is 0.4, the radii of curvature r and the distances d are changed, the values of r/p and d/p are consequently changed, and the distribution of the luminance is simulated. In the fourth condition, the refractive index of the optical sheet 20 is 1.60, the pitch p of the light-emitting portions 13 and the widths w of the light-emitting portions 13 are determined such that the value of w/p is 0.4, the radii of curvature r and the distances d are changed, the values of r/p and d/p are consequently changed, and the distribution of the luminance is simulated. In the table illustrated in FIG. 31, “1” and “0” mean the same as “1” and “0” in the table illustrated in FIG. 27.

It can be understood also from the result of the test illustrated in FIG. 31 that when at least r/p is 0.35 or more and less than 0.975 and the expression (55) is satisfied, or r/p is 0.975 or more and less than 1.5 and the expression (56) is satisfied, the condition of the luminance described above is satisfied.

In particular, it can be understood from FIG. 31 illustrating whether the condition of the luminance described above is satisfied in the first to fourth conditions that in the case where the refractive index of the optical sheet 20 is 1.50 or more and 1.60 or less, and the value of w/p is 0.3 or more and less than 0.4, when at least r/p is 0.35 or more and less than 0.975 and the expression (55) is satisfied, or r/p is 0.975 or more and less than 1.5 and the expression (56) is satisfied, the condition of the luminance described above is stably satisfied.

In the case where w/p is 0.4 or more and less than 0.5, what is preferable is that at least r/p is 0.4 or more and less than 0.675 and an expression (57) below is satisfied, or r/p is 0.675 or more and less than 1.5 and an expression (58) below is satisfied. This enables the luminance of the display device 1 to be 150% or more of the luminance of the light-emitting substrate 10 that the optical sheet 20 does not overlap and enables the minimum value m described above to be 50% or more of the maximum value M.

$$\begin{matrix}[ Math 29 ] & \\ 1.77 \times r / p - 0.68 \leq d / p \leq 5.43 \times r / p - 1.43 & expression ( 57 )\end{matrix}$$

$$1.13 \times r / p - 0.22 \leq d / p \leq 3.23 \times r / p + 0.13 \qquad expression ( 58 )$$

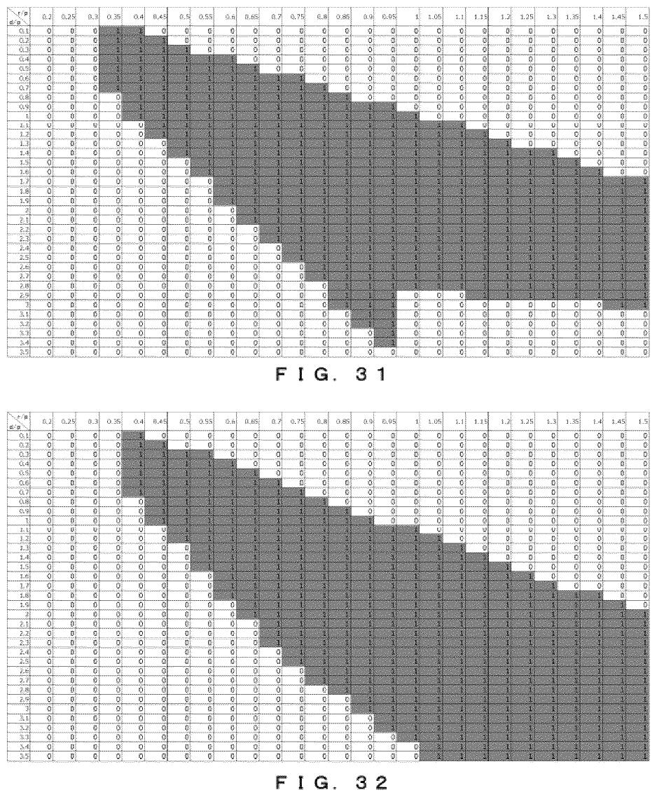

FIG. 32 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. Also, in the simulation test the result of which is illustrated in FIG. 32, the distribution of the luminance is simulated in four conditions of first to fourth conditions regarding the refractive index of the optical sheet 20 and the value of w/p as in the simulation test the result of which is illustrated in FIG. 27 except for matters described below. In the simulation test the result of which is illustrated in FIG. 32, the first to fourth conditions are determined as follows. In the first condition, the refractive index of the optical sheet 20 is 1.50, the pitch p of the light-emitting portions 13 and the widths w of the light-emitting portions 13 are determined such that the value of w/p is 0.4, the radii of curvature r and the distances d are changed, the values of r/p and d/p are consequently changed, and the distribution of the luminance is simulated. In the second condition, the refractive index of the optical sheet 20 is 1.60, the pitch p of the light-emitting portions 13 and the widths w of the light-emitting portions 13 are determined such that the value of w/p is 0.4, the radii of curvature r and the distances d are changed, the values of r/p and d/p are consequently changed, and the distribution of the luminance is simulated. In the third condition, the refractive index of the optical sheet 20 is 1.50, the pitch p of the light-emitting portions 13 and the widths w of the light-emitting portions 13 are determined such that the value of w/p is 0.5, the radii of curvature r and the distances d are changed, the values of r/p and d/p are consequently changed, and the distribution of the luminance is simulated. In the fourth condition, the refractive index of the optical sheet 20 is 1.60, the pitch p of the light-emitting portions 13 and the widths w of the light-emitting portions 13 are determined such that the value of w/p is 0.5, the radii of curvature r and the distances d are changed, the values of r/p and d/p are consequently changed, and the distribution of the luminance is simulated. In the table illustrated in FIG. 32, “1” and “0” mean the same as “1” and “0” in the table illustrated in FIG. 27.

It can be understood also from the result of the test illustrated in FIG. 32 that when at least r/p is 0.4 or more and less than 0.675 and the expression (57) is satisfied, or r/p is 0.675 or more and less than 1.5 and the expression (58) is satisfied, the condition of the luminance described above is satisfied.

In particular, it can be understood from FIG. 32 illustrating whether the condition of the luminance described above is satisfied in the first to fourth conditions that in the case where the refractive index of the optical sheet 20 is 1.50 or more and 1.60 or less, and the value of w/p is 0.4 or more and less than 0.5, when at least r/p is 0.4 or more and less than 0.675 and the expression (57) is satisfied, or r/p is 0.675 or more and less than 1.5 and the expression (58) is satisfied, the condition of the luminance described above is stably satisfied.

In the case where w/p is 0.5 or more and less than 0.6, what is preferable is that at least r/p is 0.5 or more and less than 0.675 and an expression (59) below is satisfied, or r/p is 0.675 or more and less than 1.5 and an expression (60) below is satisfied. This enables the luminance of the display device 1 to be 150% or more of the luminance of the light-emitting substrate 10 that the optical sheet 20 does not overlap and enables the minimum value m described above to be 50% or more of the maximum value M.

$$\begin{matrix}[ Math 30 ] & \\ 2.6 \times r / p - 1.17 \leq d / p \leq 6.6 \times r / p - 2.27 & expression ( 59 )\end{matrix}$$

$$1.27 \times r / p - 0.33 \leq d / p \leq 3.3 \times r / p - 0.06 \qquad expression ( 60 )$$

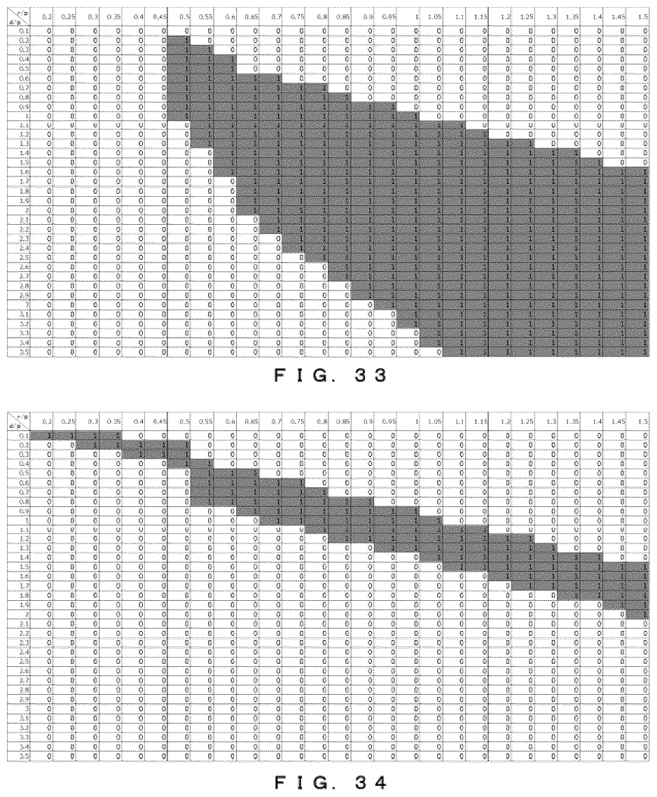

FIG. 33 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. Also, in the simulation test the result of which is illustrated in FIG. 33, the distribution of the luminance is simulated in four conditions of first to fourth conditions regarding the refractive index of the optical sheet 20 and the value of w/p as in the simulation test the result of which is illustrated in FIG. 27 except for matters described below. In the simulation test the result of which is illustrated in FIG. 33, the first to fourth conditions are determined as follows. In the first condition, the refractive index of the optical sheet 20 is 1.50, the pitch p of the light-emitting portions 13 and the widths w of the light-emitting portions 13 are determined such that the value of w/p is 0.5, the radii of curvature r and the distances d are changed, the values of r/p and d/p are consequently changed, and the distribution of the luminance is simulated. In the second condition, the refractive index of the optical sheet 20 is 1.60, the pitch p of the light-emitting portions 13 and the widths w of the light-emitting portions 13 are determined such that the value of w/p is 0.5, the radii of curvature r and the distances d are changed, the values of r/p and d/p are consequently changed, and the distribution of the luminance is simulated. In the third condition, the refractive index of the optical sheet 20 is 1.50, the pitch p of the light-emitting portions 13 and the widths w of the light-emitting portions 13 are determined such that the value of w/p is 0.6, the radii of curvature r and the distances d are changed, the values of r/p and d/p are consequently changed, and the distribution of the luminance is simulated. In the fourth condition, the refractive index of the optical sheet 20 is 1.60, the pitch p of the light-emitting portions 13 and the widths w of the light-emitting portions 13 are determined such that the value of w/p is 0.6, the radii of curvature r and the distances d are changed, the values of r/p and d/p are consequently changed, and the distribution of the luminance is simulated. In the table illustrated in FIG. 33, “1” and “0” mean the same as “1” and “0” in the table illustrated in FIG. 27.

It can be understood also from the result of the test illustrated in FIG. 33 that when at least r/p is 0.5 or more and less than 0.675 and the expression (59) is satisfied, or r/p is 0.675 or more and less than 1.5 and the expression (60) is satisfied, the condition of the luminance described above is satisfied. In particular, it can be understood from FIG. 33 illustrating whether the condition of the luminance described above is satisfied in the first to fourth conditions that in the case where the refractive index of the optical sheet 20 is 1.50 or more and 1.60 or less, and the value of w/p is 0.5 or more and less than 0.6, when at least r/p is 0.5 or more and less than 0.675 and the expression (59) is satisfied, or r/p is 0.675 or more and less than 1.5 and the expression (60) is satisfied, the condition of the luminance described above is stably satisfied.

An example of a method of manufacturing the display device 1 according to the fourth modification will now be described. The method of manufacturing the display device 1 according to the fourth modification includes the adjustment step of adjusting the radii of curvature r and the distances d depending on the value of w/p as in the display devices 1 according to the embodiment and the modifications described above.

At the adjustment step according to the fourth modification, in the case where w/p is 0.01 or more and less than 0.05, the radii of curvature r and the distances d are adjusted such that at least r/p is 0.2 or more and less than 0.525 and the expression (37) described above is satisfied, r/p is 0.525 or more and less than 0.975 and the expression (38) described above is satisfied, r/p is 0.975 or more and less than 1.5 and the expression (39) described above is satisfied, r/p is 0.2 or more and less than 0.525 and the expression (40) described above is satisfied, or r/p is 0.525 or more and less than 0.975 and the expression (41) described above is satisfied.

At the adjustment step according to the fourth modification, in the case where w/p is 0.05 or more and less than 0.1, the radii of curvature r and the distances d are adjusted such that at least r/p is 0.2 or more and less than 0.525 and the expression (42) described above is satisfied, r/p is 0.525 or more and less than 0.975 and the expression (43) described above is satisfied, r/p is 0.975 or more and less than 1.5 and the expression (44) described above is satisfied, r/p is 0.2 or more and less than 0.525 and the expression (45) described above is satisfied, or r/p is 0.525 or more and less than 0.975 and the expression (46) described above is satisfied.

At the adjustment step according to the fourth modification, in the case where w/p is 0.1 or more and less than 0.2, the radii of curvature r and the distances d are adjusted such that at least r/p is 0.2 or more and less than 0.375 and the expression (47) described above is satisfied, r/p is 0.375 or more and less than 0.975 and the expression (48) described above is satisfied, r/p is 0.975 or more and less than 1.5 and the expression (49) described above is satisfied, or r/p is 0.375 or more and less than 0.975 and the expression (50) described above is satisfied.

At the adjustment step according to the fourth modification, in the case where w/p is 0.2 or more and less than 0.3, the radii of curvature r and the distances d are adjusted such that at least r/p is 0.25 or more and less than 0.725 and the expression (51) described above is satisfied, r/p is 0.725 or more and less than 0.975 and the expression (52) described above is satisfied, r/p is 0.975 or more and less than 1.5 and the expression (53) described above is satisfied, or r/p is 0.725 or more and less than 0.975 and the expression (54) described above is satisfied.

At the adjustment step according to the fourth modification, in the case where w/p is 0.3 or more and less than 0.4, the radii of curvature r and the distances d are adjusted such that at least r/p is 0.35 or more and less than 0.975 and the expression (55) described above is satisfied, or r/p is 0.975 or more and less than 1.5 and the expression (56) described above is satisfied.

At the adjustment step according to the fourth modification, in the case where w/p is 0.4 or more and less than 0.5, the radii of curvature r and the distances d are adjusted such that at least r/p is 0.4 or more and less than 0.675 and the expression (57) described above is satisfied, or r/p is 0.675 or more and less than 1.5 and the expression (58) described above is satisfied.

At the adjustment step according to the fourth modification, in the case where w/p is 0.5 or more and less than 0.6, the radii of curvature r and the distances d are adjusted such that at least r/p is 0.5 or more and less than 0.675 and the expression (59) described above is satisfied, or r/p is 0.675 or more and less than 1.5 and the expression (60) described above is satisfied.

The method of manufacturing the display device 1 according to the fourth modification including the adjustment step described above enables the display device 1 configured such that the luminance is 150% or more of the luminance of the light-emitting substrate 10 that the optical sheet 20 does not overlap, and the minimum value m described above is 50% or more of the maximum value M to be manufactured. In particular, as for the display device 1 configured such that the light collection direction of the optical sheet 20 is the front direction of the display device 1, it is thought that the condition of the luminance according to the fourth modification is satisfied. Also, in the above manner, the pitch p of the light-emitting portions 13, the widths w of the light-emitting portions 13, the radii of curvature r, and the distances d are adjusted as described according to the fourth modification, and consequently, the luminance in a direction that forms an angle with respect to the light collection direction can be ensured while the luminance in the light collection direction is increased.

### (Fifth Modification)

A fifth modification relates to an example in which the conditions of the values of the radii of curvature r and the distances d that enable the luminance of the display device 1 to be 150% or more of the luminance of the light-emitting substrate 10 that the optical sheet 20 does not overlap and that enable the minimum value m2 described above to be 50% or more of the maximum value M2 for every value of w/p are determined from a perspective that differs from that according to the embodiment and the modifications described above.

The following description contains the conditions of the values of the radii of curvature r and the distances d that enable the luminance of the display device 1 to be 150% or more of the luminance of the light-emitting substrate 10 that the optical sheet 20 does not overlap and that enable the minimum value m2 described above to be 50% or more of the maximum value M2 for every value of w/p according to the fifth modification. In particular, the following description contains a modification to the conditions of the values of the radii of curvature r and the distances d that enable the condition of the luminance described above to be satisfied regarding the display device 1 configured such that the light collection direction of the optical sheet 20 is the front direction of the display device 1.

In the case where w/p is 0.01 or more and less than 0.05, what is preferable is that at least r/p is 0.2 or more and less than 0.525 and an expression (61) below is satisfied, or r/p is 0.525 or more and less than 1.5 and an expression (62) below is satisfied. This enables the luminance of the display device 1 to be 150% or more of the luminance of the light-emitting substrate 10 that the optical sheet 20 does not overlap and enables the minimum value m2 described above to be 50% or more of the maximum value M2.

$$\begin{matrix}[ Math 31 ] & \\ 0.21 \times r / p + 0.02 \leq d / p \leq 1 \times r / p - 0.08 & expression ( 61 )\end{matrix}$$

$$1.17 \times r / p - 0.28 \leq d / p \leq 1.26 \times r / p + 0.13 \qquad expression ( 60 )$$

FIG. 34 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. In the simulation test the result of which is illustrated in FIG. 34, the distribution of the luminance is simulated in four conditions of first to fourth conditions regarding the refractive index of the optical sheet 20 and the value of w/p. In the simulation test the result of which is illustrated in FIG. 34, the first to fourth conditions are determined as follows. In the first condition, the refractive index of the optical sheet 20 is 1.50, the pitch p of the light-emitting portions 13 and the widths w of the light-emitting portions 13 are determined such that the value of w/p is 0.01, the radii of curvature r and the distances d are changed, the values of r/p and d/p are consequently changed, and the distribution of the luminance is simulated. In the second condition, the refractive index of the optical sheet 20 is 1.60, the pitch p of the light-emitting portions 13 and the widths w of the light-emitting portions 13 are determined such that the value of w/p is 0.01, the radii of curvature r and the distances d are changed, the values of r/p and d/p are consequently changed, and the distribution of the luminance is simulated. In the third condition, the refractive index of the optical sheet 20 is 1.50, the pitch p of the light-emitting portions 13 and the widths w of the light-emitting portions 13 are determined such that the value of w/p is 0.05, the radii of curvature r and the distances d are changed, the values of r/p and d/p are consequently changed, and the distribution of the luminance is simulated. In the fourth condition, the refractive index of the optical sheet 20 is 1.60, the pitch p of the light-emitting portions 13 and the widths w of the light-emitting portions 13 are determined such that the value of w/p is 0.05, the radii of curvature r and the distances d are changed, the values of r/p and d/p are consequently changed, and the distribution of the luminance is simulated. In the table illustrated in FIG. 34, “1” means that the luminance of the display device 1 is 150% or more of the luminance of the light-emitting substrate 10 that the optical sheet 20 does not overlap, and the minimum value m2 described above is 50% or more of the maximum value M2 for the corresponding values of r/p and d/p in all of the first to fourth conditions. For example, “1” is illustrated in a column in the table where r/p is 0.2, and d/p is 0.1. This means that the radii of curvature r and the distances d are determined such that r/p is 0.2, and d/p is 0.1 in the first to fourth conditions, the distribution of the luminance is simulated, and consequently, the condition of the luminance described above is satisfied in all of the first to fourth conditions. In the table illustrated in FIG. 34, “0” means that at least the luminance of the display device 1 is not 150% or more of the luminance of the light-emitting substrate 10 that the optical sheet 20 does not overlap, or the minimum value m2 described above is not 50% or more of the maximum value M2 for the corresponding values of r/p and d/p at least in any one of the first to fourth conditions. For example, “0” is illustrated in a column in the table where r/p is 0.2, and d/p is 0.2. This means that the radii of curvature r and the distances d are determined such that r/p is 0.2, and d/p is 0.2 in the first to fourth conditions, the distribution of the luminance is simulated, and consequently, the condition of the luminance described above is not satisfied at least in any one of the first to fourth conditions.

It can be understood also from the result of the test illustrated in FIG. 34 that when at least r/p is 0.2 or more and less than 0.525 and the expression (61) is satisfied, or r/p is 0.525 or more and less than 1.5 and the expression (62) is satisfied, the condition of the luminance described above is satisfied.

In particular, it can be understood from FIG. 34 illustrating whether the condition of the luminance described above is satisfied in the first to fourth conditions that in the case where the refractive index of the optical sheet 20 is 1.50 or more and 1.60 or less, and the value of w/p is 0.01 or more and less than 0.05, when at least r/p is 0.2 or more and less than 0.525 and the expression (61) is satisfied, or r/p is 0.525 or more and less than 1.5 and the expression (62) is satisfied, the condition of the luminance described above is stably satisfied.

In the case where w/p is 0.05 or more and less than 0.1, what is preferable is that at least r/p is 0.2 or more and less than 0.525 and an expression (63) below is satisfied, or r/p is 0.525 or more and less than 1.5 and an expression (64) below is satisfied. This enables the luminance of the display device 1 to be 150% or more of the luminance of the light-emitting substrate 10 that the optical sheet 20 does not overlap and enables the minimum value m2 described above to be 50% or more of the maximum value M2.

$$\begin{matrix}[ Math 32 ] & \\ 0.21 \times r / p + 0.02 \leq d / p \leq 1 \times r / p - 0.08 & expression ( 63 )\end{matrix}$$

$$1.17 \times r / p - 0.28 \leq d / p \leq 1.26 \times r / p + 0.14 \qquad expression ( 64 )$$

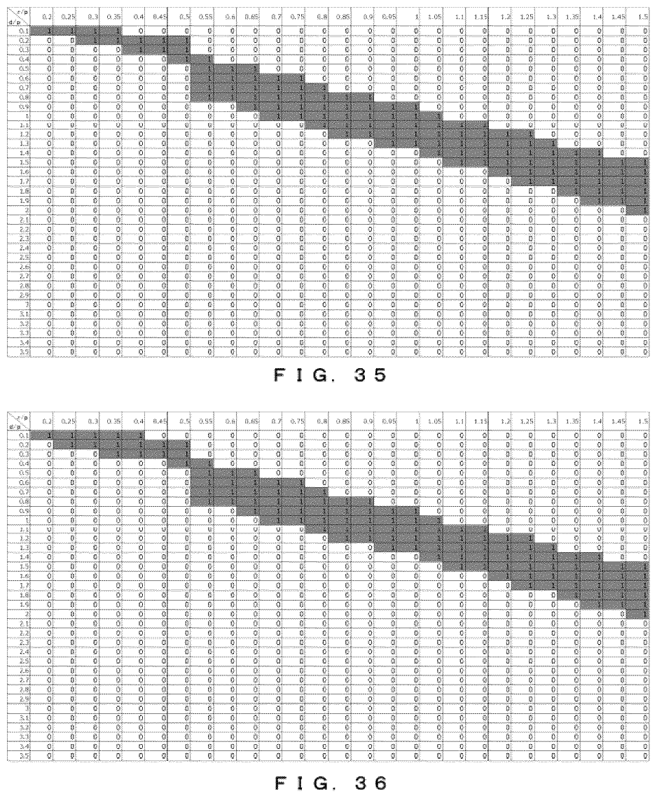

FIG. 35 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. Also, in the simulation test the result of which is illustrated in FIG. 35, the distribution of the luminance is simulated in four conditions of first to fourth conditions regarding the refractive index of the optical sheet 20 and the value of w/p as in the simulation test the result of which is illustrated in FIG. 34 except for matters described below. In the simulation test the result of which is illustrated in FIG. 35, the first to fourth conditions are determined as follows. In the first condition, the refractive index of the optical sheet 20 is 1.50, the pitch p of the light-emitting portions 13 and the widths w of the light-emitting portions 13 are determined such that the value of w/p is 0.05, the radii of curvature r and the distances d are changed, the values of r/p and d/p are consequently changed, and the distribution of the luminance is simulated. In the second condition, the refractive index of the optical sheet 20 is 1.60, the pitch p of the light-emitting portions 13 and the widths w of the light-emitting portions 13 are determined such that the value of w/p is 0.05, the radii of curvature r and the distances d are changed, the values of r/p and d/p are consequently changed, and the distribution of the luminance is simulated. In the third condition, the refractive index of the optical sheet 20 is 1.50, the pitch p of the light-emitting portions 13 and the widths w of the light-emitting portions 13 are determined such that the value of w/p is 0.1, the radii of curvature r and the distances d are changed, the values of r/p and d/p are consequently changed, and the distribution of the luminance is simulated. In the fourth condition, the refractive index of the optical sheet 20 is 1.60, the pitch p of the light-emitting portions 13 and the widths w of the light-emitting portions 13 are determined such that the value of w/p is 0.1, the radii of curvature r and the distances d are changed, the values of r/p and d/p are consequently changed, and the distribution of the luminance is simulated. In the table illustrated in FIG. 35, “1” and “0” mean the same as “1” and “0” in the table illustrated in FIG. 34.

It can be understood also from the result of the test illustrated in FIG. 35 that when at least r/p is 0.2 or more and less than 0.525 and the expression (63) is satisfied, or r/p is 0.525 or more and less than 1.5 and the expression (64) is satisfied, the condition of the luminance described above is satisfied.

In particular, it can be understood from FIG. 35 illustrating whether the condition of the luminance described above is satisfied in the first to fourth conditions that in the case where the refractive index of the optical sheet 20 is 1.50 or more and 1.60 or less, and the value of w/p is 0.05 or more and less than 0.1, when at least r/p is 0.2 or more and less than 0.525 and the expression (63) is satisfied, or r/p is 0.525 or more and less than 1.5 and the expression (64) is satisfied, the condition of the luminance described above is stably satisfied.

In the case where w/p is 0.1 or more and less than 0.2, what is preferable is that at least r/p is 0.2 or more and less than 0.525 and an expression (65) below is satisfied, or r/p is 0.525 or more and less than 1.5 and an expression (66) below is satisfied. This enables the luminance of the display device 1 to be 150% or more of the luminance of the light-emitting substrate 10 that the optical sheet 20 does not overlap and enables the minimum value m2 described above to be 50% or more of the maximum

$$\begin{matrix}[ Math 33 ] & \\ 0.21 \times r / p + 0.01 \leq d / p \leq 0.71 \times r / p + 0.05 & expression ( 65 )\end{matrix}$$

$$1.17 \times r / p - 0.28 \leq d / p \leq 1.26 \times r / p + 0.14 \qquad expression ( 66 )$$

FIG. 36 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. Also, in the simulation test the result of which is illustrated in FIG. 36, the distribution of the luminance is simulated in four conditions of first to fourth conditions regarding the refractive index of the optical sheet 20 and the value of w/p as in the simulation test the result of which is illustrated in FIG. 34 except for matters described below. In the simulation test the result of which is illustrated in FIG. 36, the first to fourth conditions are determined as follows. In the first condition, the refractive index of the optical sheet 20 is 1.50, the pitch p of the light-emitting portions 13 and the widths w of the light-emitting portions 13 are determined such that the value of w/p is 0.1, the radii of curvature r and the distances d are changed, the values of r/p and d/p are consequently changed, and the distribution of the luminance is simulated. In the second condition, the refractive index of the optical sheet 20 is 1.60, the pitch p of the light-emitting portions 13 and the widths w of the light-emitting portions 13 are determined such that the value of w/p is 0.1, the radii of curvature r and the distances d are changed, the values of r/p and d/p are consequently changed, and the distribution of the luminance is simulated. In the third condition, the refractive index of the optical sheet 20 is 1.50, the pitch p of the light-emitting portions 13 and the widths w of the light-emitting portions 13 are determined such that the value of w/p is 0.2, the radii of curvature r and the distances d are changed, the values of r/p and d/p are consequently changed, and the distribution of the luminance is simulated. In the fourth condition, the refractive index of the optical sheet 20 is 1.60, the pitch p of the light-emitting portions 13 and the widths w of the light-emitting portions 13 are determined such that the value of w/p is 0.2, the radii of curvature r and the distances d are changed, the values of r/p and d/p are consequently changed, and the distribution of the luminance is simulated. In the table illustrated in FIG. 36, “1” and “0” mean the same as “1” and “0” in the table illustrated in FIG. 34.

It can be understood also from the result of the test illustrated in FIG. 36 that when at least r/p is 0.2 or more and less than 0.525 and the expression (65) is satisfied, or r/p is 0.525 or more and less than 1.5 and the expression (66) is satisfied, the condition of the luminance described above is satisfied.

In particular, it can be understood from FIG. 36 illustrating whether the condition of the luminance described above is satisfied in the first to fourth conditions that in the case where the refractive index of the optical sheet 20 is 1.50 or more and 1.60 or less, and the value of w/p is 0.1 or more and less than 0.2, when at least r/p is 0.2 or more and less than 0.525 and the expression (65) is satisfied, or r/p is 0.525 or more and less than 1.5 and the expression (66) is satisfied, the condition of the luminance described above is stably satisfied.

In the case where w/p is 0.2 or more and less than 0.3, what is preferable is that at least r/p is 0.25 or more and less than 0.525 and an expression (67) below is satisfied, or r/p is 0.525 or more and less than 1.5 and an expression (68) below is satisfied. This enables the luminance of the display device 1 to be 150% or more of the luminance of the light-emitting substrate 10 that the optical sheet 20 does not overlap and enables the minimum value m2 described above to be 50% or more of the maximum value M2.

$$\begin{matrix}[ Math 34 ] & \\ 0.29 \times r / p - 0.05 \leq d / p \leq - 0.23 \times r / p + 0.62 & expression ( 67 )\end{matrix}$$

$$1.2 \times r / p - 0.3 \leq d / p \leq 1.2 \times r / p + 0.21 \qquad expression ( 68 )$$

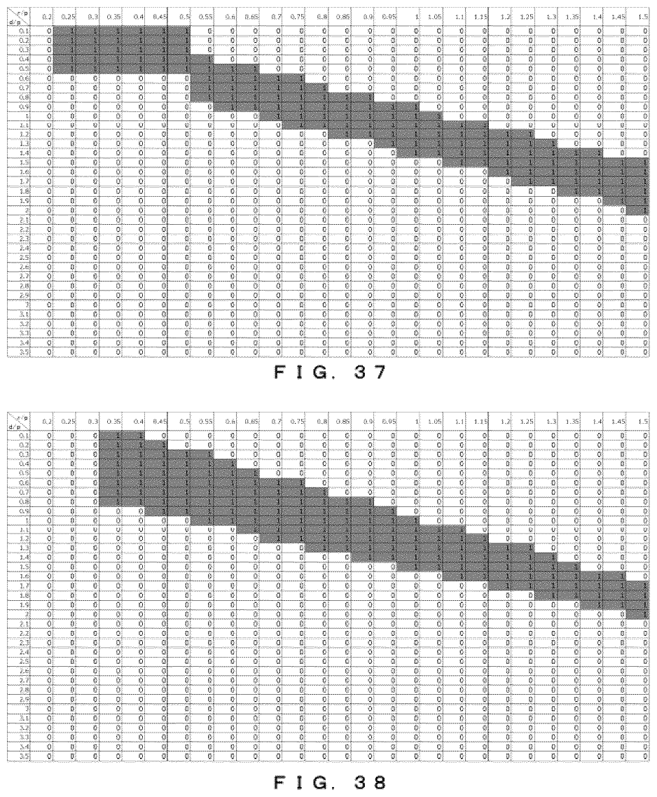

FIG. 37 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. Also, in the simulation test the result of which is illustrated in FIG. 37, the distribution of the luminance is simulated in four conditions of first to fourth conditions regarding the refractive index of the optical sheet 20 and the value of w/p as in the simulation test the result of which is illustrated in FIG. 34 except for matters described below. In the simulation test the result of which is illustrated in FIG. 37, the first to fourth conditions are determined as follows. In the first condition, the refractive index of the optical sheet 20 is 1.50, the pitch p of the light-emitting portions 13 and the widths w of the light-emitting portions 13 are determined such that the value of w/p is 0.2, the radii of curvature r and the distances d are changed, the values of r/p and d/p are consequently changed, and the distribution of the luminance is simulated. In the second condition, the refractive index of the optical sheet 20 is 1.60, the pitch p of the light-emitting portions 13 and the widths w of the light-emitting portions 13 are determined such that the value of w/p is 0.2, the radii of curvature r and the distances d are changed, the values of r/p and d/p are consequently changed, and the distribution of the luminance is simulated. In the third condition, the refractive index of the optical sheet 20 is 1.50, the pitch p of the light-emitting portions 13 and the widths w of the light-emitting portions 13 are determined such that the value of w/p is 0.3, the radii of curvature r and the distances d are changed, the values of r/p and d/p are consequently changed, and the distribution of the luminance is simulated. In the fourth condition, the refractive index of the optical sheet 20 is 1.60, the pitch p of the light-emitting portions 13 and the widths w of the light-emitting portions 13 are determined such that the value of w/p is 0.3, the radii of curvature r and the distances d are changed, the values of r/p and d/p are consequently changed, and the distribution of the luminance is simulated. In the table illustrated in FIG. 37, “1” and “0” mean the same as “1” and “0” in the table illustrated in FIG. 34.

It can be understood also from the result of the test illustrated in FIG. 37 that when at least r/p is 0.25 or more and less than 0.525 and the expression (67) is satisfied, or r/p is 0.525 or more and less than 1.5 and the expression (68) is satisfied, the condition of the luminance described above is satisfied.

In particular, it can be understood from FIG. 37 illustrating whether the condition of the luminance described above is satisfied in the first to fourth conditions that in the case where the refractive index of the optical sheet 20 is 1.50 or more and 1.60 or less, and the value of w/p is 0.2 or more and less than 0.3, when at least r/p is 0.25 or more and less than 0.525 and the expression (67) is satisfied, or r/p is 0.525 or more and less than 1.5 and the expression (68) is satisfied, the condition of the luminance described above is stably satisfied.

In the case where w/p is 0.3 or more and less than 0.4, what is preferable is that at least r/p is 0.35 or more and less than 0.675 and an expression (69) below is satisfied, or r/p is 0.675 or more and less than 1.5 and an expression (70) below is satisfied. This enables the luminance of the display device 1 to be 150% or more of the luminance of the light-emitting substrate 10 that the optical sheet 20 does not overlap and enables the minimum value m2 described above to be 50% or more of the maximum value M2.

$$\begin{matrix}[ Math 35 ] & \\ 1.43 \times r / p - 0.49 \leq d / p \leq 1.07 \times r / p + 0.45 & expression ( 69 )\end{matrix}$$

$$1.19 \times r / p - 0.28 \leq d / p \leq 1 \times r / p + 0.5 \qquad expression ( 70 )$$

FIG. 38 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. Also, in the simulation test the result of which is illustrated in FIG. 38, the distribution of the luminance is simulated in four conditions of first to fourth conditions regarding the refractive index of the optical sheet 20 and the value of w/p as in the simulation test the result of which is illustrated in FIG. 34 except for matters described below. In the simulation test the result of which is illustrated in FIG. 38, the first to fourth conditions are determined as follows. In the first condition, the refractive index of the optical sheet 20 is 1.50, the pitch p of the light-emitting portions 13 and the widths w of the light-emitting portions 13 are determined such that the value of w/p is 0.3, the radii of curvature r and the distances d are changed, the values of r/p and d/p are consequently changed, and the distribution of the luminance is simulated. In the second condition, the refractive index of the optical sheet 20 is 1.60, the pitch p of the light-emitting portions 13 and the widths w of the light-emitting portions 13 are determined such that the value of w/p is 0.3, the radii of curvature r and the distances d are changed, the values of r/p and d/p are consequently changed, and the distribution of the luminance is simulated. In the third condition, the refractive index of the optical sheet 20 is 1.50, the pitch p of the light-emitting portions 13 and the widths w of the light-emitting portions 13 are determined such that the value of w/p is 0.4, the radii of curvature r and the distances d are changed, the values of r/p and d/p are consequently changed, and the distribution of the luminance is simulated. In the fourth condition, the refractive index of the optical sheet 20 is 1.60, the pitch p of the light-emitting portions 13 and the widths w of the light-emitting portions 13 are determined such that the value of w/p is 0.4, the radii of curvature r and the distances d are changed, the values of r/p and d/p are consequently changed, and the distribution of the luminance is simulated. In the table illustrated in FIG. 38, “1” and “0” mean the same as “1” and “0” in the table illustrated in FIG. 34.

It can be understood also from the result of the test illustrated in FIG. 38 that when at least r/p is 0.35 or more and less than 0.675 and the expression (69) is satisfied, or r/p is 0.675 or more and less than 1.5 and the expression (70) is satisfied, the condition of the luminance described above is satisfied.

In particular, it can be understood from FIG. 38 illustrating whether the condition of the luminance described above is satisfied in the first to fourth conditions that in the case where the refractive index of the optical sheet 20 is 1.50 or more and 1.60 or less, and the value of w/p is 0.3 or more and less than 0.4, when at least r/p is 0.35 or more and less than 0.675 and the expression (69) is satisfied, or r/p is 0.675 or more and less than 1.5 and the expression (70) is satisfied, the condition of the luminance described above is stably satisfied.

In the case where w/p is 0.4 or more and less than 0.5, what is preferable is that at least r/p is 0.4 or more and less than 0.675 and an expression (71) below is satisfied, or r/p is 0.675 or more and less than 1.5 and an expression (72) below is satisfied. This enables the luminance of the display device 1 to be 150% or more of the luminance of the light-emitting substrate 10 that the optical sheet 20 does not overlap and enables the minimum value m2 described above to be 50% or more of the maximum

$$\begin{matrix}[ Math 36 ] & \\ 1.77 \times r / p - 0.68 \leq d / p \leq 2.86 \times r / p - 0.23 & expression ( 71 )\end{matrix}$$

$$1.15 \times r / p - 0.23 \leq d / p \leq 0.64 \times r / p + 1.13 \qquad expression ( 72 )$$

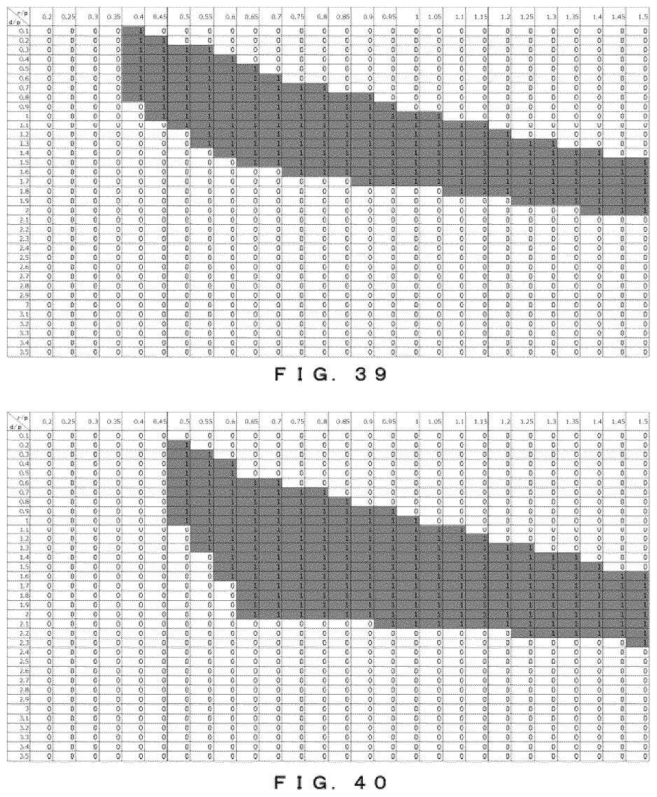

FIG. 39 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. Also, in the simulation test the result of which is illustrated in FIG. 39, the distribution of the luminance is simulated in four conditions of first to fourth conditions regarding the refractive index of the optical sheet 20 and the value of w/p as in the simulation test the result of which is illustrated in FIG. 34 except for matters described below. In the simulation test the result of which is illustrated in FIG. 38, the first to fourth conditions are determined as follows. In the first condition, the refractive index of the optical sheet 20 is 1.50, the pitch p of the light-emitting portions 13 and the widths w of the light-emitting portions 13 are determined such that the value of w/p is 0.4, the radii of curvature r and the distances d are changed, the values of r/p and d/p are consequently changed, and the distribution of the luminance is simulated. In the second condition, the refractive index of the optical sheet 20 is 1.60, the pitch p of the light-emitting portions 13 and the widths w of the light-emitting portions 13 are determined such that the value of w/p is 0.4, the radii of curvature r and the distances d are changed, the values of r/p and d/p are consequently changed, and the distribution of the luminance is simulated. In the third condition, the refractive index of the optical sheet 20 is 1.50, the pitch p of the light-emitting portions 13 and the widths w of the light-emitting portions 13 are determined such that the value of w/p is 0.5, the radii of curvature r and the distances d are changed, the values of r/p and d/p are consequently changed, and the distribution of the luminance is simulated. In the fourth condition, the refractive index of the optical sheet 20 is 1.60, the pitch p of the light-emitting portions 13 and the widths w of the light-emitting portions 13 are determined such that the value of w/p is 0.5, the radii of curvature r and the distances d are changed, the values of r/p and d/p are consequently changed, and the distribution of the luminance is simulated. In the table illustrated in FIG. 39, “1” and “0” mean the same as “1” and “0” in the table illustrated in FIG. 34.

It can be understood also from the result of the test illustrated in FIG. 39 that when at least r/p is 0.4 or more and less than 0.675 and the expression (71) is satisfied, or r/p is 0.675 or more and less than 1.5 and the expression (72) is satisfied, the condition of the luminance described above is satisfied. In particular, it can be understood from FIG. 39 illustrating whether the condition of the luminance described above is satisfied in the first to fourth conditions that in the case where the refractive index of the optical sheet 20 is 1.50 or more and 1.60 or less, and the value of w/p is 0.4 or more and less than 0.5, when at least r/p is 0.4 or more and less than 0.675 and the expression (71) is satisfied, or r/p is 0.675 or more and less than 1.5 and the expression (72) is satisfied, the condition of the luminance described above is stably satisfied.

In the case where w/p is 0.5 or more and less than 0.6, what is preferable is that at least r/p is 0.5 or more and less than 0.675 and an expression (73) below is satisfied, or r/p is 0.675 or more and less than 1.5 and an expression (74) below is satisfied. This enables the luminance of the display device 1 to be 150% or more of the luminance of the light-emitting substrate 10 that the optical sheet 20 does not overlap and enables the minimum value m2 described above to be 50% or more of the maximum value M2.

$$\begin{matrix}[ Math 37 ] & \\ 2.6 \times r / p - 1.17 \leq d / p \leq 6.6 \times r / p - 2.27 & expression ( 73 )\end{matrix}$$

$$1.27 \times r / p - 0.33 \leq d / p \leq 0.35 \times r / p + 1.78 \qquad expression ( 74 )$$

FIG. 40 is a table illustrating the result of a test in which the pitch p of the light-emitting portions 13, the widths w of the light-emitting portions 13, the radii of curvature r, and the distances d are set, and the distribution of the luminance in the direction perpendicular to the second direction d2 is simulated regarding the display device 1 illustrated in FIG. 1 to FIG. 5. Also, in the simulation test the result of which is illustrated in FIG. 40, the distribution of the luminance is simulated in four conditions of first to fourth conditions regarding the refractive index of the optical sheet 20 and the value of w/p as in the simulation test the result of which is illustrated in FIG. 34 except for matters described below. In the simulation test the result of which is illustrated in FIG. 40, the first to fourth conditions are determined as follows. In the first condition, the refractive index of the optical sheet 20 is 1.50, the pitch p of the light-emitting portions 13 and the widths w of the light-emitting portions 13 are determined such that the value of w/p is 0.5, the radii of curvature r and the distances d are changed, the values of r/p and d/p are consequently changed, and the distribution of the luminance is simulated. In the second condition, the refractive index of the optical sheet 20 is 1.60, the pitch p of the light-emitting portions 13 and the widths w of the light-emitting portions 13 are determined such that the value of w/p is 0.5, the radii of curvature r and the distances d are changed, the values of r/p and d/p are consequently changed, and the distribution of the luminance is simulated. In the third condition, the refractive index of the optical sheet 20 is 1.50, the pitch p of the light-emitting portions 13 and the widths w of the light-emitting portions 13 are determined such that the value of w/p is 0.6, the radii of curvature r and the distances d are changed, the values of r/p and d/p are consequently changed, and the distribution of the luminance is simulated. In the fourth condition, the refractive index of the optical sheet 20 is 1.60, the pitch p of the light-emitting portions 13 and the widths w of the light-emitting portions 13 are determined such that the value of w/p is 0.6, the radii of curvature r and the distances d are changed, the values of r/p and d/p are consequently changed, and the distribution of the luminance is simulated. In the table illustrated in FIG. 40, “1” and “0” mean the same as “1” and “0” in the table illustrated in FIG. 34.

It can be understood also from the result of the test illustrated in FIG. 40 that when at least r/p is 0.5 or more and less than 0.675 and the expression (73) is satisfied, or r/p is 0.675 or more and less than 1.5 and the expression (74) is satisfied, the condition of the luminance described above is satisfied.

In particular, it can be understood from FIG. 40 illustrating whether the condition of the luminance described above is satisfied in the first to fourth conditions that in the case where the refractive index of the optical sheet 20 is 1.50 or more and 1.60 or less, and the value of w/p is 0.5 or more and less than 0.6, when at least r/p is 0.5 or more and less than 0.675 and the expression (73) is satisfied, or r/p is 0.675 or more and less than 1.5 and the expression (74) is satisfied, the condition of the luminance described above is stably satisfied.

An example of a method of manufacturing the display device 1 according to the fifth modification will now be described. The method of manufacturing the display device 1 according to the fifth modification includes the adjustment step of adjusting the radii of curvature r and the distances d depending on the value of w/p as in the display devices 1 according to the embodiment and the modifications described above.

At the adjustment step according to the fifth modification, in the case where w/p is 0.01 or more and less than 0.05, the radii of curvature r and the distances d are adjusted such that at least r/p is 0.2 or more and less than 0.525 and the expression (61) described above is satisfied, or r/p is 0.525 or more and less than 1.5 and the expression (62) described above is satisfied.

At the adjustment step according to the fifth modification, in the case where w/p is 0.05 or more and less than 0.1, the radii of curvature r and the distances d are adjusted such that at least r/p is 0.2 or more and less than 0.525 and the expression (63) described above is satisfied, or r/p is 0.525 or more and less than 1.5 and the expression (64) described above is satisfied.

At the adjustment step according to the fifth modification, in the case where w/p is 0.1 or more and less than 0.2, the radii of curvature r and the distances d are adjusted such that at least r/p is 0.2 or more and less than 0.525 and the expression (65) described above is satisfied, or r/p is 0.525 or more and less than 1.5 and the expression (66) described above is satisfied.

At the adjustment step according to the fifth modification, in the case where w/p is 0.2 or more and less than 0.3, the radii of curvature r and the distances d are adjusted such that at least r/p is 0.25 or more and less than 0.525 and the expression (67) described above is satisfied, or r/p is 0.525 or more and less than 1.5 and the expression (68) described above is satisfied.

At the adjustment step according to the fifth modification, in the case where w/p is 0.3 or more and less than 0.4, the radii of curvature r and the distances d are adjusted such that at least r/p is 0.35 or more and less than 0.675 and the expression (69) described above is satisfied, or r/p is 0.675 or more and less than 1.5 and the expression (70) described above is satisfied.

At the adjustment step according to the fifth modification, in the case where w/p is 0.4 or more and less than 0.5, the radii of curvature r and the distances d are adjusted such that at least r/p is 0.4 or more and less than 0.675 and the expression (71) described above is satisfied, or r/p is 0.675 or more and less than 1.5 and the expression (72) described above is satisfied.

At the adjustment step according to the fifth modification, in the case where w/p is 0.5 or more and less than 0.6, the radii of curvature r and the distances d are adjusted such that at least r/p is 0.5 or more and less than 0.675 and the expression (73) described above is satisfied, or r/p is 0.675 or more and less than 1.5 and the expression (74) described above is satisfied.

The method of manufacturing the display device 1 according to the fifth modification including the adjustment step described above enables the display device 1 configured such that the luminance is 150% or more of the luminance of the light-emitting substrate 10 that the optical sheet 20 does not overlap, and the minimum value m2 described above is 50% or more of the maximum value M2 to be manufactured. In particular, as for the display device 1 configured such that the light collection direction of the optical sheet 20 is the front direction of the display device 1, it is thought that the condition of the luminance according to the fifth modification is satisfied. Also, in the above manner, the pitch p of the light-emitting portions 13, the widths w of the light-emitting portions 13, the radii of curvature r, and the distances d are adjusted as described according to the fifth modification, and consequently, the luminance in a direction that forms an angle with respect to the light collection direction can be ensured while the luminance in the light collection direction is increased.

Multiple components disclosed in the embodiment and the modifications described above can be appropriately combined as needed. Alternatively, some components among all of the components disclosed in the embodiment and the modifications described above may be removed.

### REFERENCE SIGNS LIST

1 display device
10 light-emitting substrate
10a unit region
10c unit region second direction column
11 semiconductor layer
13 light-emitting portion
13R first light-emitting portion
13G second light-emitting portion
13B third light-emitting portion
20 optical sheet
20a first surface
20b second surface
21 unit lens
21a lens surface
70 light angle adjustment layer
80 light deflection layer

1. A display device comprising: a light-emitting substrate that includes a semiconductor layer that is divided into multiple unit regions and a light-emitting portion that is disposed in the multiple unit regions; and
an optical sheet that faces the light-emitting substrate,
wherein the optical sheet includes multiple unit lenses that are arranged in a first direction and that extend in a second direction unparallel with the first direction,
wherein the multiple unit regions are arranged in the first direction and the second direction, and
wherein w/p is less than 0.025, and at least r/p is 0.2 or more and less than 0.525 and an expression (1) below is satisfied, r/p is 0.525 or more and less than 1.5 and an expression (2) below is satisfied, r/p is 0.2 or more and less than 0.525 and an expression (3) below is satisfied, r/p is 0.525 or more and less than 0.725 and an expression (4) below is satisfied, or r/p is 0.725 or more and less than 1.5 and an expression (5) below is satisfied, where p is a pitch of the light-emitting portion in the first direction, w is a width of the light-emitting portion in the first direction, r is a radius of curvature of a lens surface of the unit lenses, and d is a distance between the light-emitting portion and the unit lenses,
wherein w/p is 0.025 or more and less than 0.075, and at least r/p is 0.2 or more and less than 0.525 and an expression (6) below is satisfied, r/p is 0.525 or more and less than 1.5 and an expression (7) below is satisfied, r/p is 0.2 or more and less than 0.525 and an expression (8) below is satisfied, r/p is 0.525 or more and less than 0.725 and an expression (9) below is satisfied, or r/p is 0.725 or more and less than 1.5 and an expression (10) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.075 or more and less than 0.15, and at least r/p is 0.2 or more and less than 0.375 and an expression (11) below is satisfied, r/p is 0.375 or more and less than 1.5 and an expression (12) below is satisfied, r/p is 0.2 or more and less than 0.725 and an expression (13) below is satisfied, or r/p is 0.725 or more and less than 1.5 and an expression (14) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.15 or more and less than 0.25, and at least r/p is 0.2 or more and less than 0.725 and an expression (15) below is satisfied, r/p is 0.725 or more and less than 1.5 and an expression (16) below is satisfied, or r/p is 0.2 or more and less than 1.5 and an expression (17) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.25 or more and less than 0.35, and at least r/p is 0.25 or more and less than 0.975 and an expression (18) below is satisfied, or r/p is 0.975 or more and less than 1.5 and an expression (19) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.35 or more and less than 0.45, and r/p is 0.3 or more and less than 1.5 and an expression (20) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.45 or more and less than 0.55, and r/p is 0.4 or more and less than 1.5 and an expression (21) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.55 or more and less than 0.65, and r/p is 0.45 or more and less than 1.5 and an expression (22) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.01 or more and less than 0.05, and at least r/p is 0.2 or more and less than 0.525 and an expression (37) below is satisfied, r/p is 0.525 or more and less than 0.975 and an expression (38) below is satisfied, r/p is 0.975 or more and less than 1.5 and an expression (39) below is satisfied, r/p is 0.2 or more and less than 0.525 and an expression (40) below is satisfied, or r/p is 0.525 or more and less than 0.975 and an expression (41) below is satisfied, where p is a pitch of the light-emitting portion in the first direction, w is a width of the light-emitting portion in the first direction, r is a radius of curvature of a lens surface of the unit lenses, and d is a distance between the light-emitting portion and the unit lenses,
wherein w/p is 0.05 or more and less than 0.1, and at least r/p is 0.2 or more and less than 0.525 and an expression (42) below is satisfied, r/p is 0.525 or more and less than 0.975 and an expression (43) below is satisfied, r/p is 0.975 or more and less than 1.5 and an expression (44) below is satisfied, r/p is 0.2 or more and less than 0.525 and an expression (45) below is satisfied, or r/p is 0.525 or more and less than 0.975 and an expression (46) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.1 or more and less than 0.2, and at least r/p is 0.2 or more and less than 0.375 and an expression (47) below is satisfied, r/p is 0.375 or more and less than 0.975 and an expression (48) below is satisfied, r/p is 0.975 or more and less than 1.5 and an expression (49) below is satisfied, or r/p is 0.375 or more and less than 0.975 and an expression (50) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.2 or more and less than 0.3, and at least r/p is 0.25 or more and less than 0.725 and an expression (51) below is satisfied, r/p is 0.725 or more and less than 0.975 and an expression (52) below is satisfied, r/p is 0.975 or more and less than 1.5 and an expression (53) below is satisfied, or r/p is 0.725 or more and less than 0.975 and an expression (54) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.3 or more and less than 0.4, and at least r/p is 0.35 or more and less than 0.975 and an expression (55) below is satisfied, or r/p is 0.975 or more and less than 1.5 and an expression (56) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.4 or more and less than 0.5, and at least r/p is 0.4 or more and less than 0.675 and an expression (57) below is satisfied, or r/p is 0.675 or more and less than 1.5 and an expression (58) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses, or
wherein w/p is 0.5 or more and less than 0.6, and at least r/p is 0.5 or more and less than 0.675 and an expression (59) below is satisfied, or r/p is 0.675 or more and less than 1.5 and an expression (60) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
$$1.18 \times r / p - 0.29 \leq d / p \leq 1.36 \times r / p - 0.05 , \qquad expression ( 1 )$$
$$1.18 \times r / p - 0.29 \leq d / p \leq 2.08 \times r / p - 0.15 , \qquad expression ( 2 )$$
$$2.43 \times r / p + 0.05 \leq d / p \leq 4.64 \times r / p - 0.3 , \qquad expression ( 3 )$$
$$4.5 \times r / p - 0.85 \leq d / p \leq 4.64 \times r / p - 0.3 , \qquad expression ( 4 )$$
$$4.5 \times r / p - 0.85 \leq d / p \leq 1.2 \times r / p + 2.46 , \qquad expression ( 5 )$$
$$1.18 \times r / p - 0.29 \leq d / p \leq 1.36 \times r / p , \qquad expression ( 6 )$$
$$1.18 \times r / p - 0.29 \leq d / p \leq 2.05 \times r / p - 0.03 , \qquad expression ( 7 )$$
$$2.57 \times r / p - 0.01 \leq d / p \leq 4.65 \times r / p - 0.3 , \qquad expression ( 8 )$$
$$4.67 \times r / p - 0.98 \leq d / p \leq 4.65 \times r / p - 0.3 , \qquad expression ( 9 )$$
$$4.67 \times r / p - 0.98 \leq d / p \leq 1.2 \times r / p + 2.46 , \qquad expression ( 10 )$$
$$1.18 \times r / p - 0.29 \leq d / p \leq 4 \times r / p - 0.1 , \qquad expression ( 11 )$$
$$1.18 \times r / p - 0.29 \leq d / p \leq 2.17 \times r / p - 0.19 , \qquad expression ( 12 )$$
$$4.79 \times r / p - 1.09 \leq d / p \leq 5.07 \times r / p - 0.58 , \qquad expression ( 13 )$$
$$4.79 \times r / p - 1.09 \leq d / p \leq 1.8 \times r / p + 1.94 , \qquad expression ( 14 )$$
$$1.18 \times r / p - 0.29 \leq d / p \leq 4.84 \times r / p - 0.45 , \qquad expression ( 15 )$$
$$1.18 \times r / p - 0.29 \leq d / p \leq 1.69 \times r / p + 0.6 , \qquad expression ( 16 )$$
$$5.6 \times r / p - 1.84 \leq d / p \leq 1.8 \times r / p + 1.94 , \qquad expression ( 17 )$$
$$1.22 \times r / p - 0.33 \leq d / p \leq 4.55 \times r / p - 0.42 , \qquad expression ( 18 )$$
$$1.22 \times r / p - 0.33 \leq d / p \leq 1.04 \times r / p + 1.78 , \qquad expression ( 19 )$$
$$1.26 \times r / p - 0.37 \leq d / p \leq 5.56 \times r / p - 1.01 , \qquad expression ( 20 )$$
$$1.28 \times r / p - 0.39 \leq d / p \leq 5.83 \times r / p - 1.29 , \qquad expression ( 21 )$$
$$1.38 \times r / p - 0.45 \leq d / p \leq 5.8 \times r / p - 1.48 . \qquad expression ( 22 )$$
$$0.21 \times r / p + 0.01 \leq d / p \leq 1 \times r / p - 0.02 , \qquad expression ( 37 )$$
$$1.4 \times r / p - 0.45 \leq d / p \leq 2.23 \times r / p - 1.4 , \qquad expression ( 38 )$$
$$1.09 \times r / p - 0.18 \leq d / p \leq 1.53 \times r / p + 0.3 , \qquad expression ( 39 )$$
$$2.43 \times r / p + 0.05 \leq d / p \leq 3.57 \times r / p - 0.21 , \qquad expression ( 40 )$$
$$4.57 \times r / p - 0.89 \leq d / p \leq 4 \times r / p - 0.3 , \qquad expression ( 41 )$$
$$0.21 \times r / p + 0.01 \leq d / p \leq 0.79 \times r / p + 0.11 , \qquad expression ( 42 )$$
$$1.4 \times r / p - 0.45 \leq d / p \leq 2.23 \times r / p - 0.4 , \qquad expression ( 43 )$$
$$1.09 \times r / p - 0.18 \leq d / p \leq 1.56 \times r / p + 0.27 , \qquad expression ( 44 )$$
$$2.57 \times r / p - 0.01 \leq d / p \leq 3.43 \times r / p - 0.17 , \qquad expression ( 45 )$$
$$4.77 \times r / p - 1.04 \leq d / p \leq 4.13 \times r / p - 0.41 , \qquad expression ( 46 )$$
$$0.6 \times r / p - 0.09 \leq d / p \leq 4 \times r / p - 0.4 , \qquad expression ( 47 )$$
$$1.53 \times r / p - 0.56 \leq d / p \leq 2.27 \times r / p - 0.35 , \qquad expression ( 48 )$$
$$1.09 \times r / p - 0.18 \leq d / p \leq 1.56 \times r / p + 0.28 , \qquad expression ( 49 )$$
$$4.79 \times r / p - 1.09 \leq d / p \leq 4.41 \times r / p - 0.64 , \qquad expression ( 50 )$$
$$1.03 \times r / p - 0.26 \leq d / p \leq 4.39 \times r / p - 0.64 , \qquad expression ( 51 )$$
$$1.4 \times r / p - 0.45 \leq d / p \leq 0.4 \times r / p + 1.58 , \qquad expression ( 52 )$$
$$1.15 \times r / p - 0.24 \leq d / p \leq 1.49 \times r / p + 0.54 , \qquad expression ( 53 )$$
$$5.6 \times r / p - 1.84 \leq d / p \leq 4 \times r / p - 0.3 , \qquad expression ( 54 )$$
$$1.45 \times r / p - 0.5 \leq d / p \leq 4.45 \times r / p - 0.77 , \qquad expression ( 55 )$$
$$1.16 \times r / p - 0.25 \leq d / p \leq 0.35 \times r / p + 2.51 , \qquad expression ( 56 )$$
$$1.77 \times r / p - 0.68 \leq d / p \leq 5.43 \times r / p - 1.43 , \qquad expression ( 57 )$$
$$1.13 \times r / p - 0.22 \leq d / p \leq 3.23 \times r / p + 0.13 , \qquad expression ( 58 )$$
$$2.6 \times r / p - 1.17 \leq d / p \leq 6.6 \times r / p - 2.27 , \qquad expression ( 59 )$$
$$1.27 \times r / p - 0.33 \leq d / p \leq 3.3 \times r / p - 0.06 . \qquad expression ( 60 ) .$$

2. A display device comprising: a light-emitting substrate that includes a semiconductor layer that is divided into multiple unit regions and a light-emitting portion that is disposed in the multiple unit regions; and
an optical sheet that faces the light-emitting substrate,
wherein the optical sheet includes multiple unit lenses that are arranged in a first direction and that extend in a second direction unparallel with the first direction,
wherein the multiple unit regions are arranged in the first direction and the second direction, and
wherein w/p is less than 0.025, and at least r/p is 0.2 or more and less than 0.525 and an expression (23) below is satisfied, or r/p is 0.525 or more and less than 1.5 and an expression (24) below is satisfied, where p is a pitch of the light-emitting portion in the first direction, w is a width of the light-emitting portion in the first direction, r is a radius of curvature of a lens surface of the unit lenses, and d is a distance between the light-emitting portion and the unit lenses,
wherein w/p is 0.025 or more and less than 0.15, and at least r/p is 0.2 or more and less than 0.525 and an expression (25) below is satisfied, or r/p is 0.525 or more and less than 1.5 and an expression (26) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.15 or more and less than 0.25, and at least r/p is 0.2 or more and less than 0.525 and an expression (27) below is satisfied, or r/p is 0.525 or more and less than 1.5 and an expression (28) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.25 or more and less than 0.35, and at least r/p is 0.25 or more and less than 0.425 and an expression (29) below is satisfied, or r/p is 0.425 or more and less than 1.5 and an expression (30) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.35 or more and less than 0.45, and at least r/p is 0.3 or more and less than 0.525 and an expression (31) below is satisfied, or r/p is 0.525 or more and less than 1.5 and an expression (32) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.45 or more and less than 0.55, and at least r/p is 0.4 or more and less than 0.625 and an expression (33) below is satisfied, or r/p is 0.625 or more and less than 1.5 and an expression (34) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.55 or more and less than 0.65, and at least r/p is 0.45 or more and less than 0.625 and an expression (35) below is satisfied, or r/p is 0.625 or more and less than 1.5 and an expression (36) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.01 or more and less than 0.05, and at least r/p is 0.2 or more and less than 0.525 and an expression (61) below is satisfied, or r/p is 0.525 or more and less than 1.5 and an expression (62) below is satisfied, where p is a pitch of the light-emitting portion in the first direction, w is a width of the light-emitting portion in the first direction, r is a radius of curvature of a lens surface of the unit lenses, and d is a distance between the light-emitting portion and the unit lenses,
wherein w/p is 0.05 or more and less than 0.1, and at least r/p is 0.2 or more and less than 0.525 and an expression (63) below is satisfied, or r/p is 0.525 or more and less than 1.5 and an expression (64) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.1 or more and less than 0.2, and at least r/p is 0.2 or more and less than 0.525 and an expression (65) below is satisfied, or r/p is 0.525 or more and less than 1.5 and an expression (66) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.2 or more and less than 0.3, and at least r/p is 0.25 or more and less than 0.525 and an expression (67) below is satisfied, or r/p is 0.525 or more and less than 1.5 and an expression (68) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.3 or more and less than 0.4, and at least r/p is 0.35 or more and less than 0.675 and an expression (69) below is satisfied, or r/p is 0.675 or more and less than 1.5 and an expression (70) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
wherein w/p is 0.4 or more and less than 0.5, and at least r/p is 0.4 or more and less than 0.675 and an expression (71) below is satisfied, or r/p is 0.675 or more and less than 1.5 and an expression (72) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses, or
wherein w/p is 0.5 or more and less than 0.6, and at least r/p is 0.5 or more and less than 0.675 and an expression (73) below is satisfied, or r/p is 0.675 or more and less than 1.5 and an expression (74) below is satisfied, where p is the pitch of the light-emitting portion in the first direction, w is the width of the light-emitting portion in the first direction, r is the radius of curvature of the lens surface of the unit lenses, and d is the distance between the light-emitting portion and the unit lenses,
$$1.18 \times r / p - 0.29 \leq d / p \leq 1 \times r / p - 0.02 , \qquad expression ( 23 )$$
$$1.18 \times r / p - 0.29 \leq d / p \leq 1.33 \times r / p + 0.15 , \qquad expression ( 24 )$$
$$1.18 \times r / p - 0.29 \leq d / p \leq 1.14 \times r / p - 0.04 , \qquad expression ( 25 )$$
$$1.18 \times r / p - 0.29 \leq d / p \leq 1.3 \times r / p + 0.18 , \qquad expression ( 26 )$$
$$1.18 \times r / p - 0.29 \leq d / p \leq - 0.29 \times r / p + 0.73 , \qquad expression ( 27 )$$
$$1.18 \times r / p - 0.29 \leq d / p \leq 1.29 \times r / p + 0.28 , \qquad expression ( 28 )$$
$$1.22 \times r / p - 0.33 \leq d / p \leq 4.6 \times r / p - 0.52 , \qquad expression ( 29 )$$
$$1.22 \times r / p - 0.33 \leq d / p \leq 1.23 \times r / p + 0.38 , \qquad expression ( 30 )$$
$$1.26 \times r / p - 0.37 \leq d / p \leq 5.4 \times r / p - 0.96 , \qquad expression ( 31 )$$
$$1.26 \times r / p - 0.37 \leq d / p \leq 0.77 \times r / p + 1.08 , \qquad expression ( 32 )$$
$$1.28 \times r / p - 0.39 \leq d / p \leq 5.83 \times r / p - 1.29 , \qquad expression ( 33 )$$
$$1.28 \times r / p - 0.39 \leq d / p \leq 0.4 \times r / p + 1.77 , \qquad expression ( 34 )$$
$$1.38 \times r / p - 0.45 \leq d / p \leq 7.6 \times r / p - 2.44 , \qquad expression ( 35 )$$
$$1.38 \times r / p - 0.45 \leq d / p \leq 0.26 \times r / p + 2.29 . \qquad expression ( 36 )$$
$$0.21 \times r / p + 0.02 \leq d / p \leq 1 \times r / p - 0.08 , \qquad expression ( 61 )$$
$$1.17 \times r / p - 0.28 \leq d / p \leq 1.26 \times r / p + 0.13 , \qquad expression ( 62 )$$
$$0.21 \times r / p + 0.02 \leq d / p \leq 1 \times r / p - 0.08 , \qquad expression ( 63 )$$
$$1.17 \times r / p - 0.28 \leq d / p \leq 1.26 \times r / p + 0.14 , \qquad expression ( 64 )$$
$$0.21 \times r / p + 0.01 \leq d / p \leq 0.71 \times r / p + 0.05 , \qquad expression ( 65 )$$
$$1.17 \times r / p - 0.28 \leq d / p \leq 1.26 \times r / p + 0.14 , \qquad expression ( 66 )$$
$$0.29 \times r / p - 0.05 \leq d / p \leq - 0.23 \times r / p + 0.62 , \qquad expression ( 67 )$$
$$1.2 \times r / p - 0.3 \leq d / p \leq 1.2 \times r / p + 0.21 , \qquad expression ( 68 )$$
$$1.43 \times r / p - 0.49 \leq d / p \leq 1.07 \times r / p + 0.45 , \qquad expression ( 69 )$$
$$1.19 \times r / p - 0.28 \leq d / p \leq 1 \times r / p + 0.5 , \qquad expression ( 70 )$$
$$1.77 \times r / p - 0.68 \leq d / p \leq 2.86 \times r / p - 0.23 , \qquad expression ( 71 )$$
$$1.15 \times r / p - 0.23 \leq d / p \leq 0.64 \times r / p + 1.13 , \qquad expression ( 72 )$$
$$2.6 \times r / p - 1.17 \leq d / p \leq 6.6 \times r / p - 2.27 , \qquad expression ( 73 )$$
$$1.27 \times r / p - 0.33 \leq d / p \leq 0.35 \times r / p + 1.78 . \qquad expression ( 74 ) .$$

3-4. (canceled)

5. The display device according to claim 1, wherein during observation in a normal direction to a plate surface of the light-emitting substrate, one of the unit lenses corresponds to one of unit region second direction columns that are formed by the multiple unit regions that are arranged in the second direction.

6. The display device according to claim 5, wherein during observation in the normal direction to the plate surface of the light-emitting substrate, a center in the first direction of the one of the unit lenses is shifted from a center in the first direction of the light-emitting portion in the unit region that forms the corresponding one of the unit region second direction columns.

7. The display device according to claim 1, wherein the optical sheet has a first surface that faces the light-emitting substrate and a second surface that is opposite the first surface, and
wherein a light deflection layer that faces the second surface of the optical sheet and that deflects light from the optical sheet such that a travelling direction changes during observation in the second direction is further included.

8. The display device according to claim 1, wherein the optical sheet has a first surface that faces the light-emitting substrate and a second surface that is opposite the first surface, and
wherein a light angle adjustment layer that is located along the second surface of the optical sheet and that adjusts an angle of a travelling direction of light from the optical sheet with respect to a normal direction to a plate surface of the light-emitting substrate is further included.

9. The display device according to claim 1, wherein the light-emitting substrate includes, as the light-emitting portion, a first light-emitting portion and a second light-emitting portion that emits light at a wavelength that differs from that of the first light-emitting portion.

10. The display device according to claim 1, wherein a minimum value m of luminance when an angle that is formed with respect to a light collection direction of the optical sheet is in a range of −5° or more and +5° or less is 50% or more of a maximum value M of luminance when the angle that is formed with respect to the light collection direction of the optical sheet is in the range of −5° or more and +5° or less.

11. The display device according to claim 2, wherein a minimum value m2 of luminance when an angle that is formed with respect to a light collection direction of the optical sheet is in a range of −10° or more and +10° or less is 50% or more of a maximum value M2 of luminance when the angle that is formed with respect to the light collection direction of the optical sheet is in the range of −10° or more and +10° or less.

12. A method of manufacturing a display device including: a light-emitting substrate that includes a semiconductor layer that is divided into multiple unit regions and a light-emitting portion that is disposed in the multiple unit regions; and an optical sheet that faces the light-emitting substrate,
the optical sheet including multiple unit lenses that are arranged in a first direction and that extend in a second direction unparallel with the first direction,
the multiple unit regions being arranged in the first direction and the second direction,
the method comprising an adjustment step of adjusting a radius of curvature r and a distance d depending on a value of w/p, where p is a pitch of the light-emitting portion in the first direction, w is a width of the light-emitting portion in the first direction, r is a radius of curvature of a lens surface of the unit lenses, and d is a distance between the light-emitting portion and the unit lenses,
wherein in the adjustment step, in a case where w/p is less than 0.025, the radius of curvature r and the distance d are adjusted such that at least r/p is 0.2 or more and less than 0.525 and an expression (1) below is satisfied, r/p is 0.525 or more and less than 1.5 and an expression (2) below is satisfied, r/p is 0.2 or more and less than 0.525 and an expression (3) below is satisfied, r/p is 0.525 or more and less than 0.725 and an expression (4) below is satisfied, or r/p is 0.725 or more and less than 1.5 and an expression (5) below is satisfied,
wherein in the adjustment step, in a case where w/p is 0.025 or more and less than 0.075, the radius of curvature r and the distance d are adjusted such that at least r/p is 0.2 or more and less than 0.525 and an expression (6) below is satisfied, r/p is 0.525 or more and less than 1.5 and an expression (7) below is satisfied, r/p is 0.2 or more and less than 0.525 and an expression (8) below is satisfied, r/p is 0.525 or more and less than 0.725 and an expression (9) below is satisfied, or r/p is 0.725 or more and less than 1.5 and an expression (10) below is satisfied, wherein in the adjustment step, in a case where w/p is 0.075 or more and less than 0.15, the radius of curvature r and the distance d are adjusted such that at least r/p is 0.2 or more and less than 0.375 and an expression (11) below is satisfied, r/p is 0.375 or more and less than 1.5 and an expression (12) below is satisfied, r/p is 0.2 or more and less than 0.725 and an expression (13) below is satisfied, or r/p is 0.725 or more and less than 1.5 and an expression (14) below is satisfied,
wherein in the adjustment step, in a case where w/p is 0.15 or more and less than 0.25, the radius of curvature r and the distance d are adjusted such that at least r/p is 0.2 or more and less than 0.725 and an expression (15) below is satisfied, r/p is 0.725 or more and less than 1.5 and an expression (16) below is satisfied, or r/p is 0.2 or more and less than 1.5 and an expression (17) below is satisfied,
wherein in the adjustment step, in a case where w/p is 0.25 or more and less than 0.35, the radius of curvature r and the distance d are adjusted such that at least r/p is 0.25 or more and less than 0.975 and an expression (18) below is satisfied, or r/p is 0.975 or more and less than 1.5 and an expression (19) below is satisfied,
wherein in the adjustment step, in a case where w/p is 0.35 or more and less than 0.45, the radius of curvature r and the distance d are adjusted such that r/p is 0.3 or more and less than 1.5 and an expression (20) below is satisfied,
wherein in the adjustment step, in a case where w/p is 0.45 or more and less than 0.55, the radius of curvature r and the distance d are adjusted such that r/p is 0.4 or more and less than 1.5 and an expression (21) below is satisfied, and
wherein in the adjustment step, in a case where w/p is 0.55 or more and less than 0.65, the radius of curvature r and the distance d are adjusted such that r/p is 0.45 or more and less than 1.5 and an expression (22) below is satisfied,
wherein in the adjustment step, in a case where w/p is less than 0.025, the radius of curvature r and the distance d are adjusted such that at least r/p is 0.2 or more and less than 0.525 and an expression (23) below is satisfied, or r/p is 0.525 or more and less than 1.5 and an expression (24) below is satisfied, wherein in the adjustment step, in a case where w/p is 0.025 or more and less than 0.15, the radius of curvature r and the distance d are adjusted such that at least r/p is 0.2 or more and less than 0.525 and an expression (25) below is satisfied, or r/p is 0.525 or more and less than 1.5 and an expression (26) below is satisfied, wherein in the adjustment step, in a case where w/p is 0.15 or more and less than 0.25, the radius of curvature r and the distance d are adjusted such that at least r/p is 0.2 or more and less than 0.525 and an expression (27) below is satisfied, or r/p is 0.525 or more and less than 1.5 and an expression (28) below is satisfied, wherein in the adjustment step, in a case where w/p is 0.25 or more and less than 0.35, the radius of curvature r and the distance d are adjusted such that at least r/p is 0.25 or more and less than 0.425 and an expression (29) below is satisfied, or r/p is 0.425 or more and less than 1.5 and an expression (30) below is satisfied, wherein in the adjustment step, in a case where w/p is 0.35 or more and less than 0.45, the radius of curvature r and the distance d are adjusted such that at least r/p is 0.3 or more and less than 0.525 and an expression (31) below is satisfied, or r/p is 0.525 or more and less than 1.5 and an expression (32) below is satisfied, wherein in the adjustment step, in a case where w/p is 0.45 or more and less than 0.55, the radius of curvature r and the distance d are adjusted such that at least r/p is 0.4 or more and less than 0.625 and an expression (33) below is satisfied, or r/p is 0.625 or more and less than 1.5 and an expression (34) below is satisfied, and wherein in the adjustment step, in a case where w/p is 0.55 or more and less than 0.65, the radius of curvature r and the distance d are adjusted such that at least r/p is 0.45 or more and less than 0.625 and an expression (35) below is satisfied, or r/p is 0.625 or more and less than 1.5 and an expression (36) below is satisfied,
wherein in the adjustment step, in a case where w/p is 0.01 or more and less than 0.05, the radius of curvature r and the distance d are adjusted such that at least r/p is 0.2 or more and less than 0.525 and an expression (37) below is satisfied, r/p is 0.525 or more and less than 0.975 and an expression (38) below is satisfied, r/p is 0.975 or more and less than 1.5 and an expression (39) below is satisfied, r/p is 0.2 or more and less than 0.525 and an expression (40) below is satisfied, or r/p is 0.525 or more and less than 0.975 and an expression (41) below is satisfied, wherein in a case where w/p is 0.05 or more and less than 0.1, the radius of curvature r and the distance d are adjusted such that at least r/p is 0.2 or more and less than 0.525 and an expression (42) below is satisfied, r/p is 0.525 or more and less than 0.975 and an expression (43) below is satisfied, r/p is 0.975 or more and less than 1.5 and an expression (44) below is satisfied, r/p is 0.2 or more and less than 0.525 and an expression (45) below is satisfied, or r/p is 0.525 or more and less than 0.975 and an expression (46) below is satisfied, wherein in a case where w/p is 0.1 or more and less than 0.2, the radius of curvature r and the distance d are adjusted such that at least r/p is 0.2 or more and less than 0.375 and an expression (47) below is satisfied, r/p is 0.375 or more and less than 0.975 and an expression (48) below is satisfied, r/p is 0.975 or more and less than 1.5 and an expression (49) below is satisfied, or r/p is 0.375 or more and less than 0.975 and an expression (50) below is satisfied, wherein in a case where w/p is 0.2 or more and less than 0.3, the radius of curvature r and the distance d are adjusted such that at least r/p is 0.25 or more and less than 0.725 and an expression (51) below is satisfied, r/p is 0.725 or more and less than 0.975 and an expression (52) below is satisfied, r/p is 0.975 or more and less than 1.5 and an expression (53) below is satisfied, or r/p is 0.725 or more and less than 0.975 and an expression (54) below is satisfied, wherein in a case where w/p is 0.3 or more and less than 0.4, the radius of curvature r and the distance d are adjusted such that at least r/p is 0.35 or more and less than 0.975 and an expression (55) below is satisfied, or r/p is 0.975 or more and less than 1.5 and an expression (56) below is satisfied, wherein in a case where w/p is 0.4 or more and less than 0.5, the radius of curvature r and the distance d are adjusted such that at least r/p is 0.4 or more and less than 0.675 and an expression (57) below is satisfied, or r/p is 0.675 or more and less than 1.5 and an expression (58) below is satisfied, and wherein in a case where w/p is 0.5 or more and less than 0.6, the radius of curvature r and the distance d are adjusted such that at least r/p is 0.5 or more and less than 0.675 and an expression (59) below is satisfied, or r/p is 0.675 or more and less than 1.5 and an expression (60) below is satisfied, or
wherein in the adjustment step, in a case where w/p is 0.01 or more and less than 0.05, the radius of curvature r and the distance d are adjusted such that at least r/p is 0.2 or more and less than 0.525 and an expression (61) below is satisfied, or r/p is 0.525 or more and less than 1.5 and an expression (62) below is satisfied, wherein in a case where w/p is 0.05 or more and less than 0.1, the radius of curvature r and the distance d are adjusted such that at least r/p is 0.2 or more and less than 0.525 and an expression (63) below is satisfied, or r/p is 0.525 or more and less than 1.5 and an expression (64) below is satisfied, wherein in a case where w/p is 0.1 or more and less than 0.2, the radius of curvature r and the distance d are adjusted such that at least r/p is 0.2 or more and less than 0.525 and an expression (65) below is satisfied, or r/p is 0.525 or more and less than 1.5 and an expression (66) below is satisfied, wherein in a case where w/p is 0.2 or more and less than 0.3, the radius of curvature r and the distance d are adjusted such that at least r/p is 0.25 or more and less than 0.525 and an expression (67) below is satisfied, or r/p is 0.525 or more and less than 1.5 and an expression (68) below is satisfied, wherein in a case where w/p is 0.3 or more and less than 0.4, the radius of curvature r and the distance d are adjusted such that at least r/p is 0.35 or more and less than 0.675 and an expression (69) below is satisfied, or r/p is 0.675 or more and less than 1.5 and an expression (70) below is satisfied, wherein in a case where w/p is 0.4 or more and less than 0.5, the radius of curvature r and the distance d are adjusted such that at least r/p is 0.4 or more and less than 0.675 and an expression (71) below is satisfied, or r/p is 0.675 or more and less than 1.5 and an expression (72) below is satisfied, and wherein in a case where w/p is 0.5 or more and less than 0.6, the radius of curvature r and the distance d are adjusted such that at least r/p is 0.5 or more and less than 0.675 and an expression (73) below is satisfied, or r/p is 0.675 or more and less than 1.5 and an expression (74) below is satisfied,
$$1.18 \times r / p - 0.29 \leq d / p \leq 1.36 \times r / p - 0.05 , \qquad expression ( 1 )$$
$$1.18 \times r / p - 0.29 \leq d / p \leq 2.08 \times r / p - 0.15 , \qquad expression ( 2 )$$
$$2.43 \times r / p + 0.05 \leq d / p \leq 4.64 \times r / p - 0.3 , \qquad expression ( 3 )$$
$$4.5 \times r / p - 0.85 \leq d / p \leq 4.64 \times r / p - 0.3 , \qquad expression ( 4 )$$
$$4.5 \times r / p - 0.85 \leq d / p \leq 1.2 \times r / p + 2.46 , \qquad expression ( 5 )$$
$$1.18 \times r / p - 0.29 \leq d / p \leq 1.36 \times r / p , \qquad expression ( 6 )$$
$$1.18 \times r / p - 0.29 \leq d / p \leq 2.05 \times r / p - 0.03 , \qquad expression ( 7 )$$
$$2.57 \times r / p - 0.01 \leq d / p \leq 4.65 \times r / p - 0.3 , \qquad expression ( 8 )$$
$$4.67 \times r / p - 0.98 \leq d / p \leq 4.65 \times r / p - 0.3 , \qquad expression ( 9 )$$
$$4.67 \times r / p - 0.98 \leq d / p \leq 1.2 \times r / p + 2.46 , \qquad expression ( 10 )$$
$$1.18 \times r / p - 0.29 \leq d / p \leq 4 \times r / p - 0.1 , \qquad expression ( 11 )$$
$$1.18 \times r / p - 0.29 \leq d / p \leq 2.17 \times r / p - 0.19 , \qquad expression ( 12 )$$
$$4.79 \times r / p - 1.09 \leq d / p \leq 5.07 \times r / p - 0.58 , \qquad expression ( 13 )$$
$$4.79 \times r / p - 1.09 \leq d / p \leq 1.8 \times r / p + 1.94 , \qquad expression ( 14 )$$
$$1.18 \times r / p - 0.29 \leq d / p \leq 4.84 \times r / p - 0.45 , \qquad expression ( 15 )$$
$$1.18 \times r / p - 0.29 \leq d / p \leq 1.69 \times r / p + 0.6 , \qquad expression ( 16 )$$
$$5.6 \times r / p - 1.84 \leq d / p \leq 1.8 \times r / p + 1.94 , \qquad expression ( 17 )$$
$$1.22 \times r / p - 0.33 \leq d / p \leq 4.55 \times r / p - 0.42 , \qquad expression ( 18 )$$
$$1.22 \times r / p - 0.33 \leq d / p \leq 1.04 \times r / p + 1.78 , \qquad expression ( 19 )$$
$$1.26 \times r / p - 0.37 \leq d / p \leq 5.56 \times r / p - 1.01 , \qquad expression ( 20 )$$
$$1.28 \times r / p - 0.39 \leq d / p \leq 5.83 \times r / p - 1.29 , \qquad expression ( 21 )$$
$$1.38 \times r / p - 0.45 \leq d / p \leq 5.8 \times r / p - 1.48 . \qquad expression ( 22 )$$
$$1.18 \times r / p - 0.29 \leq d / p \leq 1 \times r / p - 0.02 , \qquad expression ( 23 )$$
$$1.18 \times r / p - 0.29 \leq d / p \leq 1.33 \times r / p + 0.15 , \qquad expression ( 24 )$$
$$1.18 \times r / p - 0.29 \leq d / p \leq 1.14 \times r / p - 0.04 , \qquad expression ( 25 )$$
$$1.18 \times r / p - 0.29 \leq d / p \leq 1.3 \times r / p + 0.18 , \qquad expression ( 26 )$$
$$1.18 \times r / p - 0.29 \leq d / p \leq - 0.29 \times r / p + 0.73 , \qquad expression ( 27 )$$
$$1.18 \times r / p - 0.29 \leq d / p \leq 1.29 \times r / p + 0.28 , \qquad expression ( 28 )$$
$$1.22 \times r / p - 0.33 \leq d / p \leq 4.6 \times r / p - 0.52 , \qquad expression ( 29 )$$
$$1.22 \times r / p - 0.33 \leq d / p \leq 1.23 \times r / p + 0.38 , \qquad expression ( 30 )$$
$$1.26 \times r / p - 0.37 \leq d / p \leq 5.4 \times r / p - 0.96 , \qquad expression ( 31 )$$
$$1.26 \times r / p - 0.37 \leq d / p \leq 0.77 \times r / p + 1.08 , \qquad expression ( 32 )$$
$$1.28 \times r / p - 0.39 \leq d / p \leq 5.83 \times r / p - 1.29 , \qquad expression ( 33 )$$
$$1.28 \times r / p - 0.39 \leq d / p \leq 0.4 \times r / p + 1.77 , \qquad expression ( 34 )$$
$$1.38 \times r / p - 0.45 \leq d / p \leq 7.6 \times r / p - 2.44 , \qquad expression ( 35 )$$
$$1.38 \times r / p - 0.45 \leq d / p \leq 0.26 \times r / p + 2.29 . \qquad expression ( 36 )$$
$$0.21 \times r / p + 0.01 \leq d / p \leq 1 \times r / p - 0.02 , \qquad expression ( 37 )$$
$$1.4 \times r / p - 0.45 \leq d / p \leq 2.23 \times r / p - 1.4 , \qquad expression ( 38 )$$
$$1.09 \times r / p - 0.18 \leq d / p \leq 1.53 \times r / p + 0.3 , \qquad expression ( 39 )$$
$$2.43 \times r / p + 0.05 \leq d / p \leq 3.57 \times r / p - 0.21 , \qquad expression ( 40 )$$
$$4.57 \times r / p - 0.89 \leq d / p \leq 4 \times r / p - 0.3 , \qquad expression ( 41 )$$
$$0.21 \times r / p + 0.01 \leq d / p \leq 0.79 \times r / p + 0.11 , \qquad expression ( 42 )$$
$$1.4 \times r / p - 0.45 \leq d / p \leq 2.23 \times r / p - 0.4 , \qquad expression ( 43 )$$
$$1.09 \times r / p - 0.18 \leq d / p \leq 1.56 \times r / p + 0.27 , \qquad expression ( 44 )$$
$$2.57 \times r / p - 0.01 \leq d / p \leq 3.43 \times r / p - 0.17 , \qquad expression ( 45 )$$
$$4.77 \times r / p - 1.04 \leq d / p \leq 4.13 \times r / p - 0.41 , \qquad expression ( 46 )$$
$$0.6 \times r / p - 0.09 \leq d / p \leq 4 \times r / p - 0.4 , \qquad expression ( 47 )$$
$$1.53 \times r / p - 0.56 \leq d / p \leq 2.27 \times r / p - 0.35 , \qquad expression ( 48 )$$
$$1.09 \times r / p - 0.18 \leq d / p \leq 1.56 \times r / p + 0.28 , \qquad expression ( 49 )$$
$$4.79 \times r / p - 1.09 \leq d / p \leq 4.41 \times r / p - 0.64 , \qquad expression ( 50 )$$
$$1.03 \times r / p - 0.26 \leq d / p \leq 4.39 \times r / p - 0.64 , \qquad expression ( 51 )$$
$$1.4 \times r / p - 0.45 \leq d / p \leq 0.4 \times r / p + 1.58 , \qquad expression ( 52 )$$
$$1.15 \times r / p - 0.24 \leq d / p \leq 1.49 \times r / p + 0.54 , \qquad expression ( 53 )$$
$$5.6 \times r / p - 1.84 \leq d / p \leq 4 \times r / p - 0.3 , \qquad expression ( 54 )$$
$$1.45 \times r / p - 0.5 \leq d / p \leq 4.45 \times r / p - 0.77 , \qquad expression ( 55 )$$
$$1.16 \times r / p - 0.25 \leq d / p \leq 0.35 \times r / p + 2.51 , \qquad expression ( 56 )$$
$$1.77 \times r / p - 0.68 \leq d / p \leq 5.43 \times r / p - 1.43 , \qquad expression ( 57 )$$
$$1.13 \times r / p - 0.22 \leq d / p \leq 3.23 \times r / p + 0.13 , \qquad expression ( 58 )$$
$$2.6 \times r / p - 1.17 \leq d / p \leq 6.6 \times r / p - 2.27 , \qquad expression ( 59 )$$
$$1.27 \times r / p - 0.33 \leq d / p \leq 3.3 \times r / p - 0.06 . \qquad expression ( 60 )$$
$$0.21 \times r / p + 0.02 \leq d / p \leq 1 \times r / p - 0.08 , \qquad expression ( 61 )$$
$$1.17 \times r / p - 0.28 \leq d / p \leq 1.26 \times r / p + 0.13 , \qquad expression ( 62 )$$
$$0.21 \times r / p + 0.02 \leq d / p \leq 1 \times r / p - 0.08 , \qquad expression ( 63 )$$
$$1.17 \times r / p - 0.28 \leq d / p \leq 1.26 \times r / p + 0.14 , \qquad expression ( 64 )$$
$$0.21 \times r / p + 0.01 \leq d / p \leq 0.71 \times r / p + 0.05 , \qquad expression ( 65 )$$
$$1.17 \times r / p - 0.28 \leq d / p \leq 1.26 \times r / p + 0.14 , \qquad expression ( 66 )$$
$$0.29 \times r / p - 0.05 \leq d / p \leq - 0.23 \times r / p + 0.62 , \qquad expression ( 67 )$$
$$1.2 \times r / p - 0.3 \leq d / p \leq 1.2 \times r / p + 0.21 , \qquad expression ( 68 )$$
$$1.43 \times r / p - 0.49 \leq d / p \leq 1.07 \times r / p + 0.45 , \qquad expression ( 69 )$$
$$1.19 \times r / p - 0.28 \leq d / p \leq 1 \times r / p + 0.5 , \qquad expression ( 70 )$$
$$1.77 \times r / p - 0.68 \leq d / p \leq 2.86 \times r / p - 0.23 , \qquad expression ( 71 )$$
$$1.15 \times r / p - 0.23 \leq d / p \leq 0.64 \times r / p + 1.13 , \qquad expression ( 72 )$$
$$2.6 \times r / p - 1.17 \leq d / p \leq 6.6 \times r / p - 2.27 , \qquad expression ( 73 )$$
$$1.27 \times r / p - 0.33 \leq d / p \leq 0.35 \times r / p + 1.78 . \qquad expression ( 74 ) .$$

13-15. (canceled)

16. The display device according to claim 2, wherein during observation in a normal direction to a plate surface of the light-emitting substrate, one of the unit lenses corresponds to one of unit region second direction columns that are formed by the multiple unit regions that are arranged in the second direction.

17. The display device according to claim 16, wherein during observation in the normal direction to the plate surface of the light-emitting substrate, a center in the first direction of the one of the unit lenses is shifted from a center in the first direction of the light-emitting portion in the unit region that forms the corresponding one of the unit region second direction columns.

18. The display device according to claim 2, wherein the optical sheet has a first surface that faces the light-emitting substrate and a second surface that is opposite the first surface, and
wherein a light deflection layer that faces the second surface of the optical sheet and that deflects light from the optical sheet such that a travelling direction changes during observation in the second direction is further included.

19. The display device according to claim 2, wherein the optical sheet has a first surface that faces the light-emitting substrate and a second surface that is opposite the first surface, and
wherein a light angle adjustment layer that is located along the second surface of the optical sheet and that adjusts an angle of a travelling direction of light from the optical sheet with respect to a normal direction to a plate surface of the light-emitting substrate is further included.

20. The display device according to claim 2, wherein the light-emitting substrate includes, as the light-emitting portion, a first light-emitting portion and a second light-emitting portion that emits light at a wavelength that differs from that of the first light-emitting portion.
